(19) United States
(12) Patent Application Publication
(10) Pub. No.: US 2019/0214578 A1
(43) Pub. Date: Jul. 11, 2019

(54) ORGANIC ELECTROLUMINESCENT ELEMENT, DISPLAY DEVICE, AND ILLUMINATION DEVICE

(71) Applicant: Konica Minolta, Inc., Tokyo (JP)

(72) Inventors: RYUTARO SUGAWARA, Machida-shi, Tokyo (JP); TAKATUGU SUZUKI, Hachioji-shi, Tokyo (JP)

(73) Assignee: Konica Minolta, Inc., Tokyo (JP)

(21) Appl. No.: 16/315,073

(22) PCT Filed: Jul. 6, 2017
(86) PCT No.: PCT/JP2017/024813

§ 371 Date: Jan. 3, 2019

(30) Foreign Application Priority Data
Jul. 8, 2016 (JP) 2016-135991

(51) Int. Cl. H01L 51/00

(52) U.S. Cl. CPC H01L 51/0072; H01L 51/0071; H01L 51/0085; H01L 51/5012; H01L 51/006; H01L 51/0067; H01L 51/0059

(57) ABSTRACT

An object of the present invention is to provide an organic electroluminescent element having a maximum emission wavelength in a near-infrared region, high luminous efficiency, and a small change in resistance value over time during passage of a current. An organic electroluminescent element of the present invention includes a positive electrode, a negative electrode, and an organic layer sandwiched between the positive electrode and the negative electrode and including at least a light emitting layer. The light emitting layer includes a first organic compound formed of a delayed fluophor or a phosphorescent compound having ΔE_{ST} of 0.3 eV or less. Any one of the positive electrode, the negative electrode, and the organic layer includes a second organic compound formed of a fluorescent dye represented by general formula (1) or (2), having a maximum emission wavelength of 700 nm to 1000 nm in a fluorescence spectrum.

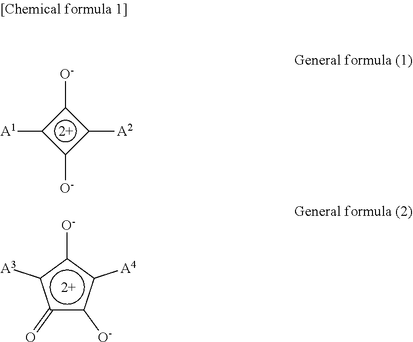

When the first organic compound is the delayed fluophor, the following formula (a) is satisfied. When the first organic compound is the phosphorescent compound, the following formula (b) is satisfied.
Formula (a): ES1(A)>ES1(B)
Formula (b): ET1(A)>ES1(B)

### TECHNICAL FIELD

The present invention relates to an organic electroluminescent element, a display device, and an illumination device, and particularly to an organic electroluminescent element having excellent luminous efficiency and stability over time, and a display device and an illumination device each including the organic electroluminescent element.

### BACKGROUND ART

An organic electroluminescent element (hereinafter, also referred to as an organic EL element) has a configuration in which an organic functional layer containing a light emitting material is sandwiched between a negative electrode and a positive electrode, and is a light emitting element that recombines a hole injected from the positive electrode and an electron injected from the negative electrode in a light emitting layer by application of an electric field to generate an exciton, and utilizes emission of light when the exciton is deactivated. The organic EL element can emit light in a plane, and therefore is applied not only to an electronic display but also to an illumination apparatus. Development of the organic EL element is expected.

A light emission method of the organic EL element includes two types, that is, “phosphorescence” that is light emission when the organic EL element returns from a triplet excited state to a ground state, and “fluorescence” that is light emission when the organic EL element returns from a singlet excited state to the ground state.

When an electric field is applied to the organic EL element, a hole and an electron are injected from a positive electrode and a negative electrode, respectively, and are recombined in a light emitting layer to generate an exciton. At this time, a singlet exciton and a triplet exciton are generated at a ratio of 25%:75%. Therefore, it is known that phosphorescence utilizing the triplet exciton can obtain theoretically higher internal quantum efficiency than fluorescence.

As a development for practical use of an organic EL element, development of technology to efficiently emit light with high brightness with low power consumption has been desired. Since an organic EL element using phosphorescence from an excited triplet was reported (M. A. Baldo et al., Nature. Vol. 395, 151 p. 154 (1998)), a material exhibiting phosphorescence at room temperature has been actively studied. For example, A. Tsuboyama, et al., J. Am. Chem. Soc., Volume 125, 42 p 12971 (2003) has reported an organic EL element utilizing phosphorescence from a iridium complex. The organic EL element can emit light in a visible light region such as blue, green, or red depending on the structure of a ligand of the iridium complex.

In recent years, as a system incorporating a light emitting element, not only a system utilizing light emission in a visible light region such as blue, green, or red but also a system utilizing infrared light has attracted attention. An element that emits infrared light has already been put to practical use in an inorganic LED, is used, for example, as a light source of an infrared camera, and is incorporated in a foreign matter inspection system or the like. However, the organic EL element that emits infrared light has low luminous efficiency and remains at a development stage.

As a conventionally known organic EL element that emits light in an infrared region, for example, Patent Literature 1 describes that an organic EL element using a cyanine dye represented by the following structure has a maximum emission wavelength at 800 nm.

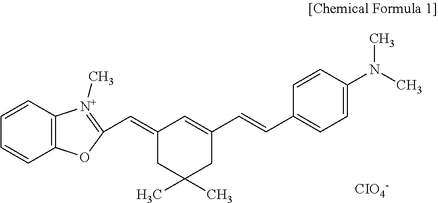

In addition, as a means for enhancing the luminous efficiency gait organic EL element, Non Patent Literature 1 discloses an organic EL element using a host compound, a light emitting compound, and an assist dopant (delayed fluophor) as a material of a light emitting layer. Non Patent Literature 1 describes that the assist dopant in this organic EL element complements transfer of excitation energy in the light emitting layer, that the transfer of energy from the assist dopant to a light emitting dopant enhances the luminous efficiency of the organic EL element, and furthermore that brightness half time is prolonged. As the delayed fluophor, in addition to the substance described above, a thermally excited delayed fluorescence (TADF) substance is also known which makes almost 100% fluorescence possible by causing inverse intersystem crossing from a triplet excited state having a low energy level to a singlet excited state due to Joule heat during light emission or ambient temperature at which a light emitting element is placed (see, for example, Patent Literature 3 or Non Patent Literature 2).

In addition, Patent Literature 2 discloses an organic EL element including a first organic compound (host compound), a second organic compound (assist dopant), and a third organic compound (light emitting compound). Furthermore, as the third organic compound (light emitting compound), a compound that emits light in green, red, blue, or yellow is illustrated. For example, as a red light emitting compound, a squarylium derivative having the following structure is described.

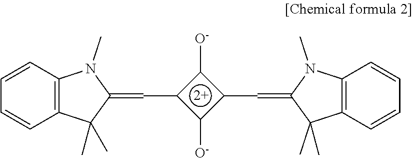

### CITATION LIST

### Patent Literature

Patent Literature 1: JP 2002-80841 A

Patent Literature 2: JP 5669163 B2

Patent Literature 3: JP 2013-116975 A

### Non Patent Literature

Non Patent Literature 1: H. Uoyama, et al., Nature, 2012, 492, 234-238

Non Patent Literature 2: H. Nakanotani, et al., Nature Communication, 2014, 5, 4016-4022.

### SUMMARY OF INVENTION

### Technical Problem

As described above, Patent Literature 1 describes that an organic EL element using a cyanine dye emits light in an infrared region. However, the present inventors evaluated the organic EL using a cyanine dye for a light emitting layer described in Patent Literature 1. As a result, the organic EL did not have sufficiently satisfactory luminous efficiency.

In addition, Patent Literature 2 describes the above-described squarylium derivative as a red light emitting compound, but a maximum emission wavelength thereof is 670 nm, which is in a visible light region. Therefore, utility of the squarylium derivative for a compound that emits light in a near-infrared region is unpredictable.

In addition, in a case where a light emitting element is incorporated in a foreign matter inspection system or the like, stability of the light emitting element is a problem. A reason thereof is as follows. That is, the foreign matter inspection system analyzes data sent from an infrared camera and detects a foreign matter, and therefore if a light emitting element of a light source is not stable, data analysis is complicated, and malfunction occurs. However, a means for improving driving stability, that is, a means for reducing a change in resistance value over time during passage of a current in an organic EL element that emits infrared light has not been reported within a range of research of the present inventor.

The present invention has been achieved in view of the above problems and circumstances, and an object of the present invention is to provide an organic EL element having a maximum emission wavelength in a near-infrared region, high luminous efficiency, and a small change in resistance value over time during passage of a current, a display device, and an illumination device.

### Solution to Problem

As a result of intensive studies, the present inventors have found that by using a plurality of organic compounds satisfying specific conditions, it is possible to provide an organic EL element having a maximum emission wavelength in a near-infrared region, high luminous efficiency, and a small change in resistance value over time during passage of a current, and have reached the present invention.

That is, the above problems related to the present invention can be solved by the following means.

[1] An organic electroluminescent element including a positive electrode, a negative electrode, and an organic layer sandwiched between the positive electrode and the negative electrode and including at least a light emitting layer, in which
the light emitting layer includes a first organic compound formed of a delayed fluophor or a phosphorescent compound having a difference in energy ΔE_{ST} of 0.3 eV or less between a lowest excited singlet state and a lowest excited triplet state at 77 K,
the positive electrode, the negative electrode, or the organic layer includes a second organic compound formed of a fluorescent dye represented by general formula (1) or (2), having a maximum emission wavelength of 700 nm to 1000 nm in a fluorescence spectrum,

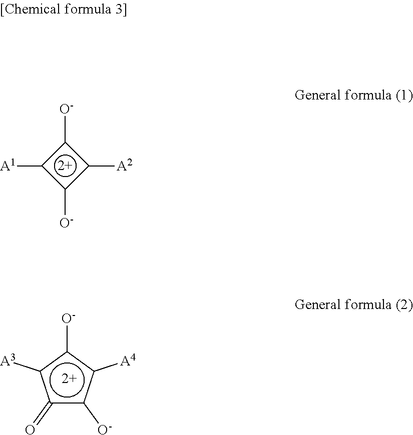

[In general formulas (1) and (2), A¹ to A⁴ each independently represent a group having a sp2 carbon atom at a bonding site]
when the first organic compound is the delayed fluophor, the first organic compound and the second organic compound satisfy the following formula (a),
formula (a): ES1(A)>ES1(B)
(In formula (a),
ES1(A) represents a lowest excited singlet energy level of the first organic compound, and
ES1(B) represents a lowest excited singlet energy level of the second organic compound), and
when the first organic compound is the phosphorescent compound, the first organic compound and the second organic compound satisfy the following formula (b).
Formula (b): ET1(A)>ES1(B)
(In formula (b),
ET1(A) represents a lowest excited triplet energy level of the first organic compound at 77 K, and
ES1(B) represents a lowest excited singlet energy level of the second organic compound.)

[2] The organic electroluminescent element according to in which
the light emitting layer further includes a third organic compound,
when the first organic compound is the delayed fluophor, the first organic compound and the third organic compound satisfy the following formulas (a)′ and (c)′,
formula (a)′: ES1(C)>ES1(A)
formula (c)′: ET1(C)>ET1(A)
(In formula (a)′,
ES1(C) represents a lowest excited singlet energy level of the third organic compound, and
ES1(A) represents a lowest excited singlet energy level of the first organic compound.
In formula (c)′,
ET1(C) represents a lowest excited triplet energy level of the third organic compound at 77 K, and
ET1(A) represents a lowest excited triplet energy level of the first organic compound at 77 K), and
when the first organic compound is the phosphorescent compound, the first organic compound and the third organic compound satisfy the formula (c)′.

[3] The organic electroluminescent element according to [1] or [2], in which the second organic compound is included in the light emitting layer or a layer adjacent to the light emitting layer.

[4] The organic electroluminescent element according to [3], in which the second organic compound is included in the light emitting layer.

[5] The organic electroluminescent element according to [2], in which the first organic compound, the second organic compound, and the third organic compound are all included in the light emitting layer.

[6] The organic electroluminescent element according to any one of [1] to [5], in which in the general formulas (1) and (2), A¹ to A⁴ are each independently selected from the group consisting of the following (a) to (l).

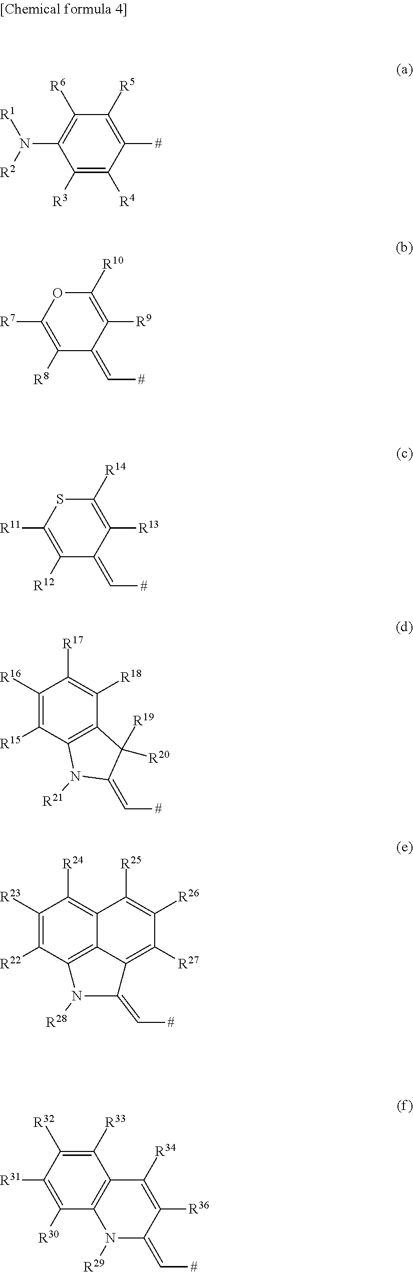

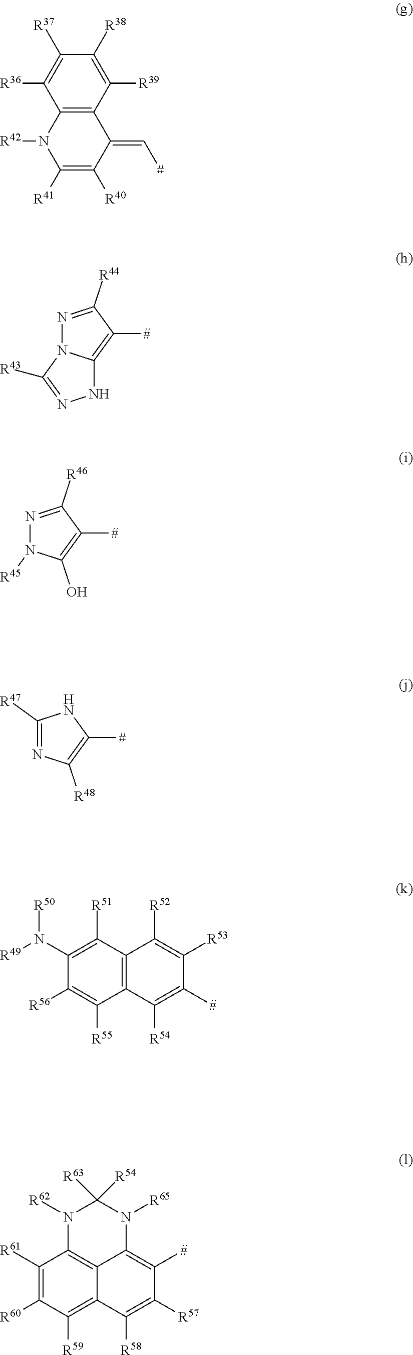

[In formulas (a) to (l),
R¹ to R⁶⁵ each independently represent a hydrogen atom or a substituent,
adjacent ones of the substituents may be bonded to each other to form a cyclic structure, and
# represents a bond to general formula (1) or (2).

Provided that at least one of R¹⁵ to R¹⁸ in formula (d), at least one of R²² to R²⁷ in formula (e), at least one of R³⁰ to R³⁵ in formula (f), at least one of R³⁶ to R⁴¹ in formula (g), at least one of R⁴³ and R⁴⁴ in formula (h), at least one of R⁴⁵ and R⁴⁶ in formula (i), and at least one of R⁴⁷ and R⁴⁸ in formula (j) each represent an electron-donating group D selected from the group consisting of an aryl group substituted with an electron-donating group, an optionally substituted electron-donating heterocyclic group, an optionally substituted amino group, an optionally substituted alkoxy group, and an alkyl group.]

[7] The organic electroluminescent element according to any one of [1] to [6], in which the first organic compound is the delayed fluophor.

[8] A display device including the organic electroluminescent element according to any one of [1] to [7].

[9] An illumination device including the organic electroluminescent element according to any one of [1] to [7].

### ADVANTAGEOUS EFFECTS OF INVENTION

The above means of the present invention can provide a novel organic EL element having a maximum emission wavelength in a near-infrared region, high luminous efficiency, and a small change in resistance value over time during passage of a current. In addition, the above means of the present invention can provide a display device and an illumination device each including the organic EL element.

### BRIEF DESCRIPTION OF DRAWINGS

FIG. 1 is a graph illustrating examples of M-plots in a case where an electron transport layer has various film thicknesses.

FIG. 2 is a graph illustrating an example of a relationship between a film thickness and a resistance value.

FIG. 3 is a diagram illustrating an example of an equivalent circuit model of an organic electroluminescent element.

FIG. 4A is a graph illustrating an example of a relationship between resistance and voltage in each layer.

FIG. 4B is a graph illustrating an example of a relationship between resistance and voltage in each layer after deterioration.

FIG. 5 is a schematic view illustrating an example of a display device including an organic EL element.

FIG. 6 is a schematic view of a display device according to an active matrix method.

FIG. 7 is a schematic diagram illustrating a circuit of a pixel.

FIG. 8 is a schematic view of a display device according to a passive matrix method.

FIG. 9 is a schematic view of an illumination device.

FIG. 10 is a cross-sectional view of the illumination device.

### DESCRIPTION OF EMBODIMENTS

Hereinafter, the present invention, constituent elements thereof, and embodiments and modes for performing the present invention will be described in detail. Incidentally, in the present application, “to” means inclusion of numerical values described before and after “to” as a lower limit value and an upper limit value.

The present inventors have found that by using a plurality of organic compounds satisfying specific conditions, it is possible to provide an organic EL element having high luminous efficiency and a small change in resistance value over time during passage of a current. An exhibition mechanism or an action mechanism of an effect of the present invention has not been clarified but is estimated as follows.

The organic EL element of the present invention includes a first organic compound and a second organic compound satisfying the above formula (a) or (b). The first organic compound is a delayed fluophor or a phosphorescent compound, and therefore can transfer excitation energy generated by recombination to the second organic compound with a small loss. As described later, the second organic compound has a specific structure represented by general formula (1) or (2), and therefore exhibits a high absorption coefficient. As a result, the second organic compound can efficiently receive the excitation energy generated by the first organic compound. Then, the second organic compound emits fluorescence when returning from an excited singlet state to a ground state.

As described above, the organic EL element of the present invention can efficiently transfer the excitation energy generated by the first organic compound in a light emitting layer to the second organic compound. As a result, it is estimated that an organic EL element having high luminous efficiency and a small change in resistance value over time during passage of a current can be realized.

First, a light emission method and a light emitting material of an organic EL, related to the technical idea of the present invention, will be described.

<Light Emission Method of Organic EL>

A light emission method of an organic EL includes two types, that is, “phosphorescence” that is light emission when the organic EL returns from a triplet excited state to a ground state, and “fluorescence” that is light emission when the organic EL element returns from a singlet excited state to the ground state.

In a case of excitation with an electric field like the organic EL, a triplet exciton is generated with a probability of 75%, and a singlet exciton is generated with a probability of 25%. Therefore, phosphorescence can make luminous efficiency higher than fluorescence, and is an excellent method for achieving low power consumption.

Meanwhile, also in fluorescence, a method utilizing a triplet-triplet annihilation (TTA) or triplet-triplet fusion (abbreviated as TTF) mechanism that generates one singlet exciton from two triplet excitons to improve luminous efficiency by presence in high density of the triplet excitons that are generated with a probability of 75% and that normally converts energy thereof only into heat due to nonradiative deactivation has been found.

Furthermore, in recent years, Adachi et al, have found a phenomenon in which by reducing an energy gap between a singlet excited state and a triplet excited state, inverse intersystem crossing from a triplet excited state having a low energy level to a singlet excited state occurs due to Joule heat during light emission or ambient temperature at which a light emitting element is placed, and nearly 100% fluorescence emission is possible as a result (also referred to as thermally excited delayed fluorescence or thermally excited delayed fluorescence (“TADF”)), and a fluorescent substance making this phenomenon possible (see, for example, Patent Literature 3 and Non Patent Literatures 1 and 2).

<Phosphorescent Compound>

As described above, phosphorescence is theoretically three times more advantageous than fluorescence in terms of luminous efficiency. However, energy deactivation (=phosphorescence) from a triplet excited state to a singlet ground state is forbidden transition. Furthermore, similarly, intersystem crossing from the singlet excited state to the triplet excited state is also forbidden transition, and therefore a rate constant thereof is normally small. That is, since transition hardly occurs, the lifetime of an exciton is prolonged from millisecond-order to second-order, and it is difficult to obtain desired light emission.

However, in a case where a complex using a heavy metal such as iridium or platinum emits light, a rate constant of the forbidden transition increases by three orders of magnitude or more due to a heavy atom effect of a central metal, and it is also possible to obtain a phosphorescence quantum yield of 100% by selecting a certain ligand.

<Fluorescent Compound>

A general fluorescent compound does not particularly need to be a heavy metal complex unlike a phosphorescent compound. A so-called organic compound formed of a combination of general elements such as carbon, oxygen, nitrogen, and hydrogen can be applied to the fluorescent compound. In addition, another nonmetallic element such as phosphorus, sulfur, or silicon can also be used, and a complex of a typical metal such as aluminum or zinc can also be utilized. Diversity of the fluorescent compound is almost infinite.

However, in a conventional fluorescent compound, as described above, only 25% of excitons can be applied to light emission, and therefore high-efficiency light emission like phosphorescence cannot be expected.

<Delayed Fluorescent Compound>

[Excited Triplet-Triplet Annihilation (TTA) Delayed Fluorescent Compound]

In order to solve the problem of the fluorescent compound, a light emission method utilizing delayed fluorescence has appeared. The TTA method originating from collision between triplet excitons can be described by the following general formula. That is, there is an advantage that some of triplet excitons that conventionally convert energy thereof only into heat due to nonradiative deactivation can cause inverse intersystem crossing to singlet excitons that can contribute to light emission. Even an actual organic EL element can obtain external extraction quantum efficiency about twice a conventional fluorescent light emitting element.

General formula: T*+T*→S*+S (In the formula, T* represents a triplet exciton, S* represents a singlet exciton, and S represents a ground state molecule.

However, as can be seen from the above formula, two triplet excitons generate only one singlet exciton that can be used for light emission. Therefore, in principle, it is impossible to obtain 100% internal quantum efficiency with this system.

[Thermally Activated Delayed Fluorescent (TADF) Compound]

The TADF method which is another type of high-efficiency fluorescence can solve the problem of TTA.

A fluorescent compound has an advantage of infinite molecular design as described above. That is, among compounds obtained by molecular design, there are compounds specifically having an extremely close energy level difference between a triplet excited state and a singlet excited state.

Despite absence of a heavy atom in a molecule, such a compound causes inverse intersystem crossing from a triplet excited state to a singlet excited state, which cannot normally occur due to a small ΔE_{ST}. Furthermore, a rate constant of deactivation (=fluorescence) from the singlet excited state to a ground state is extremely large. Therefore, it is kinetically more advantageous for a triplet exciton itself to return to the ground state while emitting fluorescence via a singlet excited state than to be thermally deactivated (nonradiative deactivation) to the ground state. Therefore, TADF theoretically makes 100% fluorescence possible.

Next, the organic EL element of the present invention will be described in detail.

[Organic EL Element]

The organic EL element of the present invention includes a positive electrode, a negative electrode, and an organic layer sandwiched between the positive electrode and the negative electrode and including at least a light emitting layer.

The organic layer may include only a light emitting layer or may include one or more other layers in addition to the light emitting layer. Examples of the other layers include a hole transport layer, a hole injection layer, an electron blocking layer, a hole blocking layer, an electron injection layer, an electron transport layer, and an exciton blocking layer. The hole transport layer may be a hole injection transport layer having a hole injecting function, and the electron transport layer may be an electron injection transport layer having an electron injecting function.

The light emitting layer includes a first organic compound, and the light emitting layer or any other layer (positive electrode, negative electrode, or another layer) includes a second organic compound.

When the first organic compound is a delayed fluophor, the first organic compound and the second organic compound satisfy the following formula (a). When the first organic compound is a phosphorescent compound, the first organic compound and the second organic compound satisfy the following formula (b).
Formula (a): ES1(A)>ES1(B)
Formula (b): ET1(A)>ES1(B)
(In formula (a),
ES1(A) represents a lowest excited singlet energy level of the first organic compound, and
ES1(B) represents a lowest excited singlet energy level of the second organic compound.
In formula (b),
ET1(A) represents a lowest excited triplet energy level of the first organic compound at 77 K, and
ES1(B) represents a lowest excited singlet energy level of the second organic compound.)

The first organic compound is a delayed fluophor satisfying the formula (a) or a phosphorescent compound satisfying the formula (b), and can transfer excitation energy of the first organic compound generated by recombination of a hole and an electron injected into the light emitting layer to the second organic compound with a small loss. The second organic compound is a light emitter arid emits fluorescence with the energy received from the first organic compound.

The light emitting layer preferably further includes a third organic compound from a viewpoint of transferring energy efficiently and easily converting energy into light emission to enhance luminous efficiency.

When the first organic compound is a delayed fluophor, the first organic compound and the third organic compound satisfy the following formulas (a)′ and (c)′. When the first organic compound is a phosphorescent compound, the first organic compound and the third organic compound satisfy the following formula (c)′.
Formula (a)′: ES1(C)>ES1(A)
Formula (c)′: ET1(C)>ET1(A)
(In formula (a)′,
ES1(C) represents a lowest excited singlet energy level of the third organic compound, and
ES1(A) represents a lowest excited singlet energy level of the first organic compound.
In formula (c)′,
ET1(C) represents a lowest excited triplet energy level of the third organic compound at 77 K, and
ET1(A) represents a lowest excited triplet energy level of the first organic compound at 77 K).

When the first organic compound is a delayed fluophor, the third organic compound satisfies the formulas (a′) and (c)′. When the first organic compound is a phosphorescent compound, the third organic compound satisfies the formula (c)′. Therefore, the third organic compound has a function as a transport material for transporting a carrier, a function as a host compound, and a function of confining energy of the first organic compound in the compound. As a result, the second organic compound can efficiently convert the energy generated by recombination of a hole and an electron in a molecule and energy received from the first organic compound and the third organic compound into light emission.

The lowest excited singlet energy level ES1 and the lowest excited triplet energy level ET1 can be measured by the following methods.

(Lowest Excited Singlet Energy Level ES1)

A compound to be measured is vapor-deposited on a Si substrate to prepare a sample, and a fluorescence spectrum of this sample is measured at room temperature (300 K). In the fluorescence spectrum, the vertical axis represents light emission, and the horizontal axis represents a wavelength. A tangent is drawn to a trailing edge of this emission spectrum on a short wave side, and a wavelength value λedge [nm] at an intersection between the tangent and the horizontal axis is determined. This wavelength value is converted into an energy value by the following conversion formula, and the value thus obtained is referred to as ES1.

Conversion formula: ES1[eV]=1239.85/λedge

For measurement of an emission spectrum, a nitrogen laser (MNL 200 manufactured by Lasertechnik Berlin) is used as an excitation light source, and a streak camera (C4334 manufactured by Hamamatsu Photonics KK) is used as a detector.

(Lowest Excited Triplet Energy Level ET1)

The same sample as the sample used for the singlet energy ES1 is cooled to 77 [K]. The sample for phosphorescence measurement is irradiated with excitation light (337 nm) to measure phosphorescence intensity using a streak camera. A tangent is drawn to a rising edge of this phosphorescence spectrum on a short wave side, and a wavelength value λedge [nm] at an intersection between the tangent and the horizontal axis is determined. This wavelength value is converted into an energy value by the following conversion formula, and the value thus obtained is referred to as ET1.

Conversion formula: ET1[eV]=1239.85/λedge

Next, the first organic compound, the second organic compound, and the third organic compound will be specifically described.

[First Organic Compound]

The first organic compound is a delayed fluophor or a phosphorescent compound having lowest excited singlet energy and lowest excited triplet state energy larger than the second organic compound. An emission spectrum of the first organic compound preferably overlaps with an absorption spectrum of the second organic compound in order to enhance the luminous efficiency of an organic EL element and to reduce a change in resistance value over time during passage of a current.

A delayed fluophor used as the first organic compound is not particularly limited, but is preferably a thermally activated delayed fluophor that causes inverse intersystem crossing from an excited triplet state to an excited singlet state by absorption of thermal energy. The thermally activated delayed fluophor absorbs heat generated by a device, relatively easily causes inverse intersystem crossing from an excited triplet state to an excited singlet state, and can make the excited triplet energy efficiently contribute to light emission.

The delayed fluophor is a compound exhibiting delayed fluorescence. The phrase “exhibiting delayed fluorescence” means that there are two or more components having different attenuation rates of fluorescence emitted when fluorescence attenuation measurement is performed. Incidentally, in general, a component that slowly attenuates often has attenuation time of submicroseconds or more. However, the attenuation time varies depending on a material, and therefore the attenuation time is not limited.

Fluorescence attenuation measurement can be generally performed as follows. That is, a solution or a thin film of a compound to be measured or a co-vapor-deposited film of a compound to be measured and a second component is irradiated with excitation light under a nitrogen atmosphere, and the number of photons each having a certain emission wavelength is measured. At this time, it is assumed that the compound to be measured exhibits delayed fluorescence in a case where there are two or more components having different attenuation rates of emitted fluorescence.

In addition, in the delayed fluophor, a difference ΔE_{ST} between a lowest excited singlet state energy level ES1(A) and a lowest excited triplet state energy level ET1(A) is preferably 0.3 eV or less, more preferably 0.2 eV or less, still more preferably 0.1 eV or less, and further still more preferably 0.08 eV or less. A delayed fluophor having the energy difference ΔE_{ST} within the above range causes inverse intersystem crossing from an excited triplet state to an excited singlet state relatively easily, and can make the excited triplet energy efficiently contribute to light emission.

The ΔE_{ST} of the delayed fluophor can be determined by applying the lowest excited singlet energy level ES1(A) and the lowest excited triplet energy level ET1(A) at 77 K to the following formula.

ΔE_{ST}|ES1(A)−ET1(A)|

The delayed fluophor used as the first organic compound is not particularly limited as long as being able to emit delayed fluorescence, but is preferably a compound having a donor site and an acceptor site. Examples of a skeleton serving as an acceptor site include a benzene skeleton substituted with one or more cyano groups, an anthracene-9,10-dione skeleton, a dibenzo [a,j]phenazine skeleton, a 2,3-dicyanopyrazinofenanthrene skeleton, and a triazine skeleton. Examples of a skeleton serving as a donor site include an optionally substituted carbazolyl group, an optionally substituted diarylamino group, an aryl group substituted with a diarylamino group, and an optionally substituted phenoxazinyl group.

Specific preferable examples of the delayed fluophor include delayed fluophors described in JP 5669163 B2, J. Am. Chem. Soc. 2014, 136, 18070-18081, Adv. Mater. 2013, 25, 3319-3323, Angew. Chem. Int. Ed. 2016, 55, 5739-5744, and Angew. Chem. Int. Ed. 2015, 54, 13068-13072. Among these delayed fluophors, compounds represented by general formula (212) (paragraph 0135) and general formula (131) (paragraph 0064) in JP 5669163 B2, compound T-2 described in Angew. Chem. Int. Ed. 2016, 55, 5739-5744, compound T-3 described in J. Am. Chem. Soc. 2014, 136, 18070-18081, and compound T-4 described in Angew. Chem. Int. Ed. 2015, 54, 13068-13072. can be cited.

Among these compounds, preferable examples of the delayed fluophor include the following compounds.

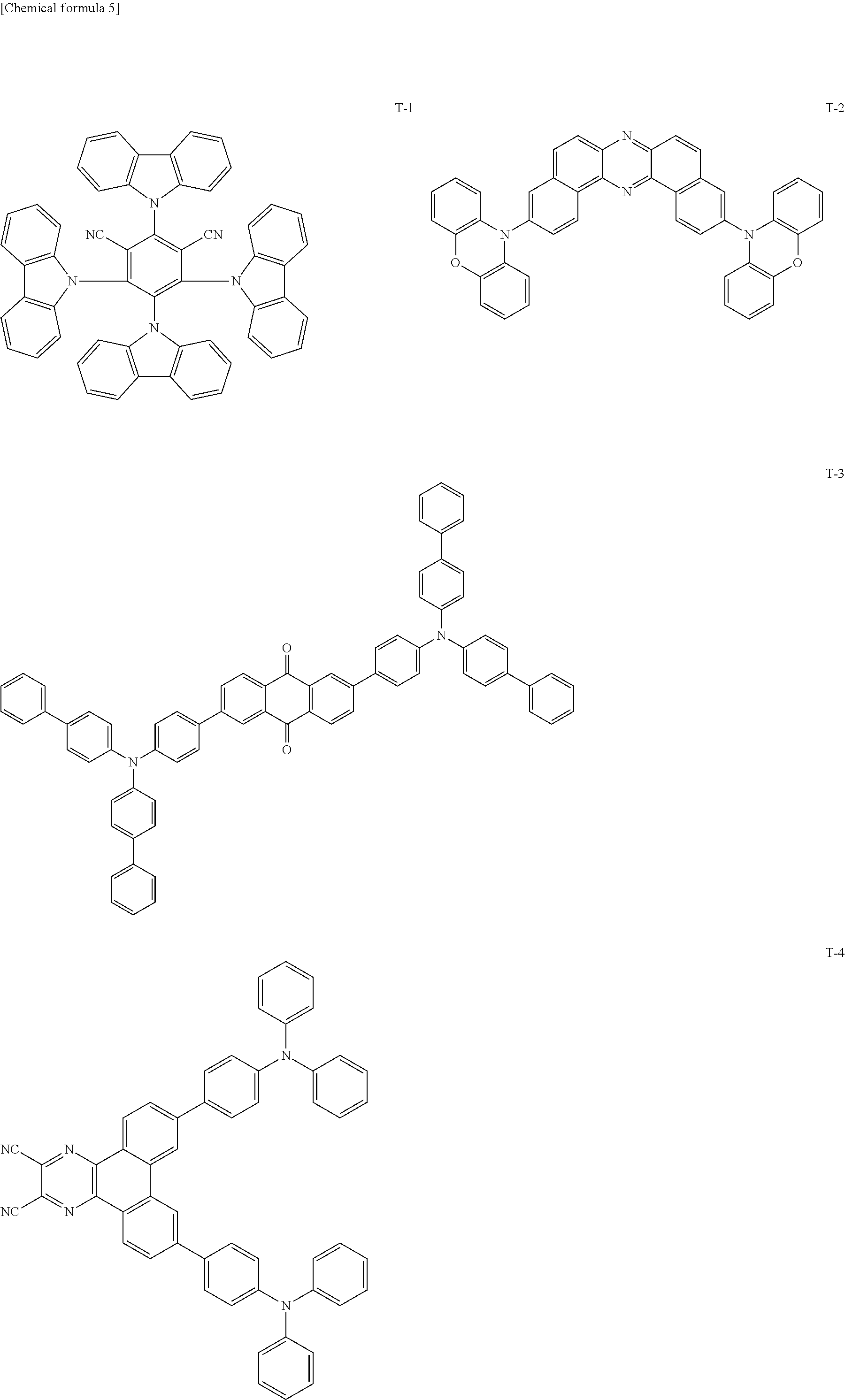 [SMILES: N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21 ; c1ccc2c(c1)Oc1ccccc1N2c1ccc2c(ccc3nc4ccc5cc(N6c7ccccc7Oc7ccccc76)ccc5c4nc32)c1 ; O=C1c2ccc(-c3ccc(N(c4ccc(-c5ccccc5)cc4)c4ccc(-c5ccccc5)cc4)cc3)cc2C(=O)c2ccc(-c3ccc(N(c4ccc(-c5ccccc5)cc4)c4ccc(-c5ccccc5)cc4)cc3)cc21 ; N#Cc1nc2c3ccc(-c4ccc(N(c5ccccc5)c5ccccc5)cc4)cc3c3cc(-c4ccc(N(c5ccccc5)c5ccccc5)cc4)ccc3c2nc1C#N]

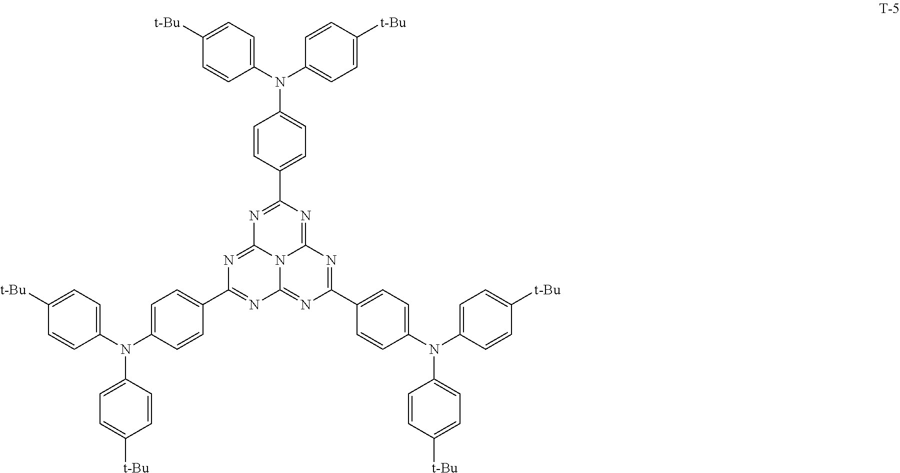 [SMILES: CC(C)(C)c1ccc(N(c2ccc(C3=NC4=NC(c5ccc(N(c6ccc(C(C)(C)C)cc6)c6ccc(C(C)(C)C)cc6)cc5)=NC5=NC(c6ccc(N(c7ccc(C(C)(C)C)cc7)c7ccc(C(C)(C)C)cc7)cc6)=NC(=N3)N45)cc2)c2ccc(C(C)(C)C)cc2)cc1]

The phosphorescent compound used as the first organic compound is not particularly limited, but is preferably a complex using a heavy metal such as iridium or platinum.

The phosphorescent compound used in the present invention is a compound in which light emission from an excited triplet is observed, and is specifically defined as a compound that emits phosphorescence at room temperature (25° C.) and has a phosphorescence quantum yield of 0.01 or more at 25° C. The phosphorescence quantum yield of the phosphorescent compound is preferably 0.1 or more.

The phosphorescence quantum yield can be measured by a method described in Spectroscopy II of the fourth edition of Experimental Chemistry Course 7, p. 398 (1992 edition, Maruzen). The phosphorescence quantum yield in a solution can be measured using various solvents. However, the phosphorescent compound used in the present invention only needs to achieve the above phosphorescence quantum yield (0.01 or more) in any solvent.

The phosphorescent compound can be appropriately selected for use from among known compounds used for a light emitting layer of an organic EL element. Specific examples of the known phosphorescent compound that can be used in the present invention include compounds described in the following literatures.

Nature 395, 151 (1998), Appl. Phys. Lett. 78, 1622 (2001), Adv. Mater. 19, 739 (2007), Chem. Mater. 17, 3532 (2005), Adv. Mater. 17, 1059 (2005), WO 2009/100991 A, WO 2008/101842 A, WO 2003/040257 A, US 2006/835469 A, US 2006/0202194 A, US 2007/0087321 A, US 2005/0244673 A. Inorg. Chem. 40, 1704 (2001), Chem. Mater. 16, 2480 (2004), Adv. Mater. 16, 2003 (2004), Angew. Chem. Int. Ed. 2006, 45, 7800, Appl. Phys. Lett. 86, 153505 (2005), Chem. Lett. 34, 592(2005), Chem. Commun. 2906 (2005), Inorg. Chem. 42, 1248 (2003), WO 2009/050290 A, WO 2002/015645 A, WO 2009/000673 A, US 2002/0034656 A, U.S. Pat. No. 7,332,232, US 2009/0108737 A, US 2009/0039776 A, U.S. Pat. No. 6,921,915, 6,687,266, US 2007/0190359 A, US 2006/0008670 A, US 2009/0165816 A, US 2008/0015355 A, U.S. Pat. No. 7,250,226, 7,396,598, US 2006/0263635 A, US 2003/0138657 A, US 2003/0152802 A, U.S. Pat. No. 7,090,928, Angew. Chem. Int. Ed. 47, 1 (2008), Chem. Mater. 18, 5119 (2006), Inorg. Chem. 46, 4308 (2007), Organometallics 23, 3745 (2004), Appl. Phys. Lett. 74, 1361 (1999), WO 2002/002714 A, WO 2006/009024 A, WO 2006/056418 A, WO 2005/019373 A, WO 2005/123873 A, WO 2005/123873 A, WO 2007/004380 A, WO 2006/082742 A, US 2006/0251923 A, US 2005/0260441 A, U.S. Pat. No. 7,393,599, 7,534,505, 7,445,855, US 2007/0190359 A, US 2008/0297033 A, U.S. Pat. No. 7,338,722, US 2002/0134984 A, US 7279704, US 2006/098120 A, US 2006/103874 A, WO 2005/076380 A, WO 2010/032663 A, WO 2008140115 A, WO 2007/052431 A, WO 2011/134013 A, WO 2011/157339 A, WO 2010/086089 A, WO 2009/113646 A, WO 2012/020327 A, WO 2011/051404 A, WO 2011/004639 A, WO 2011/073149 A, US 2012/228583 A, US 2012/212126 A, JP 2012-069737 A, JP 2011-181303 A, JP 2009-114086 A, JP 2003-81988 A, JP 2002-30267 I. A, JP 2002-363552 A, Dyes and Pigments. 131, 231 (2016), J. Mater. Chem. C, 4, 3492 (2016), Chem. Mater. 23, 5305 (2011), and the like.

Among these compounds, a preferable phosphorescent compound is a complex including at least one coordination mode selected from a metal-carbon bond, a metal-nitrogen bond, a metal-oxygen bond, and a metal-sulfur bond. Examples of such a complex include the following compounds T-6 and T-7.

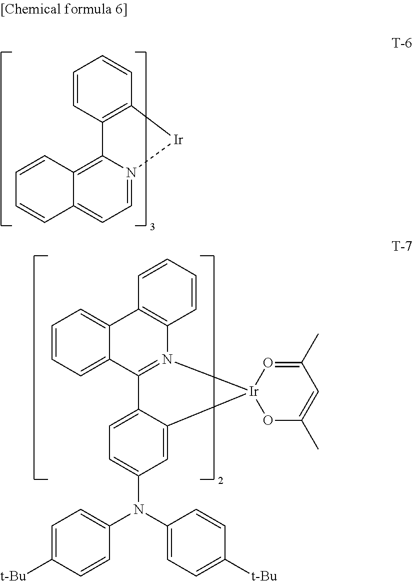

Among these compounds, the first organic compound is preferably a delayed fluophor because existence time in the lowest excited triplet state energy state is short and the lifetime of an element can be easily prolonged.

[Second Organic Compound]

The second organic compound transits to a singlet excited state upon receiving excitation energy from the first organic compound or the third organic compound, and then emits fluorescence when returning to a ground state. Two or more kinds of second organic compounds may be used. For example, by using two or more kinds of second organic compounds having different emission colors in combination, a desired color can be emitted.

An emission color of the second organic compound is a near-infrared color. Specifically, a maximum emission wavelength in a fluorescence spectrum of the second organic compound is within a range of 700 nm to 1000 nm. However, in a case where two or more kinds of second organic compound are included, the maximum emission wavelength of a fluorescence spectrum of each of the compounds is assumed to be within the above-described range.

The emission color of the second organic compound can be confirmed by the following method.

(Measurement of Fluorescence Spectrum)

1% by mass of the second organic compound and 99% by mass of CBP are vapor-deposited on a Si substrate to prepare a sample, and a fluorescence spectrum of this sample is measured at room temperature (300 K).

For measurement of the emission spectrum, a nitrogen laser (MNL 200 manufactured by Lasertechnik Berlin) is used as an excitation light source, and a spectral radiance meter CS-2000 (manufactured by Konica Minolta, Inc.) is used as a detector.

When a maximum emission wavelength is within a range of 700 nm to 1000 nm, an emission color is judged to be a near-infrared color.

Incidentally, it has already been continued that a fluorescence spectrum confirmed in this measurement is almost similar to air emission spectrum confirmed in an organic EL element (for example, an organic EL element prepared in Examples described later) including a corresponding second organic compound (only one kind of second organic compound).

The second organic compound has a structure represented by the following general formula (1) or (2). The second organic compound represented by the following general formula (1) or (2) exhibits a high absorption coefficient, and therefore can efficiently receive excitation energy from the first organic compound or the third organic compound.

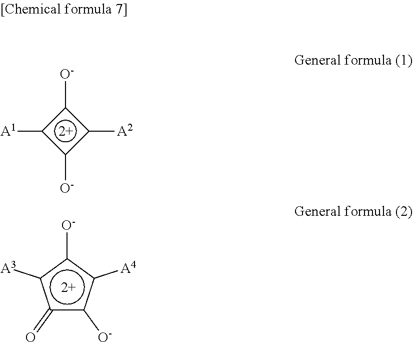

In general formulas (1) and (2), A¹ to A⁴ each independently represent a substituent having a sp2 carbon atom at a bonding site. In general formula (1), A¹ and A² may be the same as or different from each other. In general formula (2), A² and A⁴ may be the same as or different from each other.

Examples of the substituent include an aryl group, a heterocyclic group, and a substituted or unsubstituted methine group. The substituent is preferably a group containing an aryl group or a heterocyclic group, and more preferably an aryl group, a heterocyclic group, or a methine group substituted with an aryl group or a heterocyclic group from a viewpoint of spreading a π a corrugated system to facilitate near-infrared emission.

The aryl group is preferably a substituted or unsubstituted aryl group having 6 to 30 carbon atoms, and examples thereof include a phenyl group, a naphthyl group, an anthryl group, a p-chlorophenyl group, a mesityl group, a tolyl group, a xylyl group, an azulenyl group, an acenaphthenyl group, a fluorenyl group, a phenanthryl group, an indenyl group, a pyrenyl group, and a biphenylyl group.

The heterocyclic group is preferably a monovalent group obtained by removing one hydrogen atom from a 5- or 6-membered substituted or unsubstituted aromatic or nonaromatic heterocyclic compound, and more preferably a 5- or 6-membered aromatic heterocyclic group having 3 to 30 carbon atoms. Examples of the heterocyclic group include a pyridyl group, a pyrimidinyl group, a furyl group, a thienyl group, a pyrrolyl group, an imidazolyl group, a benzimidazolyl group, a pyrazolyl group, a benzopyrazolyl group, a pyrazinyl group, a triazolyl group (for example, a 1,2,4-triazol-1-yl group or a 1,2,3-triazol-1-yl group), an oxazolyl group, a benzexazolyl group, a thiazolyl group, an isoxazolyl group, an isothiazolyl group, a furazanyl group, a thienyl group, a quinolyl group, a benzofuryl group, a benzothienyl group, a dibenzofuryl group, a benzothienyl group, a dibenzothienyl group, an indolyl group, a carbazolyl group, a carbolinyl group, a diazacarbazolyl group (indicating a group in which one of carbon atoms constituting a carboline ring of the carbolinyl group is substituted with a nitrogen atom), a quinoxalinyl group, a pyridazinyl group, a triazinyl group, a quinazolinyl group, a phthalazinyl group, and the like), and a heterocyclic group (for example, a pyrrolidyl group, an imidazolidyl group, a morpholyl group, or an oxazolidyl group).

Examples of the substituent included in the aryl group and the heterocyclic group include an alkyl group (for example, a methyl group, an ethyl group, a propyl group, an isopropyl group, a tert-butyl group, a pentyl group, a hexyl group, an octyl group, a dodecyl group, a tridecyl group, a tetradecyl group, or a pentadecyl group), a cycloalkyl group (for example, a cyclopentyl group or a cyclohexyl group), an alkenyl group (for example, a vinyl group or an allyl group), an alkynyl group (for example, an ethynyl group or a propargyl group), an aromatic hydrocarbon group (also referred to as an aromatic hydrocarbon ring group, an aromatic carbocyclic group, an aryl group, or the like, and examples thereof include a phenyl group, a p-chlorophenyl group, a mesityl group, a tolyl group, a xylyl group, a naphthyl group, an anthryl group, an azulenyl group, an acenaphthenyl group, a fluorenyl group, a phenanthryl group, an indenyl group, a pyrenyl group, and a biphenylyl group), an aromatic heterocyclic group (for example, a pyridyl group, a pyrimidinyl group, a furyl group, a pyrrolyl group, an imidazolyl group, a benzimidazolyl group, a pyrazolyl group, a pyrazinyl group, a triazolyl group (for example, a 1,2,4-triazol-1-yl group or a 1,2,3-triazol-1-yl group), a pyrazolotriazolyl group, an oxazolyl group, a benzoxazolyl group, a thiazolyl group, an isoxazolyl group, an isothiazolyl group, a furazanyl group, a thienyl group, a quinolyl group, a benzofuryl group, a dibenzofuryl group, a benzothienyl group, a dibenzothienyl group, an indolyl group, a carbazolyl group, a carbolinyl group, a diaza carbozolyl group (indicating a group in which one of carbon atoms constituting a carboline ring of the carbolinyl group is substituted with a nitrogen atom), a quinoxalinyl group, a pyridazinyl group, a triazinyl group, a quinazolinyl group, or a phthalazinyl group), a heterocyclic group (for example, a pyrrolidyl group, an imidazolidyl group, a morpholyl group, or an oxazolidyl group), an alkoxy group (for example, a methoxy group, an ethoxy group, a propyloxy group, a pentyloxy group, a hexyloxy group, an octyloxy group, or a dodecyloxy group), a cycloalkoxy group (for example, a cyclopentyloxy group or a cyclohexyloxy group), an aryloxy group (for example, a phenoxy group or a naphthyloxy group), an ankylthio group (for example, a methylthio group, an ethylthio group, a propylthio group, a pentylthio group, a hexylthio group, an octylthio group, or a dodecylthio group), a cyclolalkylthio group (for example, a cyclopentylthio group or a cyclohexylthio group), an arylthio group (for example, a phenylthio group or a naphthylthio group), an alkoxycarbonyl group (for example, a methyloxycarbonyl group, an ethyloxycarbonyl group, a butyloxycarbonyl group, an octyloxycarbonyl group, or a dodecyloxycarbonyl group), an aryloxycarbonyl group (for example, a phenyloxycarbonyl group or a naphthyloxycarbonyl group), a sulfamoyl group (for example, an aminosulfonyl group, a methylaminosulfonyl group, a dimethylaminosulfonyl group, a butylaminosulfonyl group, a hexylaminosulfonyl group, a cyclohexylaminosulfonyl group, an octylaminosulfonyl group, a dodecylaminosulfonyl group, a phenylaminosulfonyl group, a naphthylaminosulfonyl group, or a 2-pyridylaminosulfonyl group), an acyl group (for example, an acetyl group, an ethylcarbonyl group, a propylcarbonyl group, a pentylcarbonyl group, a cyclohexylcarbonyl group, an octylcarbonyl group, a 2-ethylhexylcarbonyl group, a dodecylcarbonyl group, a phenylcarbonyl group, a naphthylcarbonyl group, or a pyridylcarbonyl group), an acyloxy group (for example, an acetyloxy group, an ethylcarbonyloxy group, a butylcarbonyloxy group, an octylcarbonyloxy group, a dodecylcarbonyloxy group, or a phenylcarbonyloxy group), an amido group (for example, a methylcarbonylamino group, an ethylcarbonylamino group, a dimethylcarbonylamino group, a propylcarbonylamino group, a pentylcarbonylamino group, a cyclohexylcarbonylamino group, a 2-ethylhexylcarbonylamino group, an octylcarbonylamino group, a dodecylcarbonylamino group, a phenylcarbonylamino group, or a naphthylcarbonylamino group), a carbamoyl group (for example, an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecylaminocarbonyl group, a phenylaminocarbonyl group, a naphthylaminocarbonyl group, or a 2-pyridylaminocarbonyl group), a ureido group (for example, a methylureido group, an ethylureido group, a pentylureido group, a cyclohexylureido group, an octylureido group, a dodecylureido group, a phenylureido group, a naphthylureido group, or a 2-pyridylaminoureido group), a sulfinyl group (for example, a methylsulfinyl group, an ethylsulfinyl group, a butylsulfinyl group, a cyclohexylsulfinyl group, a 2-ethylhexylsulfinyl group, a dodecylsulfinyl group, a phenylsulfinyl group, a naphthylsulfinyl group, or a 2-pyridylsulfinyl group), an alkylsulfonyl group (for example, a methylsulfonyl group, an ethylsulfonyl group, a butylsulfonyl group, a cyclohexylsulfonyl group, a 2-ethylhexylsulfonyl group, or a dodecylsulfonyl group), an arylsulfonyl group or a heteroarylsulfonyl group (for example, a phenylsulfonyl group, a naphthylsulfonyl group, or a 2-pyridylsulfonyl group), an amino group (for example, an amino group, an ethylamino group, a dimethylamino group, a diphenylamino group, a diisopropylamino group, a ditertbutyl group, a cyclohexylamino group, a butylamino group, a cyclopentylamino group, a 2-ethylhexylamino group, a dodecylamino group, an anilino group, a naphthylamino group, or a 2-pyridylamino group), a halogen atom (for example, a fluorine atom, a chlorine atom, or a bromine atom), a fluorohydrocarbon group (for example, a fluoromethyl group, a trifluoromethyl group, a pentafluoroethyl group, or a pentafluorophenyl group), a cyano group, a nitro group, a hydroxy group, a mercapto group, a silyl group (for example, a trimethylsilyl group, a triisopropylsilyl group, a triphenylsilyl group, or a phenyldiethylsilyl group), and a phosphono group. Preferable examples thereof include an alkyl group, an aromatic hydrocarbon group, an aromatic heterocyclic group, an alkoxy group, an amino group, and a hydroxy group.

In addition, these substituents may be further substituted with the above substituents.

The substituted or unsubstituted methine group is preferably a group represented by —CR⁶⁶═R⁶⁷.

R⁶⁶ is a hydrogen atom or an alkyl group. The alkyl group is preferably a methyl group. R⁶⁷ is a substituent. The substituent is preferably an alkyl group (preferably a substituted or unsubstituted alkyl group having 1 to 5 carbon atoms, for example, methyl, ethyl, propyl, butyl, benzyl, or phenethyl), an aryl group (preferably a substituted or unsubstituted aryl group having 6 to 30 carbon atoms, for example, phenyl, p-tolyl, or naphthyl), a heterocyclic group (preferably a 5- or 6-membered aromatic heterocyclic group having 3 to 30 carbon atoms), or the like. In a case of a methine group to which a heterocyclic group is bonded (in a case where R⁶⁷ is a heterocyclic group), a carbon atom in the heterocyclic ring is preferably bonded to the methine group.

A¹ to A⁴ preferably each independently represent a group selected from the group consisting of the following (a) to (l).

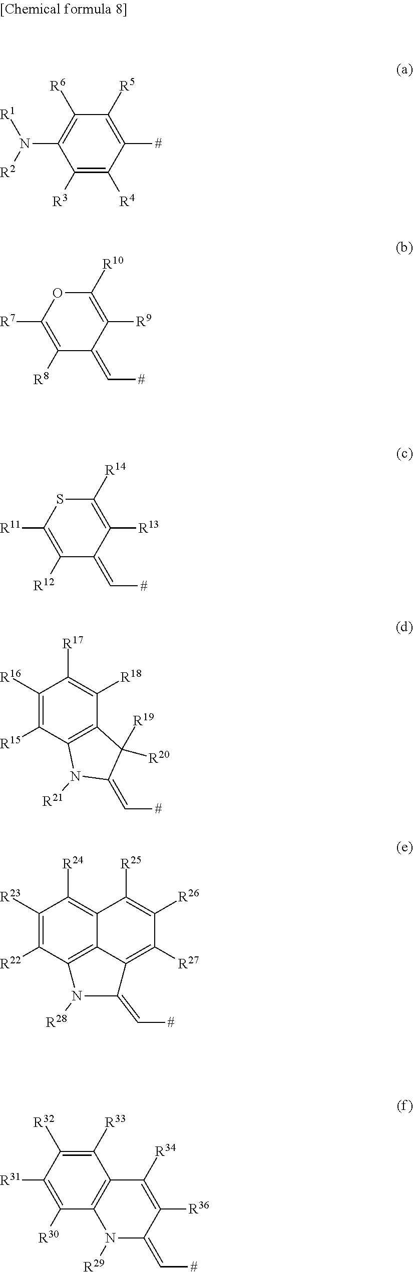

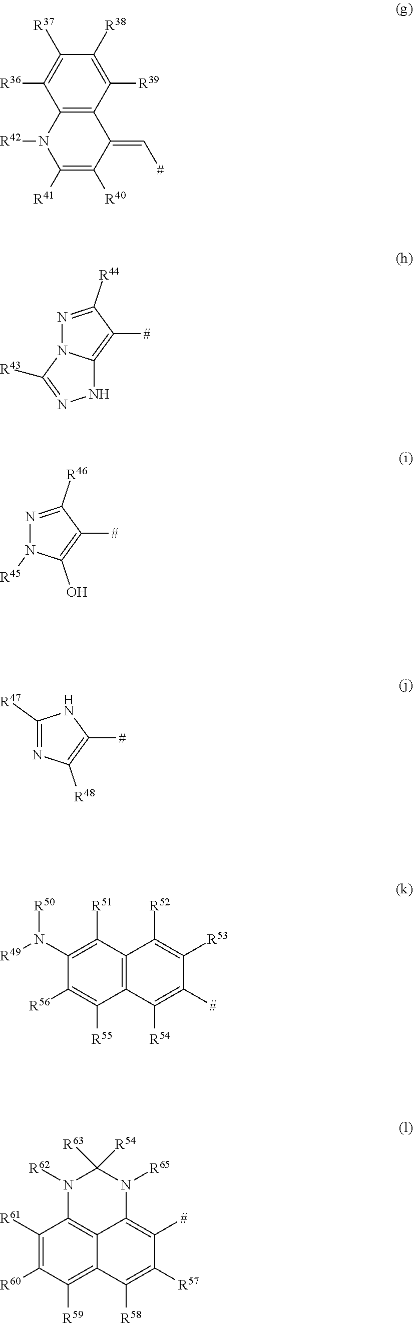

In formulas (a) to (l), R¹ to R⁶⁵ each independently represent a hydrogen atom a substituent. # represents a bond to general formula (1) or (2).

Description and preferable ranges of the substituents represented by R¹ to R⁶⁵ are similar to the description and preferable ranges of the substituents included in the aryl group and the heterocyclic group. Among these groups, an optionally substituted aryl group, an optionally substituted heterocyclic group, an optionally substituted alkoxy group, a hydroxy group, an amido group, and an optionally substituted amino group are preferable.

However, at least one of R¹⁵ to R¹⁸ in formula (d), at least one of R²² to R²⁷ in formula (e), at least one of R³⁰ to R³⁵ in formula (f), at least one of R³⁶ to R⁴¹ in formula (g), at least one of R⁴³ and R⁴⁴ in formula (h), at least one of R⁴⁵ and R⁴⁶ in formula (i), and at least one of R⁴⁷ and R⁴⁸ in formula (j) each represent an electron-donating group D. As a result, each of the groups represented by formulas (a) to (l) exhibits an adequate donor property, and the central portion of general formula (1) or (2) exhibits an accebtor property. Therefore, the compound represented by general formula (1) or (2) can easily emit near-infrared light (the maximum emission wavelength can easily be set within a range of 700 nm to 1000 nm).

The electron-donating group D may be an “aryl group substituted with an electron-donating group”, an “optionally substituted electron-donating heterocyclic group”, an “optionally substituted amino group” an “optionally substituted alkoxy group”, or an “alkyl group”.

The aryl group in the “aryl group substituted with an electron-donating group” represented by D is preferably a group derived from an aromatic hydrocarbon ring having 6 to 24 carbon atoms. Examples of such an aromatic hydrocarbon ring include a benzene ring, an indene ring, a naphthalene ring, a fluorene ring, a phenanthrene ring, an anthracene ring, an acenaphthylene ring, a biphenylene ring, a naphthacene ring, a triphenylene ring, an as-indacene ring, a chrysene ring, an s-indacene ring, a phenalene ring, a fluoranthene ring, an acephenanthrylene ring, a biphenyl ring, a terphenyl ring, and a tetraphenyl ring. Among these rings, a benzene ring, a naphthalene ring, a fluorene ring, a biphenyl ring, and a terphenyl ring are preferable.

Examples of the electron-donating group included in the aryl group include an alkyl group, an alkoxy group, an optionally substituted amino group, an optionally substituted electron-donating heterocyclic group. Among these groups, an optionally substituted amino group and an optionally substituted electron-donating heterocyclic group are preferable.

The alkyl group may be linear, branched, or cyclic, and may be, for example, a linear or branched alkyl group having 1 to 20 carbon atoms or a cyclic alkyl group having 5 to 20 carbon atoms. Examples of the alkyl group include a methyl group, an ethyl group, a n-propyl group, an isopropyl group, a n-butyl group, a s-butyl group, a t-butyl group, a n-pentyl group, a neopentyl group, a n-hexyl group, a cyclohexyl group, a 2-ethylhexyl group, a n-heptyl group, a n-octyl group, a 2-hexyloctyl group, a n-nonyl group, a n-decyl group, a n-undecyl group, a n-dodecyl group, a n-tridecyl group, a n-tetradecyl group, a n-pentadecyl group, a n-hexadecyl group, a n-heptadecyl group, a n-octadecyl group, a n-nonadecyl group, and a n-eicosyl group. Preferable examples of the alkyl group include a methyl group, an ethyl group, an isopropyl group, a t-butyl group, a cyclohexyl group, a 2-ethylhexyl group, and, a 2-hexyloctyl group.

The alkoxy group may be linear, branched, or cyclic and may be, for example, a linear or branched alkoxy group having 1 to 20 carbon atoms or a cyclic alkoxy group having 6 to 20 carbon atoms. Examples of the alkoxy group include a methoxy group, an ethoxy group, a n-propoxy group, an isopropoxy group, a n-butoxy group, an isobutoxy group, a t-butoxy group, a n-pentyloxy group, a neopentyloxy group, a n-hexyloxy group, a cyclohexyloxy group, a n-heptyloxy group, a n-octyloxy group, a 2-ethylhexyloxy group, a nonyloxy group, a decyloxy group, a 3,7-dimethyloctyloxy group, a n-undecyloxy group, a n-dodecyloxy group, a n-tridecyloxy group, a n-tetradecyloxy group, a 2-n-hexyl-n-octyloxy group, a n-pentadecyloxy group, a n-hexadecyloxy group, a n-heptadecyloxy group, a n octadecyloxy group, a n-nonadecyloxy group, and a n-eicosyloxy group. Preferable examples of the alkoxy group include a methoxy group, an ethoxy group, an isopropoxy group, a t-butoxy group, a cyclohexyl group, a 2-ethylhexyloxy group, and a 2-hexyloctyloxy group.

Examples of the substituent in the optionally substituted amino group include an alkyl group and an aryl group which may be substituted with an alkyl group. The alkyl group and the aryl group are synonymous with the above alkyl group and aryl group (in the aryl group substituted with an electron-donating group), respectively.

Examples of the optionally substituted electron-donating heterocyclic group include a group similar to an electron-donating heterocyclic group described later.

The “electron-donating heterocyclic group” in the “optionally substituted electron-donating heterocyclic group” represented by D is preferably a group derived from an electron-donating heterocyclic ring having 4 to 24 carbon atoms. Examples of such a heterocyclic ring include a pyrrole ring, an indole ring, a carbazole ring, an indoloindole ring, a 9,10-dihydroacridine ring, a phenoxazine ring, a phenothiazine ring, a dibenzothiophene ring, a benzofurylindole ring, a benzothienoindole ring, an indolocarbazole ring, a benzofurylcarbazole ring, a benzothienocarbazole ring, a benzothienobenzothiophene ring, a benzocarbazole ring, a dibenzocarbazole ring, an azacarbazole ring, and a diazacarbazole ring. Among these rings, a carbazole ring, an indoloindole ring, a 9,10-dihydroacridine ring, a phenoxazine ring, a phenothiazine ring, a dibenzothiophene ring, and a benzofurylindole ring are preferable. The electron-donating heterocyclic group may be a group in which two or more of the above same or different heterocyclic rings are bonded via a single bond.

Examples of the substituent that can be included in the heterocyclic group include an alkyl group and an aryl group which may be substituted with an alkyl group. The alkyl group and the aryl group are synonymous with the above alkyl group and aryl group, respectively.

Examples of the substituent in the “optionally substituted amino group” and the “optionally substituted alkoxy group” represented by D include an alkyl group and an aryl group which may be substituted with an alkyl group. The alkyl group and the aryl group may be similar to the above alkyl group and aryl group, respectively.

The “alkyl group” represented by D is synonymous with the above alkyl group.

The number of substituents in each of formulas (a) to (l) is not particularly limited. In a case where there are two or more substituents, these substituents may be the same as or different from each other. Adjacent substituents may be bonded to each other to form a cyclic structure.

A cyclic structure formed by adjacent substituents may be an aromatic ring or an alicyclic ring, may contain a hetero atom, and furthermore may be a condensed ring of two or more rings. The hetero atom mentioned here is preferably selected from the group consisting of a nitrogen atom, an oxygen atom, and a sulfur atom. Examples of the cyclic structure to be formed include a benzene ring, a naphthalene ring, a pyridine ring, a pvridazine ring, a pyrimidine ring, a pyrazine ring, a pyrrole ring, an imidazole ring, a pyrazole ring, a triazole ring, an imidazoline ring, an oxazole ring, an isoxazole ring, a thiazole ring, an isothiazole ring, a cyclohexadiene ring, a cyclohexene ring, a cyclopentaene ring, a cycloheptatriene ring, a cycloheptadiene ring, a cycloheptaene ring, a carbazole ring, and a dibenzofuran ring.

Second organic compounds represented by general formulas (1) and (2) preferably used in the present invention are exemplified below, but the present invention is not limited thereto. Specific examples of a compound represented by general formula (1) are illustrated in compounds D-1 to D-58 and D-65 to D-67, and specific examples of a compound represented by general formula (2) are illustrated in D-59 to D-64.

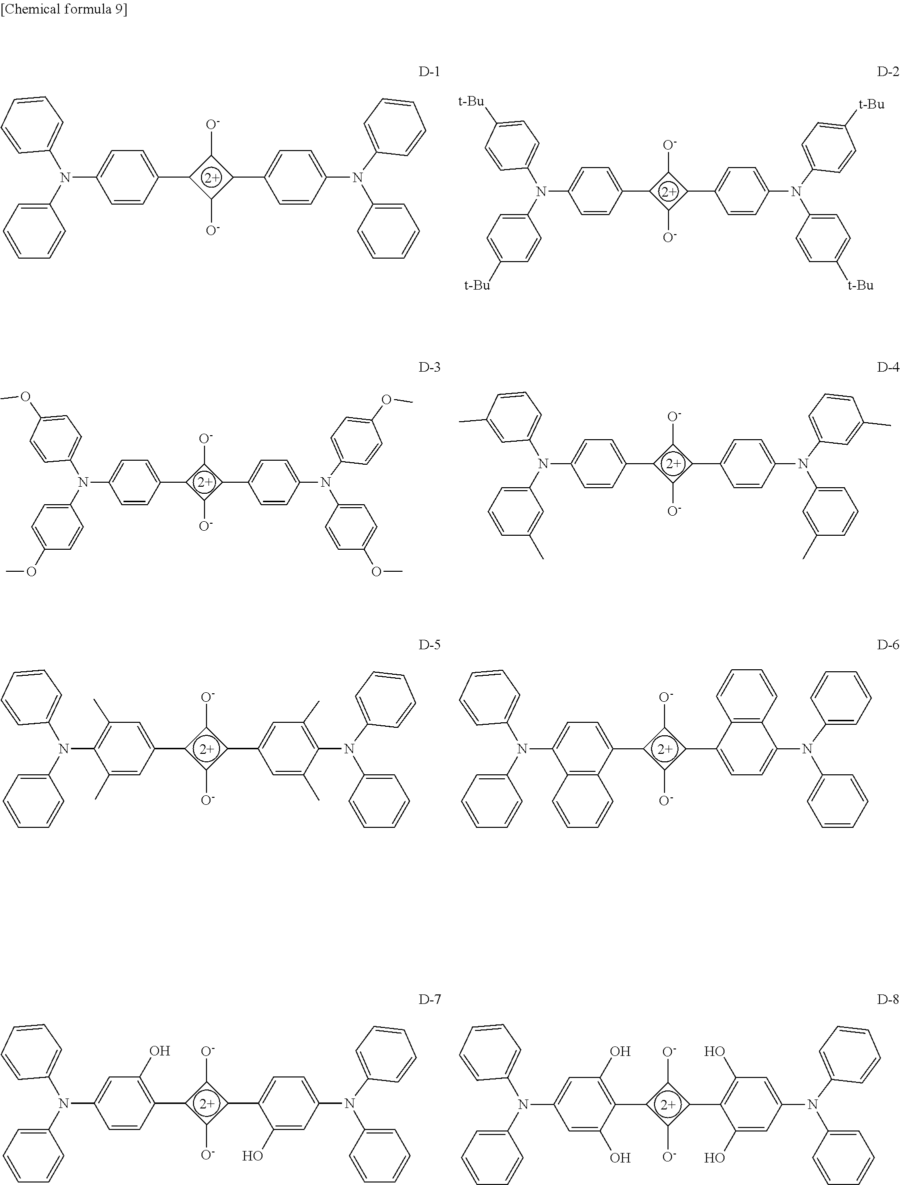

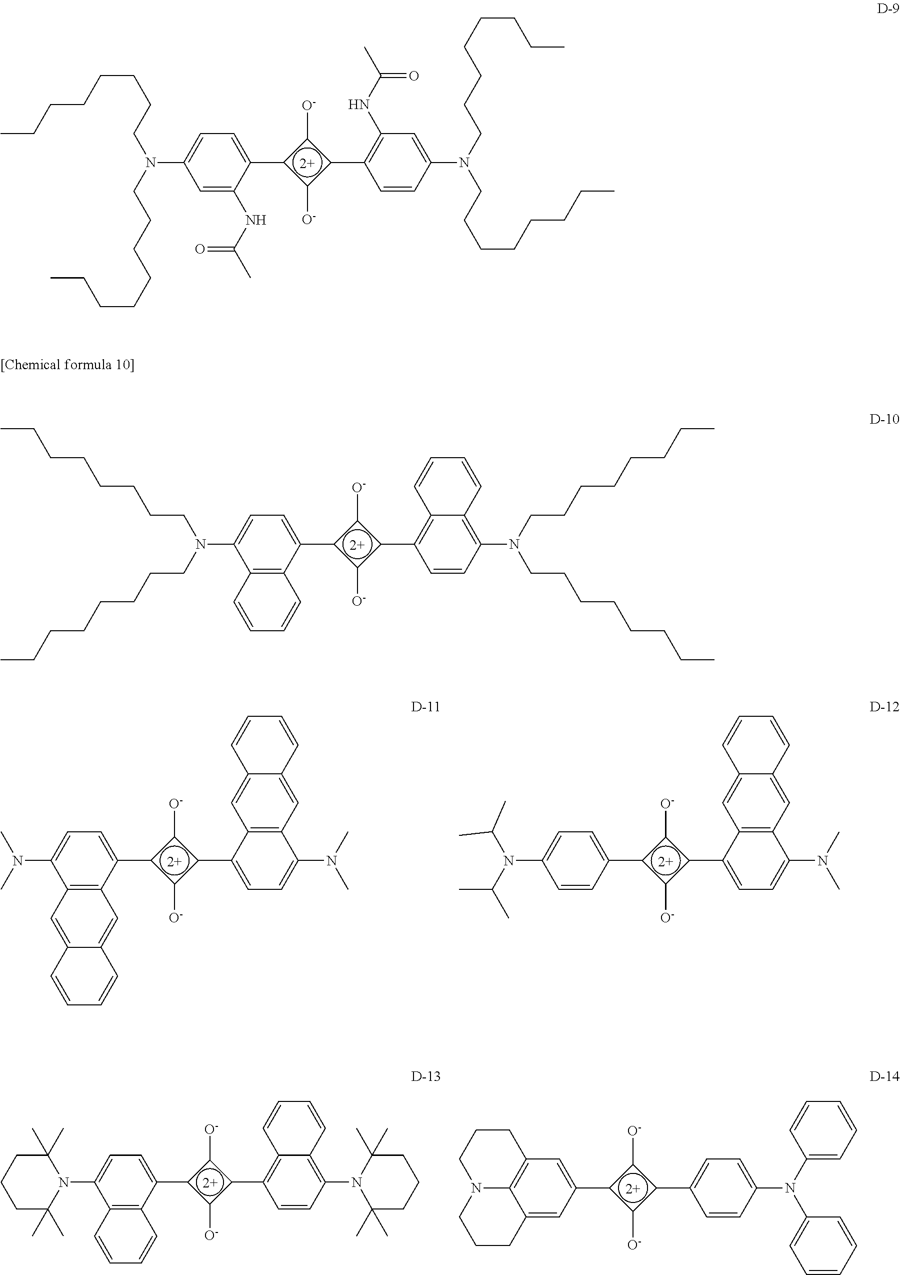

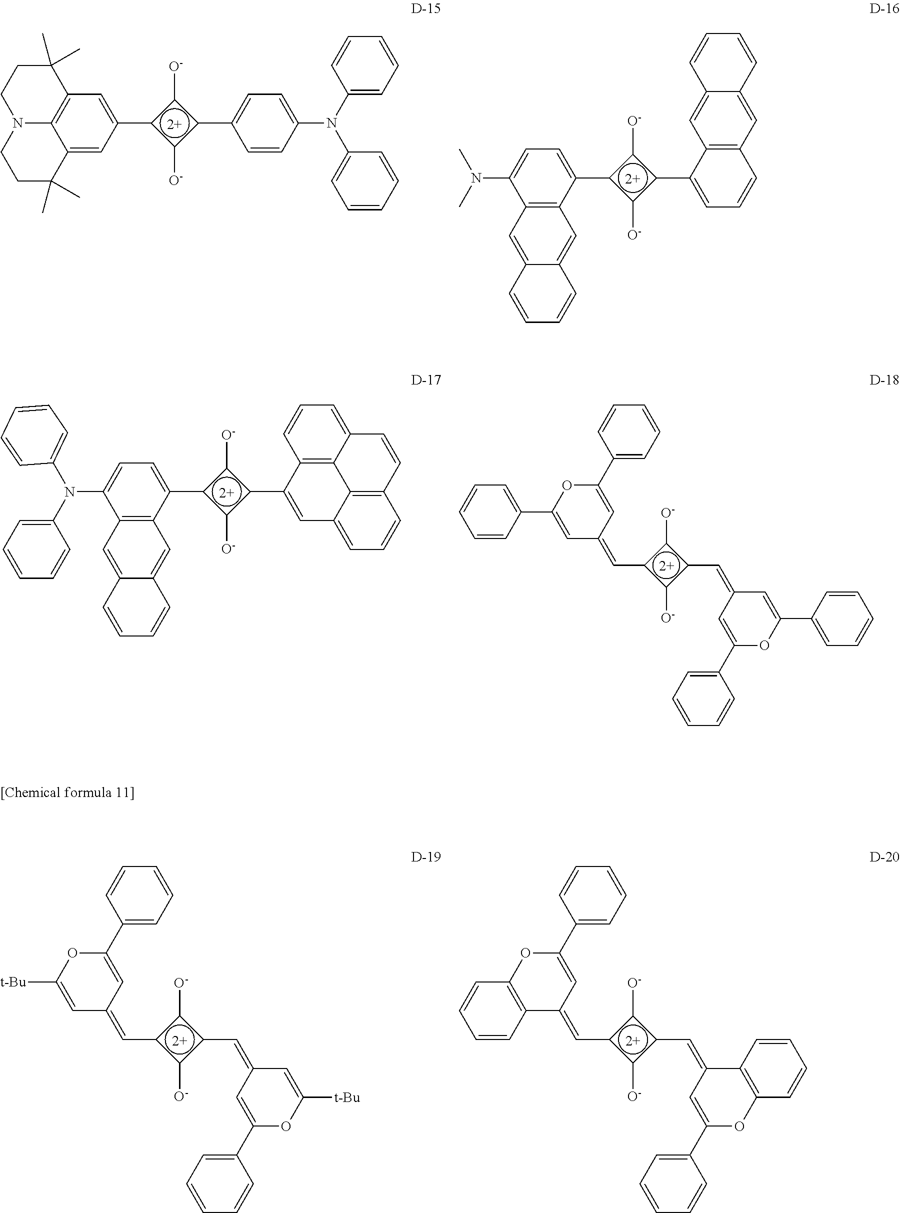

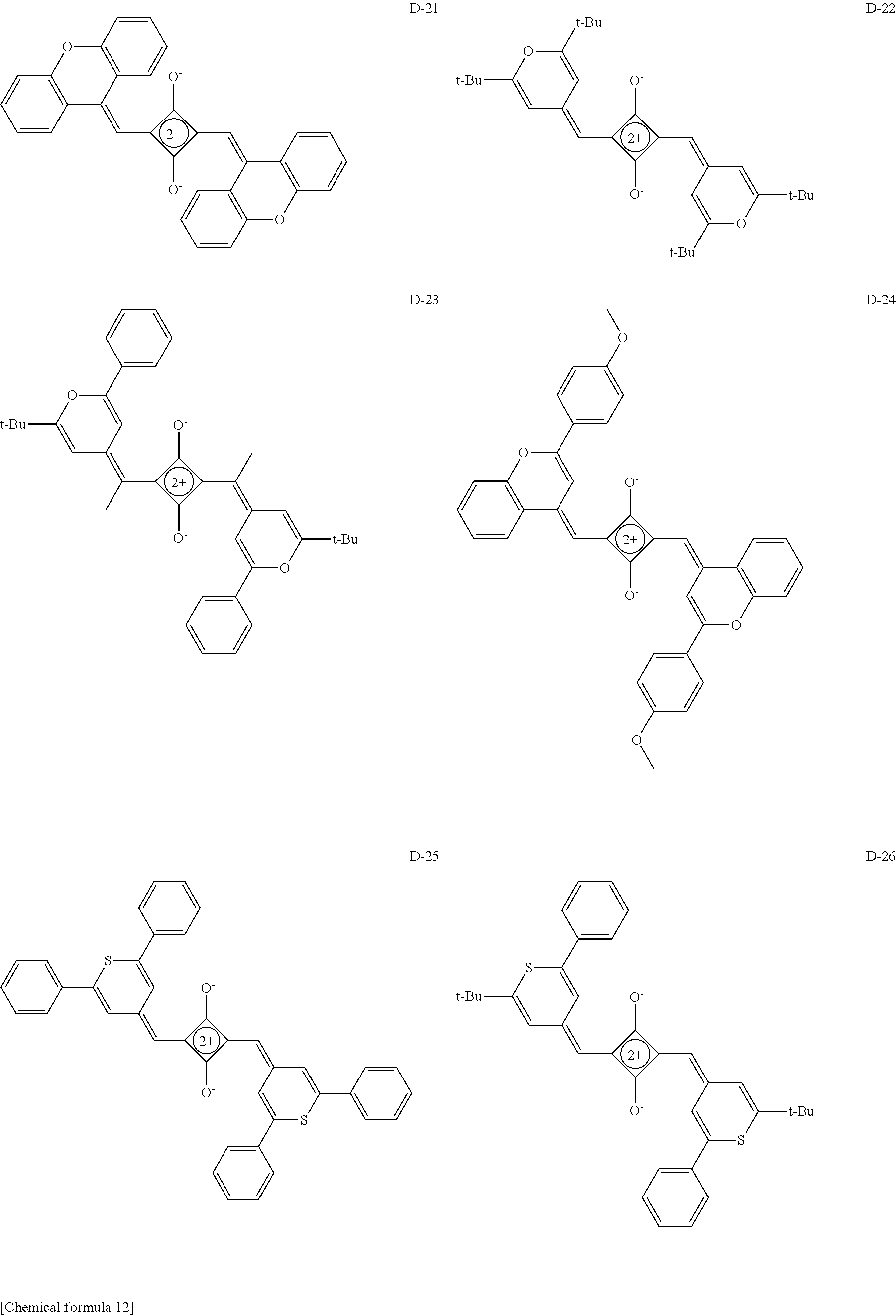

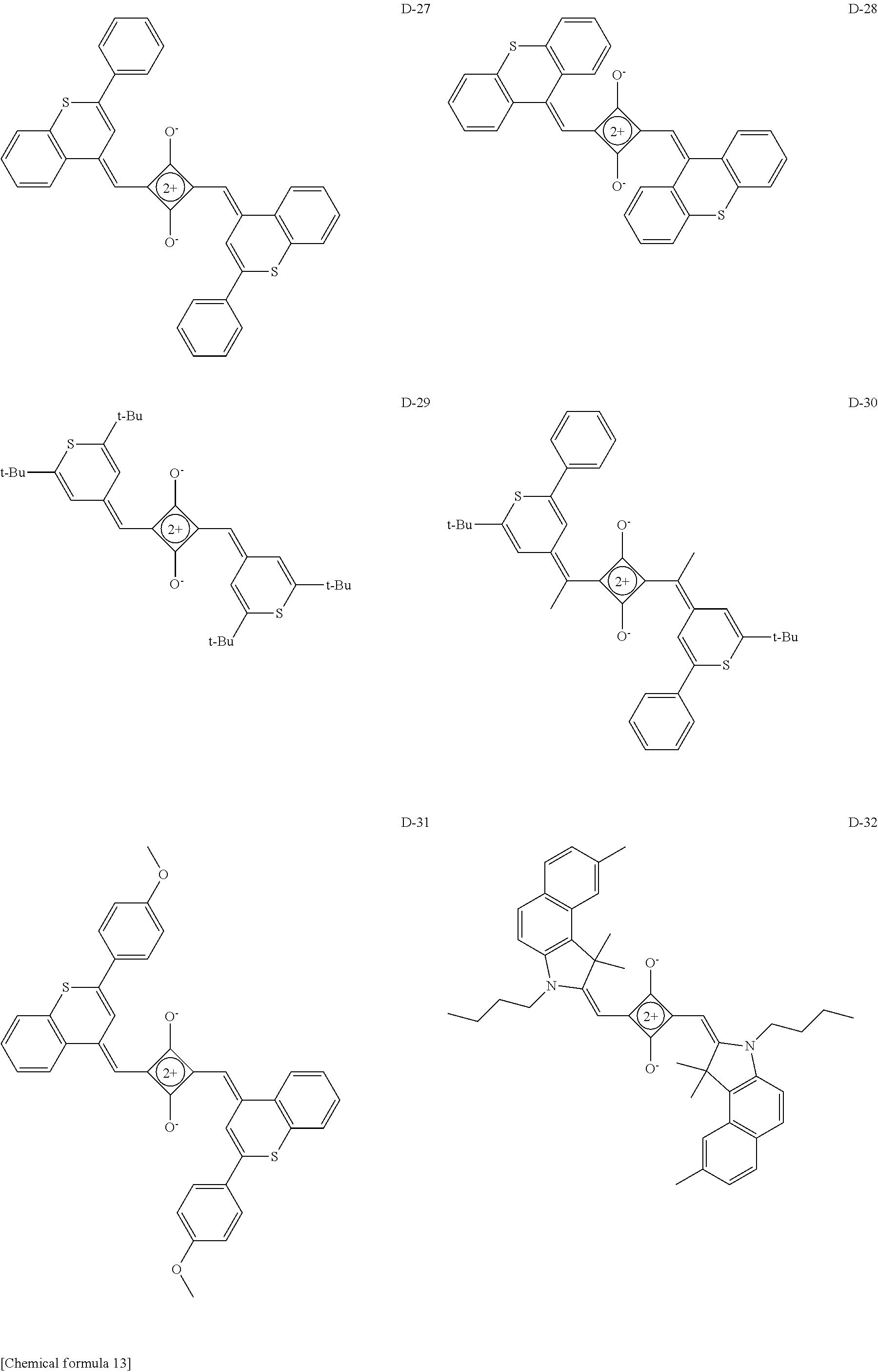

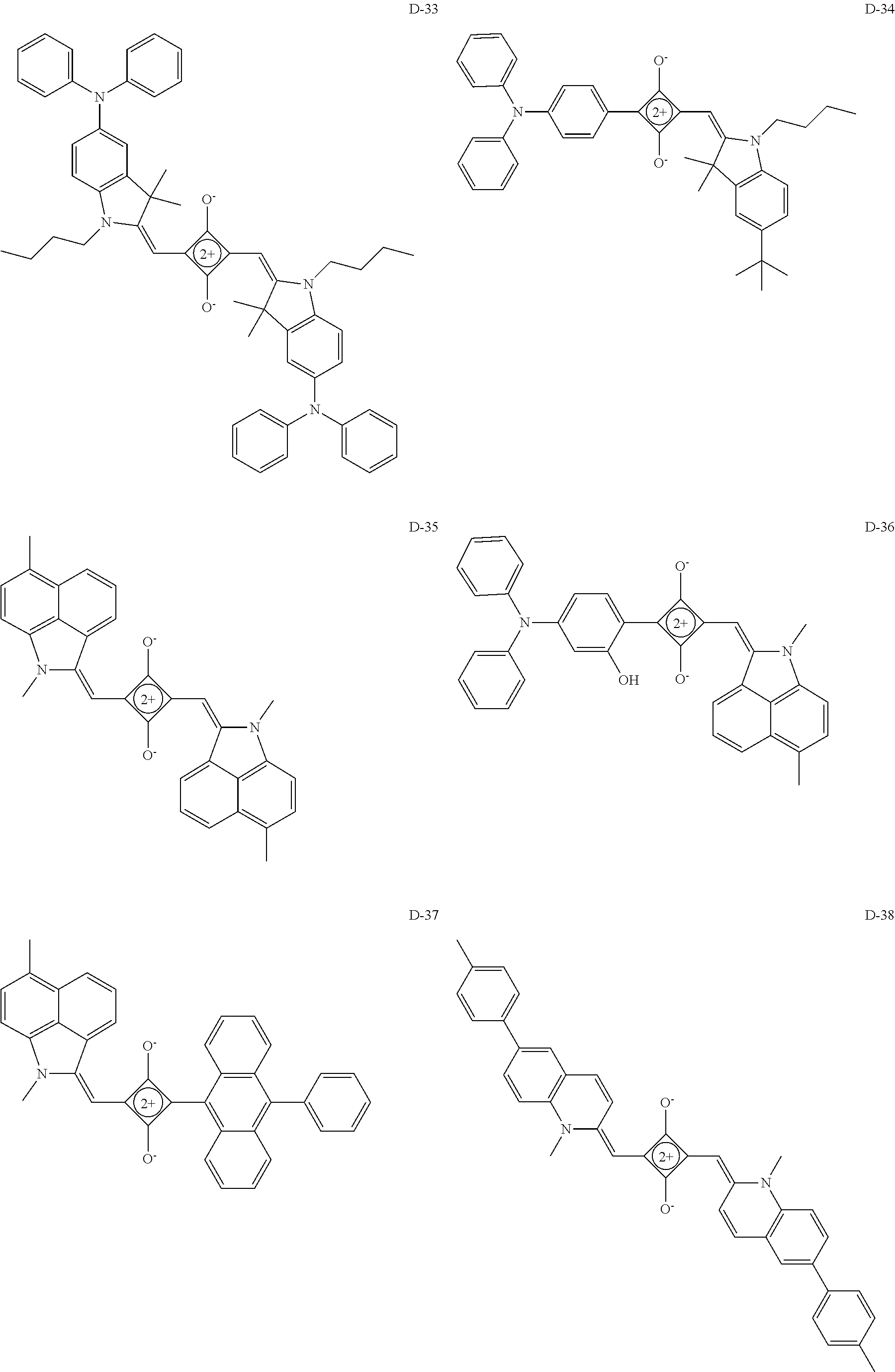

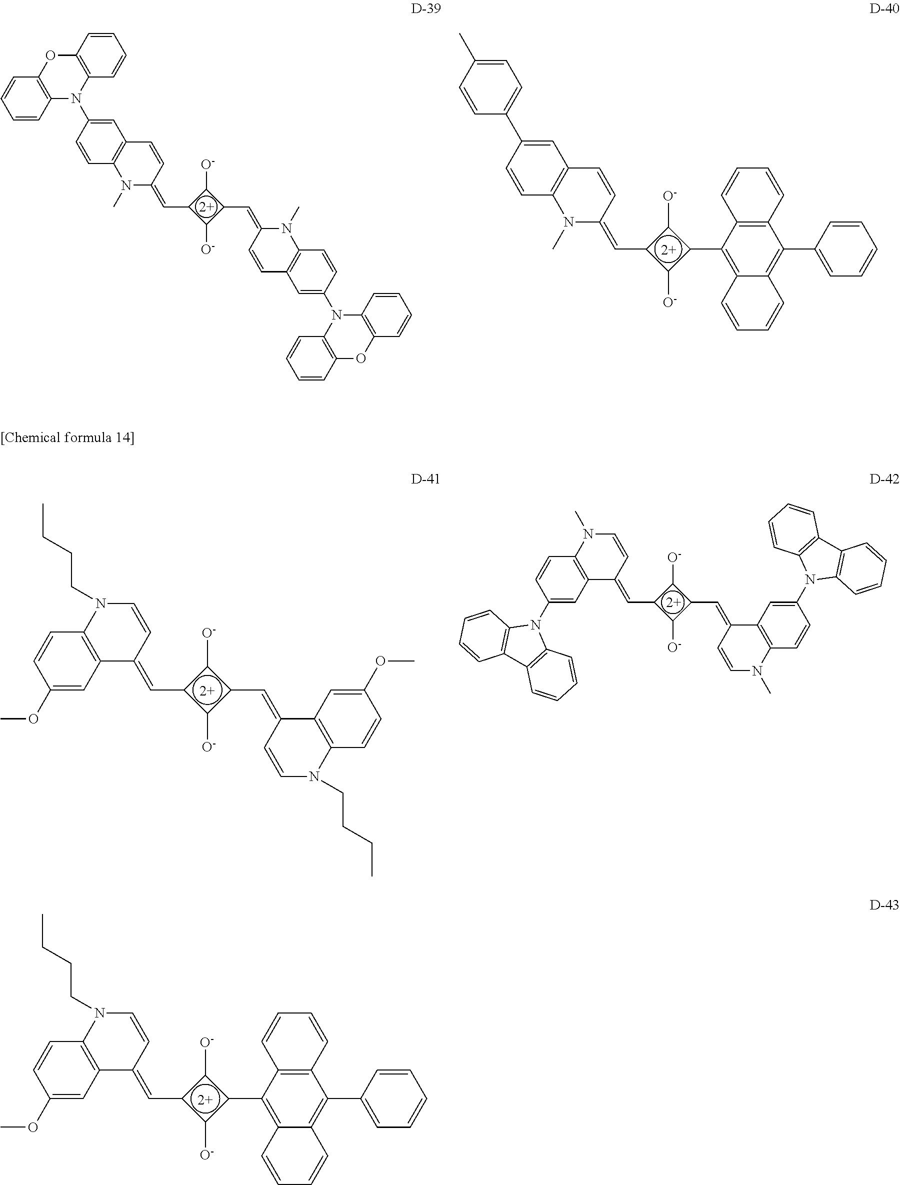

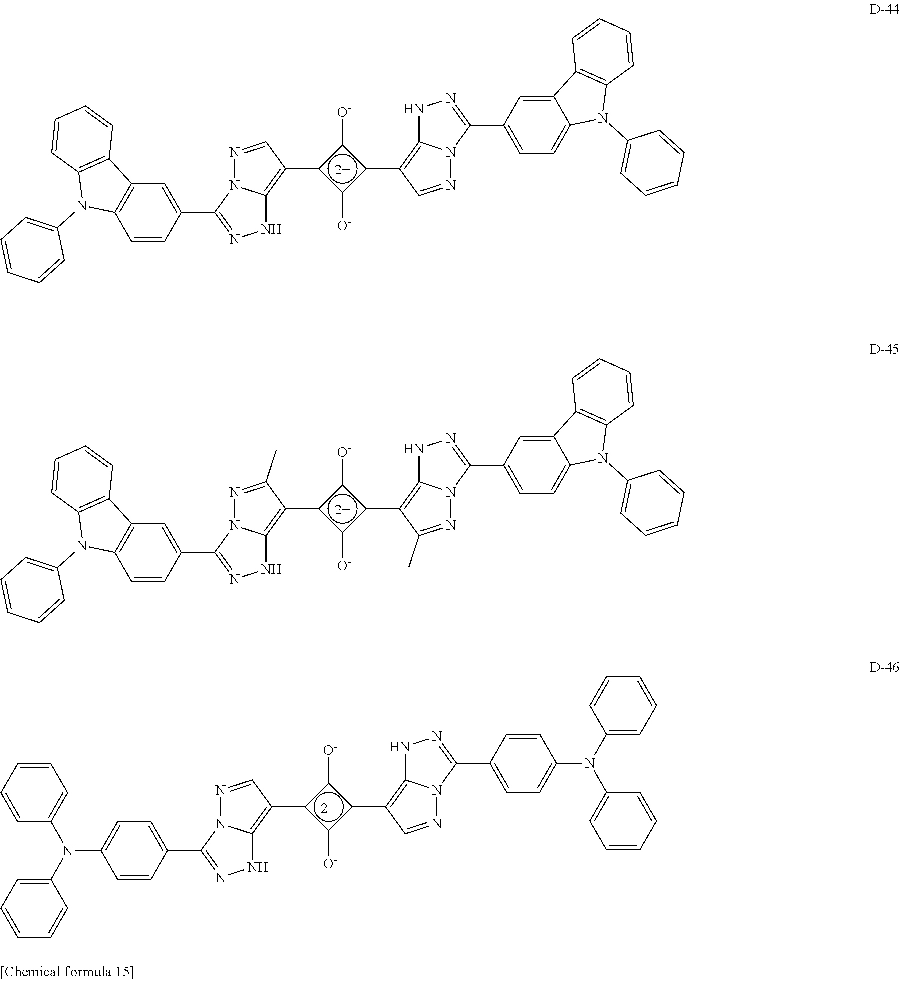

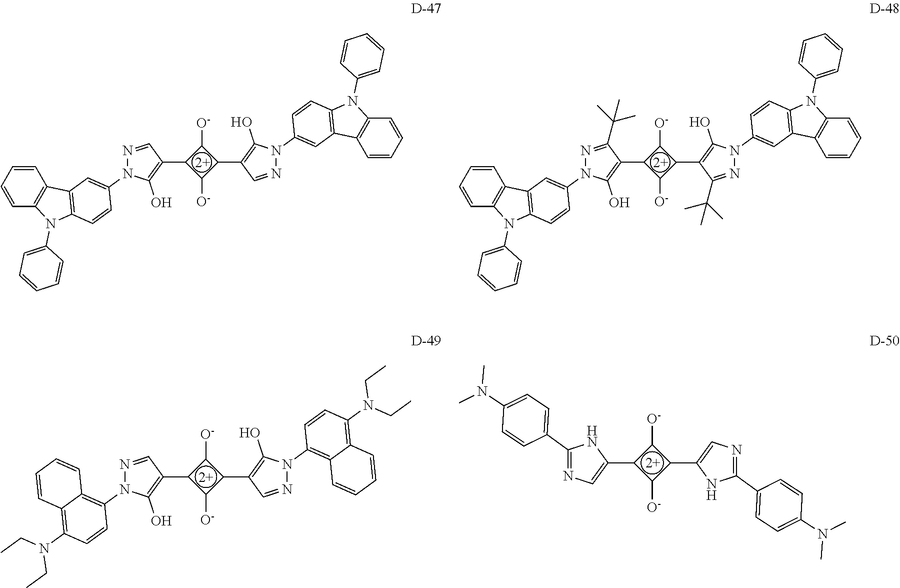

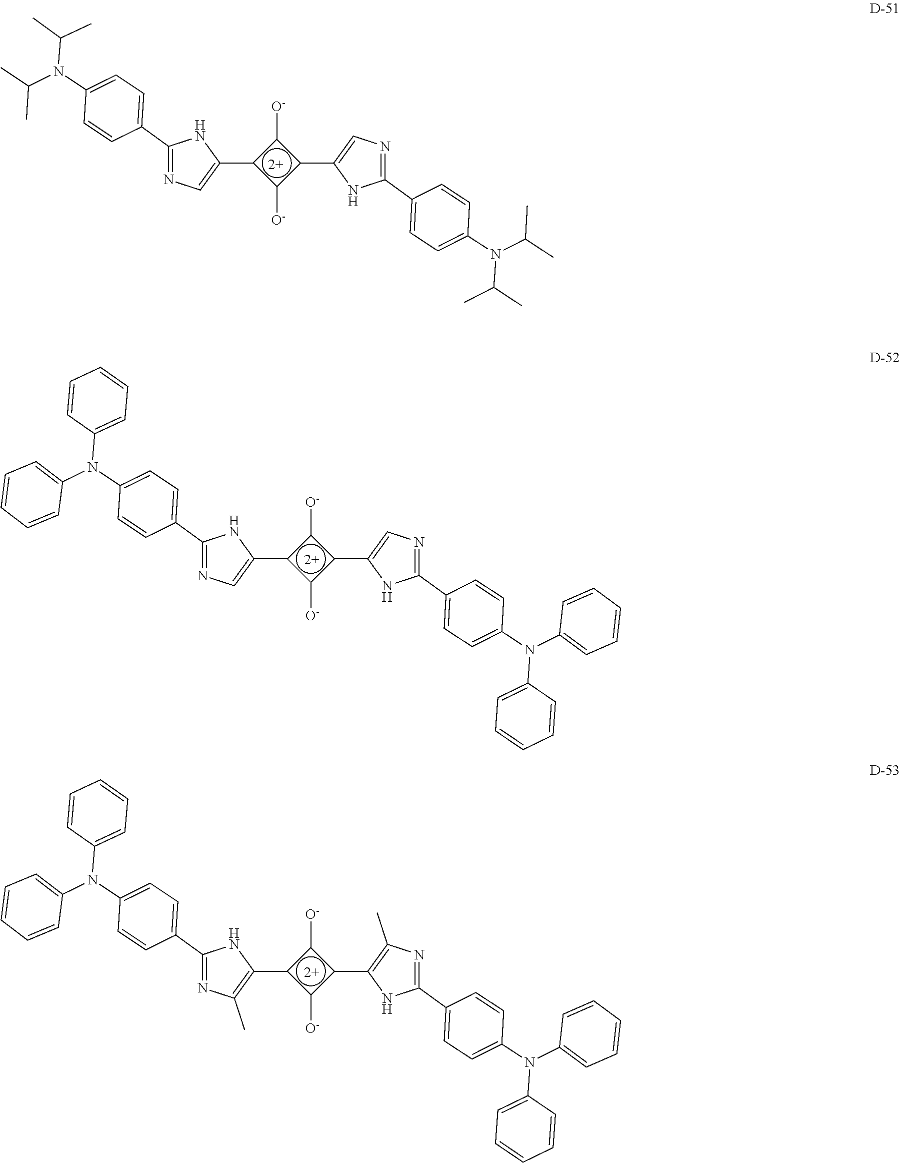

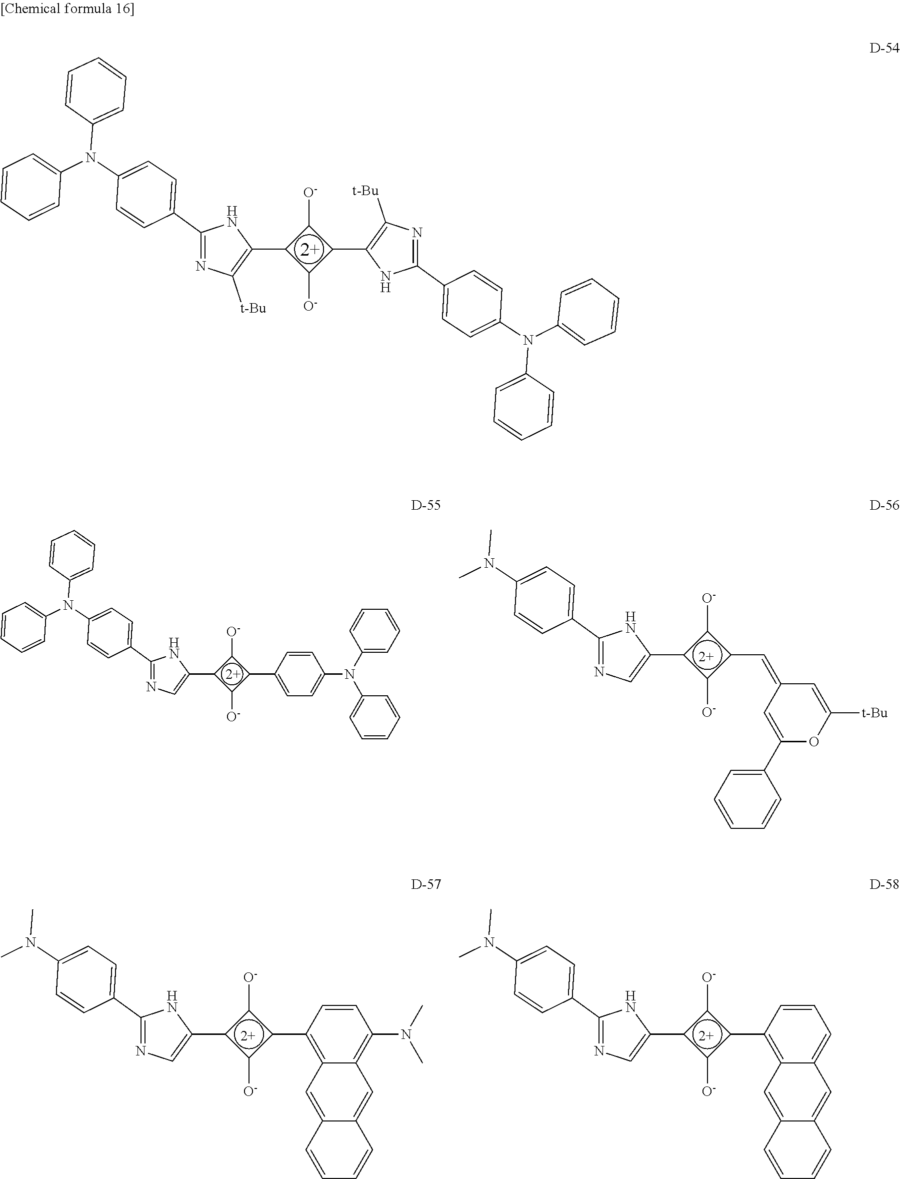

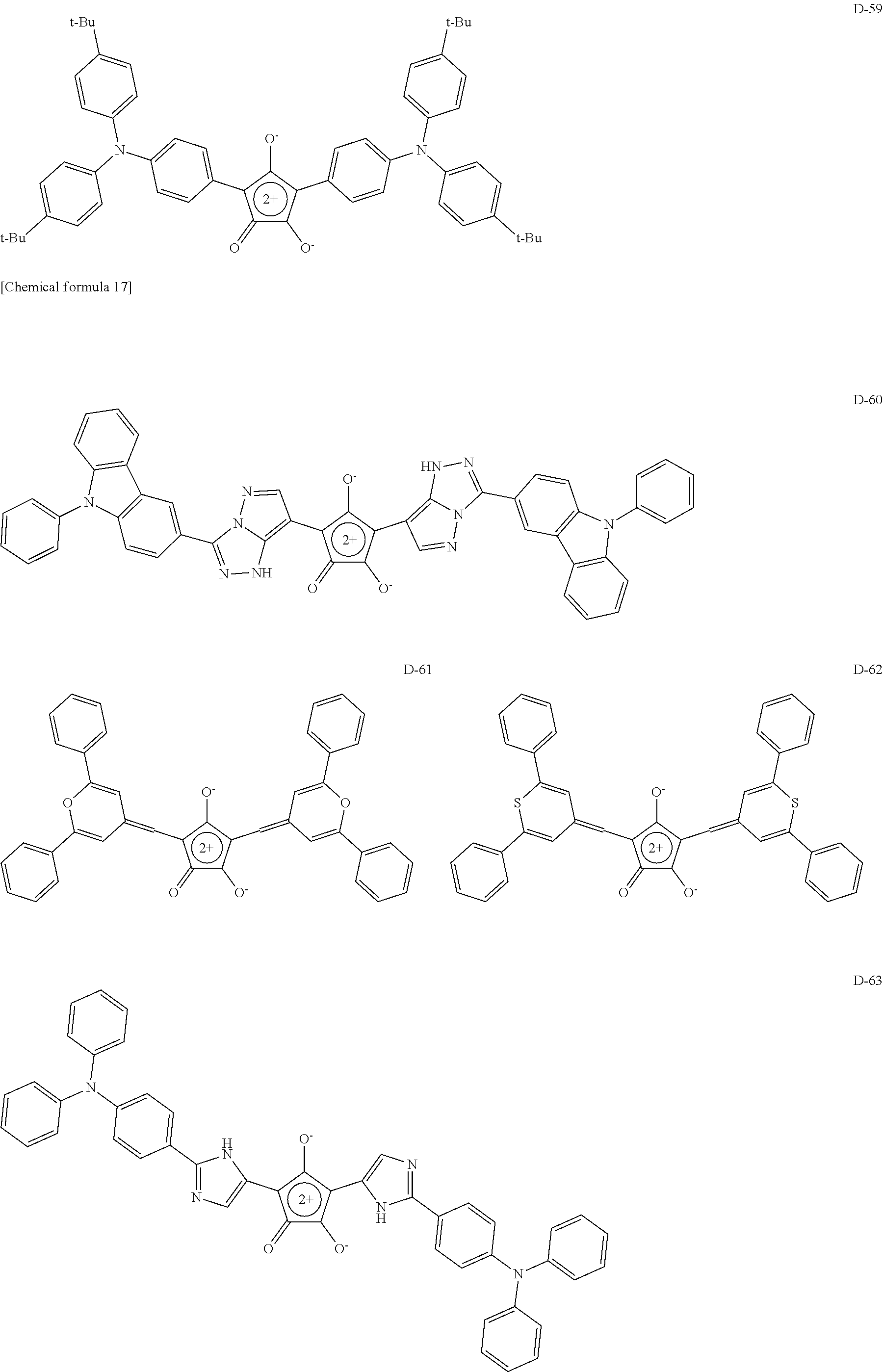

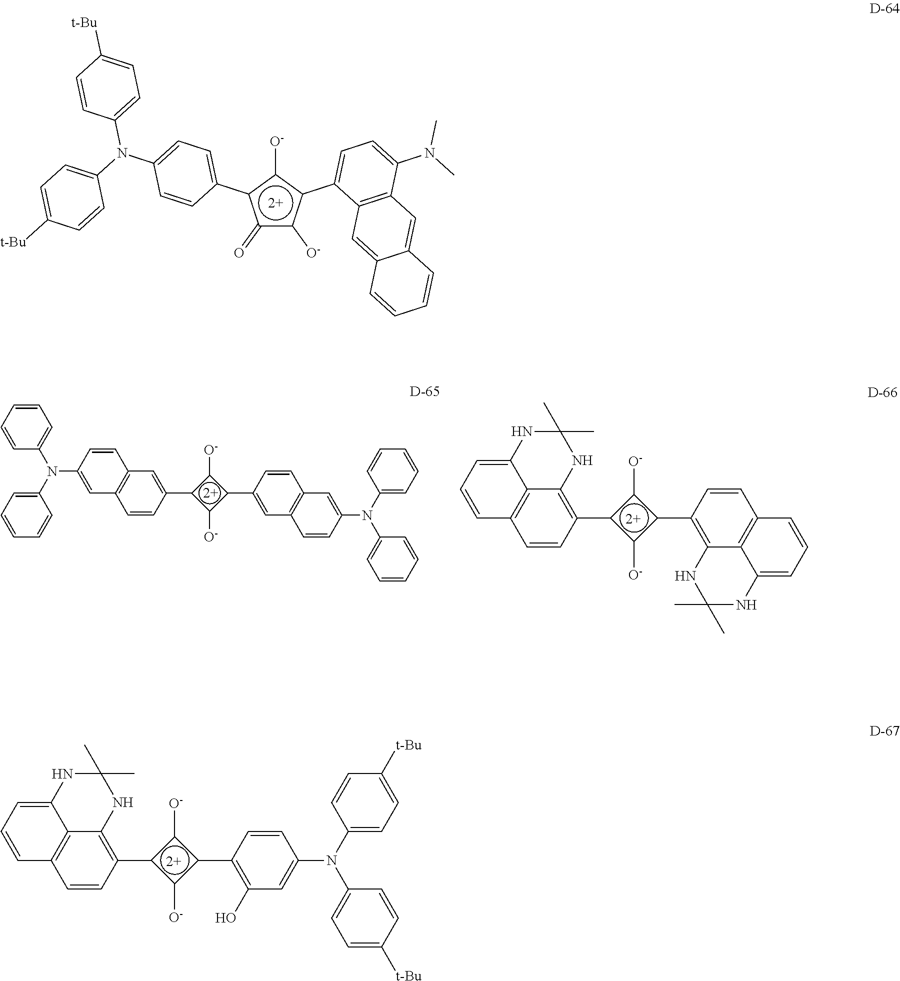

[Third Organic Compound]

The third organic compound is an organic compound having lowest excited singlet energy and lowest excited triplet state energy larger than the first organic compound and the second organic compound, and has a function as a transport material for transporting a carrier, a function as a host compound, a function of confining energy of the first organic compound in the compound, or a function to radiate delayed fluorescence. As a result, the first organic compound can efficiently convert energy generated by recombination of a hole and an electron in a molecule and energy received from the second organic compound and the third organic compound into light emission to achieve an organic EL element having high luminous efficiency.

The organic EL element of the present invention may include only one kind of third organic compound or two or more kinds thereof. For example, in a case where two kinds of third organic compounds are included, one may be a compound exhibiting delayed fluorescence, and the other may be a compound not exhibiting delayed fluorescence.

A specific structure of the third organic compound is not limited. However, the third organic compound is preferably an organic compound having hole transporting ability and electron transporting ability, preventing long wavelength emission, and having a high glass transition temperature.

The glass transition temperature of the third organic compound is preferably 90° C. or higher, and more preferably 120° C. or higher in terms of Tg.

Here, the glass transition point (Tg) is a value determined by a method in accordance with JIS K 7121-2012 using differential scanning colorimetry (DSC).

The third organic compound transports a carrier and generates an excitor in a light emitting layer. Therefore, preferably, the third organic compound can stably exist in all the states of active species, that is, in a cation radical state, an anion radical state, and an excited state, and does not cause a chemical change such as decomposition or addition reaction, and furthermore, a host molecule does not move at an angstrom level in the layer over time during passage of a current.

In addition, in a case where the first organic compound used in combination exhibits TADF emission, existence time of the TADF compound in a triplet excited state is long. Therefore, it is necessary to design an appropriate molecular structure such that the third organic compound is not brought into a low T1 state. That is, for example, the T1 energy level of the third organic compound itself needs to be high, formation of a low T1 state is prevented while the third organic compounds are associated with each other, formation of an exciplex between the first organic compound and the third organic compound is prevented, and formation of an electromer by a host compound due to an electric field is prevented.

In order to satisfy such requirements, the third organic compound itself needs to have high electron hopping mobility, high hole hopping movement, and a small structural change when the third organic compound is brought in a triplet excited state. Preferable representative examples of the third organic compound satisfying such requirements include compounds having a high T1 energy level, such as a carbazole skeleton, an azacarbazole skeleton, a dibenzofuran skeleton, a dibenzothiophene skeleton, or an azadibenzofuran skeleton.

Specific examples of the third organic compound include compounds described in the following literatures. JP 2001-257076 A, JP 2002-308855 A, JP 2001-313179 A, JP 2002-319491 A, JP 200′1-357977 A, JP 2002-334786 A, JP 2002-8860 A, JP 2002-334787 A, JP 2002-15871 A, JP 2002-334788 A, JP 2002-43056 A, JP 2002-334789 A, JP 2002-75645 A, JP 2002-338579 A, JP 2002-105445 A, JP 2002-343568 A, JP 2002-141173 A, JP 2002-352957A, JP 2002-203683 A, JP 2002-363227 A, JP 2002-231453 A, JP 2003-3165 A, JP 2002-234888 A, JP 2003-27048 A, JP 2002-255934 A, JP 2002-260861 A, JP 2002-280183 A, JP 2002-299060 A, JP 2002-302516 A, JP 2002-305083 A, JP 2002-305084 A, JP 2002-308837 A, US 2003/0175553 A., US 2006/0280965 A, US 2005/0112407 A, US 2009/0017330 A, US 2009/0030202 A, US 2005/0238919 A, WO 2001/039234 A, WO 2009/021126 A, WO 2008/056746 A, WO 2004/093207 A, WO 2005/089025 A, WO 2007/063796 A, WO 2007/063754 A, WO 2004/107822 A, WO 2005/030900 A, WO 2006/114966 A, WO 2009/086028 A, WO 2009/003898 A, WO 2012/023947 A, JP 2008-074939 A, JP 2007-254297 A, EP 2034538 B, WO 2011/055933 A, WO 2012/035853 A, JP 2015-38941 A, JP 5669163 B2, J. J. Am. Chem. Soc. 2014, 136, 18070-18081, Adv. Mater. 2013, 25, 3319-3323, Angew. Chem. Int. Ed. 2016, 55, 5739-5744, Angew. Chem. Int. Ed. 2015, 54, 13068-13072, and the like.

Specific examples of the third organic compound used in the present are illustrated below, but the present invention is not limited thereto.

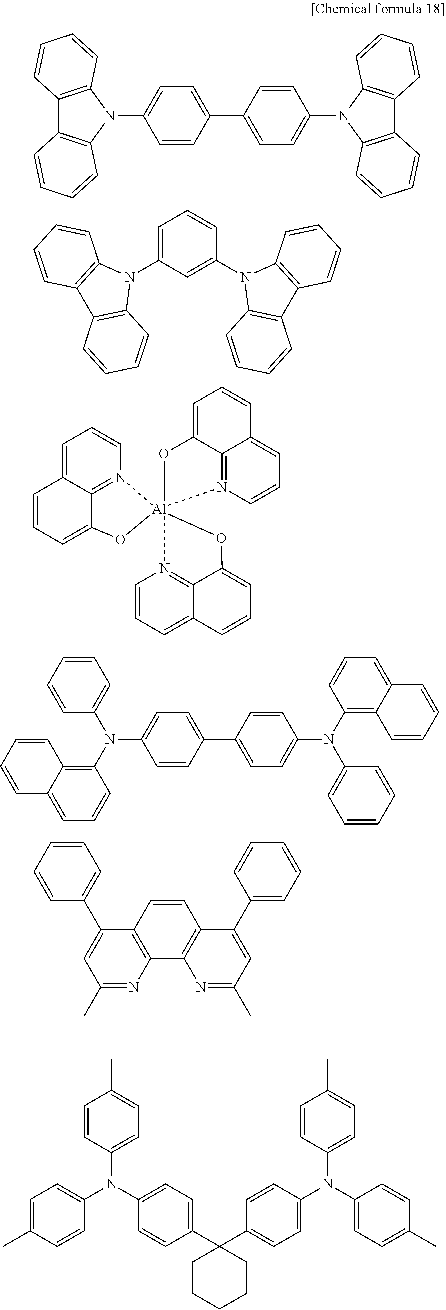

(Contents of First Organic Compound, Second Organic Compound, Third Organic Compound)

The content of each organic compound in the organic EL element of the present invention is not particularly limited, but preferably satisfies the following.

That is, when the content of the first organic compound in a light emitting layer is represented by W1, the content W1 of the first organic compound is preferably 5.0 to 100% by mass with respect to 100% by mass of the total mass of the light emitting layer.

In addition, when the content of the second organic compound included in the light emitting layer or any other layer is represented by W2, the content W2 of the second organic compound is preferably set such that W2/W1 is 0.001 to 10.

Furthermore, when the content of the third organic compound is represented by W3, the content W3 of the third organic compound is preferably set such that W3/W1 is 0.001 to 10.

(Other Organic Compounds)

The organic layer may include only the first organic compound and the second organic compound (preferably the first organic compound, the second organic compound, and the third organic compound), or may further include an organic compound other than the first organic compound, the second organic compound, and the third organic compound. Examples of the organic compound other than the first organic compound, the second organic compound, and the third organic compound include an organic compound having hole transporting ability and an organic compound having electron transporting ability. As the organic compound having hole transporting ability and the organic compound having electron transporting ability, a hole transport material and an electron transport material described later can be referred to, respectively.

As described above, the first organic compound and the optional third organic compound are included in the light emitting layer. The second organic compound may be included in the light emitting layer or may be included in any other layer.

The second organic compound only needs to be included in the organic EL element, may be included in the light emitting layer or any other layer; for example, in any one of a positive electrode, a hole injection layer, a hole transport layer, an electron blocking layer, a light emitting layer, a hole blocking layer, an electron transport layer, an electron injection layer, and a negative electrode, and is preferably included in the hole transport layer, the electron blocking layer, the light emitting layer, the hole blocking layer, or the electron transport layer. Above all, the second organic compound is more preferably included in the light emitting layer or a layer adjacent thereto, and still more preferably included in the light emitting layer.

In addition, the second organic compound may be included not only inside the organic EL element but also outside the organic EL element, for example, in a support substrate, a sealing member, a protective film, or a protective plate.

That is, in a preferable embodiment of the organic EL element of the present invention, the light emitting layer preferably includes the first organic compound and the second organic compound, and more preferably includes all of the first organic compound, the second organic compound, and the third organic compound.

Hereinafter, an example of a preferable embodiment of the organic EL element of the present invention will be specifically described.

Examples of a representative element configuration in the organic EL element of the present invention include the following configurations, but the present invention is not limited thereto.)

(1) Positive electrode/light emitting layer/negative electrode

(2) Positive electrode/light entitling layer/electron transport layer/negative electrode

(3) Positive electrode/hole transport layerdight emitting layer/negative electrode

(4) Positive electrode/hole transport layer/light emitting layer/electron transport layer/negative electrode

(5) Positive electrode/hole transport layer/light emitting layer/electron transport layer/electron injection layer/negative electrode

(6) Positive electrode/hole injection layer/hole transport layer/light emitting layer/electron transport layer/negative electrode

(7) Positive electrode/hole injection layer/hole transport layer/(electron blocking layer/) light emitting layer/(hole blocking layer/) electron transport layer/electron injection layer/negative electrode

Among the above configurations, the configuration of (7) is preferably used, but the present invention is not limited thereto.

The light emitting layer is formed of a single layer or a plurality of layers. In a case where the light emitting layer is formed of a plurality of layers, a non-light emitting intermediate layer may be disposed among the light emitting layers.

A hole blocking layer (also referred to as a hole barrier layer) or an electron injection layer (also referred to as a negative electrode buffer layer) may be disposed between the light emitting layer and the negative electrode as necessary. In addition, an electron blocking layer (also referred to as an electron barrier layer) or a hole injection layer (also referred to as a positive electrode buffer layer) may be disposed between the light emitting layer and the positive electrode.

The electron transport layer has a function of transporting an electron. In a broad sense, the electron transport layer includes an electron injection layer and a hole blocking layer. In addition, the electron transport layer may be formed of a plurality of layers.

The hole transport layer has a function of transporting a hole. In a broad sense, the hole transport layer includes a hole injection layer and an electron blocking layer. In addition, the electron transport layer may be formed of a plurality of layers.

In the above representative element configuration, a layer obtained by removing the positive electrode and the negative electrode is also referred to as an “organic layer”.

(Tandem Structure)

In addition, the organic EL element of the present invention may be a so-called tandem structure element in which a plurality of light emitting units each including at least one light entitling layer is laminated.

Examples of a representative element configuration of the tandem structure include the following configuration.

Positive electrode/first light emitting unit/intermediate layer/second light emitting unit/intermediate layer/third light emitting unit/negative electrode

Here, the first light emitting unit, the second light emitting unit, and the third light emitting unit may be all the same as or different from one another. In addition, two of the light emitting units may be the same as each other, and the remaining one may be different from the others.

The plurality of light emitting units may be laminated directly or via an intermediate layer. The intermediate layer is generally also referred to as an intermediate electrode, an intermediate conductive layer, a charge generation layer, an electron extraction layer, a connection layer, or an intermediate insulating layer, and can have a known material configuration as long as having a function of supplying an electron to an adjacent layer on the positive electrode side and supplying a hole to an adjacent layer on the negative electrode side.

Examples of a material used for the intermediate layer include a conductive inorganic compound layer such as indium tin oxide (ITO), indium zinc oxide (IZO)), ZnO₂, TiN, ZrN, HfN, TiOx, VOx, CuI, InN, GaN, CuAlO₂, CuGaO₂, SrCu₂O₂, LaB₆, RuO₂, or Al, a two-layer film such as Au/Bi₂O₃, a multilayer film such as SnO₂/Ag/SnO₂, ZnO/Ag/ZnO, Bi₂O₃/Au/Bi₂O₃, TiO₂/TiN/TiO₂, or TiO₂/ZrN/TiO₂, a fullerene such as C₆₀, a conductive organic layer such as oligothiophene, and a conductive organic compound layer such as a metal phthalocyanine, a metal free phthalocyanine, a metal porphyrin, or a metal-free porphyrin. However, the present invention is not limited thereto.

Examples of a preferable configuration in the light emitting unit include a configuration obtained by removing the positive electrode and the negative electrode from each of the configurations (1) to (7) exemplified in the above representative element configuration. However, the present invention is not limited thereto.

Specific examples of the tandem type organic EL element include element configurations and constituent materials described in U.S. Pat. No. 6,337,492, 7,420,203, 7,473,923, 6,872,472, 6,107,734, 6,337,492, WO 2005/009087 A, JP 2006-228712 A, JP 2006-24791 A, JP 2006-49393 A, JP 2006-49394 A, JP 2006-49396 A, JP 2011-96679 A, JP 2005-340187 A, JP 4711424 B2, JP 3496681 B2, JP 3884564 B2, JP 4213169 B2, JP 2010-192719 A, JP 2009-076929 A, JP 2008-078414 A, JP 2007-059848 A, JP 2003-272860 A, JP 2003-045676 A, WO 2005/094130 A, and the like. However, the present invention is not limited thereto.

Hereinafter, each layer constituting the organic EL element will be described.

<<Light Emitting layer>>

The light emitting layer provides a site where an electron a hole injected from an electrode or an adjacent layer recombine to cause light emission or to be converted into a light emitting compound via an exciton by energy transfer, and may emit light within the light entitling layer or at an interface between the light emitting layer and an adjacent layer. The configuration of the light emitting layer is not particularly limited as long as satisfying the requirements defined in the present invention.

The light emitting layer may include only the first organic compound or may include the first organic compound and one or more selected from group consisting of the second organic compound, the third organic compound, and a host compound other than the third organic compound.

The light emitting layer may be formed of one layer or a plurality of layers. At least one layer of the light emitting layers preferably includes the first organic compound, the second organic compound, and the third organic compound because luminous efficiency is improved and a change in resistance value is small over time during passage of a current.

In a case where the first organic compound, the second orgainic compound, and the third organic compound are included in the light emitting layer, the content of each of the first organic compound and the second organic compound is preferably smaller than the content of the third organic compound. This makes it possible to obtain higher luminous efficiency. Specifically, when the total weight of the content W1 of the first organic compound, the content W2 of the second organic compound, and the content W3 of the third organic compound is assumed to be 100% by weight, the content W1 of the first organic compound is preferably 5.0% by mass or more and 5.0% by mass or less, and the content W2 of the second organic compound is preferably 0.5% by mass or more and 5.0% by mass or less, and the content W3 of the third organic compound is preferably 15% by mass or more and 99.9% by mass or less.

The sum of the layer thicknesses of the light emitting layers is not particularly limited, but is preferably adjusted to a range of 2 μm to 5 μm, more preferably to a range of 2 to 500 nm, and still more preferably to a range of 5 to 200 nm from viewpoints of homogeneity of a film to be formed, prevention of applying unnecessarily high voltage at the time of light emission, and improvement in stability of emission color against a drive current.

In addition, in a case where the light emitting layer is formed of a plurality of layers, the layer thickness of each of the light emitting layers is preferably adjusted to a range of 2 nm to 1 μm, more preferably to a range of 2 to 200 nm, and still more preferably to a range of 3 to 150 nm.

<<Positive Electrode>>

As the positive electrode in organic EL element, an electrode using a metal, art alloy, an electrically conductive compound, or a mixture thereof having a large work function (4 eV or more, preferably 4.5 eV or more) as an electrode material is preferably used. Specific examples of such an electrode material include a conductive transparent material such as a metal including Au, CuI, indium tin oxide (ITO), SnO₂, or ZnO. In addition, an amorphous material that can form a transparent conductive film, such as IDIXO (In₂O₃—ZnO), may be used.

For the positive electrode, a thin film of the electrode material may be formed by a method such as vapor deposition or sputtering, and a pattern of a desired shape may be formed by a photolithography method. Alternatively, in a case where pattern accuracy is not so much required (about 100 μm or more), a pattern may be formed via a mask having a desired shape during vapor deposition or sputtering of the electrode material.

Alternatively, in a case where an applicable material such as an organic conductive compound is used, a wet film forming method such as a printing method or a coaling method can be used. In a case of extracting light emission from this positive electrode, transmittance is desirably larger than 10%, and sheet resistance as the positive electrode is preferably several hundred Ω/□ or less.

The film thickness of the positive electrode is selected usually within a range of 10 nm to 1 μm, preferably within a range of 10 to 200 nm although depending on a material.

<<Negative Electrode>>

As the negative electrode, an electrode using a metal (referred to as an electron-injecting metal), an alloy, an electrically conductive compound, or a mixture thereof having a small work function (4 eV or less) as an electrode material is used. Specific examples of such an electrode material include sodium, a sodium-potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum nnxture, aluminum, and a rare earth metal. Among these materials, a mixture of an electron-injecting metal and a second metal having a larger work function value than the electron-injecting metal and being stable, such as a magnesium/silver mixture, a magnesium/aluminum mixture, a magnesium/indium mixture, an aluminum/aluminum oxide (Al₂O₃) mixture, a lithium/aluminum mixture, or aluminum, is preferable from viewpoints of an electron-injecting property and durability against oxidation and the like.

The negative electrode can be prepared by forming a thin film of the electrode material by a method such as vapor deposition or sputtering. In addition, a sheet resistance as the negative electrode is preferably several hundred Ω/□ or less, and the film thickness is selected usually within a range of 10 nm to 5 μm, preferably within a range of 50 to 200 nm.

Incidentally, if either one of the positive electrode and the negative electrode of the organic EL element is transparent or translucent, emitted light is transmitted, and therefore light emission brightness is improved conveniently.

In addition, by preparing the above metal with a film thickness of 1 to 20 nm for the negative electrode and then preparing the conductive transparent material exemplified in the description of the positive electrode thereon, the transparent or translucent negative electrode can be prepared. By applying this, an element in which both a positive electrode and a negative electrode are transmissive can be prepared.

<<Electron Transport Layer>>

The electron transport layer only needs to be formed of a material having a function of transporting an electron and to have a function of transmitting an electron injected from the negative electrode to a light emitting layer.

The total layer thickness of the electron transport layer according to the present invention is not particularly limited, but is usually within a range of 2 nm to 5 μm, more preferably within a range of 2 to 500 nm, and still more preferably within a range of 5 to 200 nm.

In addition, in the organic EL element, it is known that when light generated in a light emitting layer is extracted from an electrode, light directly extracted from the light emitting layer interferes with light extracted after being reflected by an electrode located at the opposite pole to the electrode from which light is extracted. In a case where light is reflected by the negative electrode, by appropriately adjusting the total layer thickness of the electron transport layer within a range of several nm to several μm, this interference effect can be efficiently utilized.

Meanwhile, when the layer thickness of the electron transport layer is increased, the voltage tends to rise easily. Therefore, in a case where the layer thickness is particularly thick, the electron mobility of the electron transport layer is preferably 10⁻⁵ cm²/Vs or more.

A material used for the electron transport layer (hereinafter, referred to as an electron transport material) only needs to have any one of an electron injecting, property, an electron-transporting property, and a hole barrier property. Any compound can be selected for use from among conventionally known compounds.

Examples of the electron transport material include a nitrogen-containing aromatic heterocyclic derivative (a carbazole derivative, an azacarbazole derivative (a compound in which at least one carbon atom constituting a carbazole ring is substituted with a nitrogen atom), a pyridine derivative, a pyrimidine derivative, a pyrazine derivative, a pyridazine derivative, a triazine derivative, a quinoline derivative, a quinoxaline derivative, a phenanthroline derivative, an azatriphenylene derivative, an oxazole derivative, a thiazole derivative, an oxadiazole derivative, a thiadiazole derivative, a triazole derivative, a benzimidazole derivative, a benzoxazole derivative, a benzthiazole derivative, or the like), a dibenzofuran derivative, a dibenzothiophene derivative, a silole derivative, and an aromatic hydrocarbon ring derivative (a naphthalene derivative, an anthracene derivative, a triphenylene derivative, or the like).

In addition, a metal complex having a quinolinol skeleton or a dibenzoquinolitiol skeleton in a ligand, such as tris(8-quinolinol) aluminum (Alq), tris(5,7-dichloro-8-quinolinol) aluminum, tris(5,7-dibromo-8-quinolinol) aluminum, tris(2-methyl-8-quinolinol) aluminum, tris(5-methyl-8-quinolinol) aluminum, or bis(8-quinolinol) zinc (Zuq), and a metal complex in which a central metal of each of these complexes is substituted with In, Mg, Cu, Ca, Sn, Ga, or Pb can also be used as the electron transport material.

In addition, a metal free substance, metal phthalocyanine, or a compound in which a terminal of the metal free substance or metal phthalocyanine is substituted with an alkyl group, a sulfonic acid group, or the like can also be preferably used as the electron transport material. In addition, a distyrylpyrazine derivative exemplified as a material of the light emitting layer can also be used as the electron transport material. In a similar manner to the hole injection layer and the hole transport layer, an inorganic semiconductor such as a type-Si or it type-SiC can also be used as the electron transport material.

In addition, a polymer material obtained by introducing these materials into a polymer chain, or a polymer material using these materials as a main chain of a polymer can also be used.

In the electron transport layer, the electron transport layer may be doped with a dopant as a guest material to form the electron transport layer with a high n-properly (electron rich). Examples of the dopant include an n-type dopant such as a metal complex, a metal halide, or a metal compound. Specific examples of the electron transport layer having such a configuration are described in literatures such as JP 4-297076 A, JP 10-270172 A, JP 2000-196140 A, JP 2001-102175 A, and J. Appl. Phys., 95, 5773 (2004).

Specific examples of a well-known preferable electron transport material used in the organic EL element of the present invention include compounds described in the following literatures, but the present invention is not limited thereto. U.S. Pat. No. 6,528,187, 7,230,107, US 2005/0025993 A, US 2004/0036077 A, US 2009/0115316 A, US 2009/0101870, US 2009/0179554 A, WO 2003/060956 A, WO 2008/132085 A, Appl. Phys. Lett. 75, 4 (1999), Appl. Phys. Lett. 79, 449 (2000, Appl. Phys. Lett. 81, 162 (2002), Appl. Phys. Lett. 81, 162 (2002), Appl. Phys. Lett. 79, 156 (2001), U.S. Pat. No. 7,964,293, US 2009/030202 A, WO 2004/080975 A, WO 20041063159 A, WO 20051085387 A, WO 2006/067931 A, WO 2007/086552 A, WO 2008/114690 A, WO 2009/069442 A, WO 2009,066779 A, WO 2009/054253 A, WO 20111086935 A, WO 2010/150593 A, WO 2010/017707 A, EP 2311826 B, JP 2010-251675 A, JP 2009-209133 A, JP 2009-124114 A, JP 2008-277810 A, JP 006-156415 A, JP 2005-340122 A, JP 2003-45662 A, JP 2003-31367 A, JP 2003-282270 A, WO 2012/115034 A, and the like.

More preferable examples of the known electron transport material in the present invention include an aromatic heterocyclic compound containing at least one nitrogen atom and a compound containing a phosphorus atom, such as a pyridine derivative, a pyrimidine derivative, a pyrazine derivative, a triazine derivative, a dibenzofuran derivative, a dibenzothiophene derivative, an azadibenzofuran derivative, an azadibenzothiophene derivative, a carbazole derivative, an azacarbazole derivative, a benzimidazole derivative, or an arylphosphine oxide, derivative.

The electron transport material may be used singly or in combination of a plurality of kinds thereof.

<<Hole Blocking Layer>>

The hole blocking layer is a layer having a function of an electron transport layer in a broad sense, is preferably formed of a material having a function of transporting an electron and having small ability to transport a hole, and can improve a probability of recombining an electron and a hole by blocking a hole while transporting an electron.

In addition, the above configuration of the electron transport layer can be also used as the hole blocking layer as necessary.

The hole blocking layer disposed in the organic EL element of the present invention is preferably disposed adjacent to the negative electrode side of the light emitting layer.

The layer thickness of the hole blocking layer is preferably within a range of 3 to 100 nm, and more preferably within a range of 5 to 30 nm.

As a material used for the hole blocking layer, the above materials used for the electron transport layer are preferably used. In addition, a material used as the above host compound is also preferably used for the hole blocking layer.

<<Electron Injection Layer>>

The electron injection layer (also referred, to as “negative electrode layer”) is a layer disposed between the negative electrode and the light emitting layer in order to lower a driving voltage or to enhance light emission brightness. Details of the electron injection layer are described in Part 2, Chapter 2, “Electrode Material” (pp. 123 to 166) of “Organic EL element and Frontiers of Industrialization Thereof (issued by NTS Inc. on Nov. 30, 1998).

In the present invention, the electron injection layer is disposed as necessary, and may be present between the negative electrode and the light emitting layer as described above, or between the negative electrode and the electron transport layer.

The electron injection layer is preferably a very thin film, and the layer thickness of the electron injection layer is preferably within a range of 0.1 to 5 nm although depending on a material. In addition, the electron injection layer may be a nonuniform layer (film) in which constituent materials are intermittently present.

Details of the electron injection layer are also described in JP 6-325871 A, JP 9-17574 A, JP 10-74586 A, and the like. Specific examples of a material preferably used for the electron injection layer include a metal typified by strontium or aluminum, an alkali metal compound typified by lithium fluoride, sodium fluoride, or potassium fluoride, an alkaline earth metal compound typified by magnesium fluoride or calcium fluoride, a metal oxide typified by aluminum oxide, and a metal complex typified by lithium 8-hydroxyquinolate (Liq). In addition, the above electron transport material can also be used.

In addition, the above materials used for the electron injection layer may be used singly or in combination of a plurality of kinds thereof.

<<Hole Transport Layer>>

The hole transport layer only needs to be formed of a material having a function of transporting a hole and to have a function of transmitting a hole injected from the positive electrode to the light emitting layer.

The total layer thickness of the hole transport layer is not particularly limited, but is usually within a range of 5 nm to 5 μm, more preferably within a range of 2 to 500 nm, and still more preferably within a range of 5 to 200 nm.

A material used for the hole transport layer (hereinafter, referred to as a hole transport material) only needs to have any one of a hole-injecting property, a hole-transporting property, and an electron barrier property. Any compound can be selected for use from among conventionally known compounds.

Examples the material include a porphyrin derivative, a phthalocyanine derivative, an oxazole derivative, an oxadiazole derivative, a triazole derivative, an imidazole derivative, a pyrazoline derivative, a pyrazolone derivative, a phenylenediamine derivative, a hydrazone derivative, a stilbene derivative, a polyarylalkane derivative, a triarylamine derivative, a carbazole derivative, an indolocarbazole derivative, an isoindole derivative, an acene-based derivative such as anthracene or naphthalene, a fluorene derivative, a fluorenone derivative, polyvinyl carbazole, a polymer material or an oligomer having an aromatic amine introduced into a main chain or a side chain thereof, a polysilane, and a conductive polymer or an oligomer (for example, PEDOT/PSS, an aniline-based copolymer, polyaniline, or polythiophene).

Examples of the triarylamine derivative include a benzidine type compound typified by α-NPD (4,4′-bis[N-(1-naphthyl)-N-phenylamino]biphenyl), a starburst type compound typified by MTDATA, and a compound having fluorene or anthracene in a triarylamine-linked core part.

In addition, a hexaazatriphenylene derivative described in JP 2003-519432 A, JP 2006-135145 A, and the like can also be used as the hole transport material similarly.

It is also possible to use a hole transport layer further doped with impurities and having a high p-property. Examples thereof are described in JP 4-297076 A, JP 2000-196140 A, JP 2001-102175 A, J. Appl. Phys., 95, 5773 (2004), and the like.

In addition, a so-called p-type hole transport material and an inorganic compound of p-type-Si, p-type-SiC, or the like as described in JP 11-251067 A and J. Huang et al. (Applied Physics Letters 80 (2002), p. 139) can also be used. Furthermore, an ortho-metalated organometallic complex having Ir or Pt as a central metal as typified by Ir(ppy)3 is also preferably used.

As the hole transport material, the materials described above can be used, but preferable examples of the hole transport material include a triarylamine derivative, a carbazole derivative, an indolocarbazole derivative, an azatriphenylene derivative, an organometallic complex, and a polymer material or an oligomer having an aromatic amine introduced into a main chain or a side chain thereof.

Specific examples of a well-known preferable hole transport material used in the organic EL element of the present invention include compounds described in the following literatures in addition to the above-illustrated literatures, but the present invention is not limited thereto.

For example, Appl. Phys. Lett. 69, 2160 (1996), J. Lumin. 72-74, 985 (1997), Appl. Phys. Lett. 78, 673 (2001), Appl. Phys. Lett. 90, 183503 (2007), Appl. Phys. Lett. 90, 183503 (2007), Appl. Phys. Lett. 51, 913(1987), Synth. Met. 87, 171 (1997), Synth. Met. 91, 209 (1997), Synth. Met. 111, 421 (2000), SID Symposium Digest, 37, 923 (2006), J. Mater. Chem. 3, 319 (1993), Adv. Mater. 6, 677 (1994), Chem. Mater. 15, 3148 (2003), US 2003/0162053 A, US 2002/0158242 A, US 2006/0240279 A, US 2008/0220265 A, U.S. PAt. No. 5,061,569, WO 2007/002683 A, WO 2009/018009 A, EP 650955 B, US 2008/0124572 A, US 2007/0278938 A, US 2008/0106190 A, US 2008/0018221 A, WC) 2012/115034 A, JP 2003-519432 A, JP 2006-135145 A, and US 13/585981 A.

The hole transport material may be used singly or in combination of two or more kinds.

<<Electron Blocking Layer>>

The electron blocking layer is a layer having a function of a hole transport layer in a broad sense, is preferably formed of a material having a function of transporting a hole and having small ability to transport an electron, and can improve a probability of recombining an electron and a hole by blocking an electron while transporting a hole.

In addition, the above configuration of the hole transport layer can be used as the electron blocking layer according to the present invention as necessary.

The electron blocking layer disposed in the organic EL element of the present invention is preferably disposed adjacent to the positive electrode side of the light emitting layer.

The layer thickness of the electron blocking layer is preferably within a range of 3 to 100 nm, and more preferably within a range of 5 to 30 nm.

As a material used for the electron blocking layer, the above materials used for the hole transport layer are preferably used. In addition, the above host compound is also preferably used for the electron blocking layer.

<<Hole Injection Layer>>

The hole injection layer (also referred to as “positive electrode buffer layer”) is a layer disposed between the positive electrode and the light emitting layer in order to lower a driving voltage or to enhance light emission brightness. Details of the hole injection layer are described in Part 2, Chapter 2, “Electrode Material” (pp. 123 to 166) of “Organic EL element and Frontiers of Industrialization Thereof (issued by NTS Inc. on Nov. 30, 1998).

The hole injection layer is disposed as necessary, and may be disposed between the positive electrode and the light emitting layer as described above, or between the positive electrode and the hole transport layer.

Details of the hole injection layer are also described in JP 9-45479 A, JP 9-260062 A, JP 8-288069 A, and the like. Examples of a material used for the hole injection layer include a material used for the above hole transport layer.

Among these materials, a phthalocyanine derivative typified by copper phthalocyanine, a hexaazatriphenylene derivative as described in JP 2003-519432 A, JP 2006-135145 A, or the like, a metal oxide typified by vanadium oxide, amorphous carbon, a conductive polymer such as polyaniline (emeraldine) or polythiophene, an orthometallated complex typified by a tris(2-phenylpyridine) iridium complex, a triarylamine derivative, and the like are preferable.

The above materials used for the hole injection layer may be used singly or in combination of a plurality of kinds thereof.

<<Additive>>

The above organic layer may further include another additive.

Examples of the additive include a halogen element such as bromine, iodine, or chlorine, a halogenated compound, an alkali metal or an alkaline earth metal such as Pd, Ca, or Na, a compound of a transition metal, a complex, and a salt.

The content of the additive can be determined arbitrarily, but is preferably 1000 ppm or less, more preferably 500 ppm or less, and still more preferably 50 ppm or less with respect to the total % by mass of layers included.

However, the content is not within this range for some purposes of improving an electron-transporting property and a hole-transporting property, a purpose of making exciton energy transfer advantageous, and the like.

<<Method For Forming Organic Layer>>

A method for forming an organic layer (a hole injection layer, a hole transport layer, a light emitting layer, a hole blocking layer, an electron transport layer, an electron injection layer, an intermediate layer, or the like) will be described.

The method for forming an organic layer is not particularly limited, and a conventionally known forming method such as a vacuum vapor deposition method or a wet method (also referred to as a wet process) can be used.

Examples of the wet method include a spin coating method, a casting method, an inkjet method, a printing method, a die coating method, a blade coating method, a roll coating method, a spray coating method, a curtain coating method, and a Langmuir-Blodgett method (LB method). However, a method suitable for a roll-to-roll method, such as a die coatiting method, a roll coating method, an ink jet method, or a spray coating method, is preferable from a viewpoint of obtaining a homogeneous thin film easily and high productivity.

Examples of a liquid medium in which an organic EL material is dissolved or dispersed include a ketone such as methyl ethyl ketone or cyclohexanone, a fatty acid ester such as ethyl acetate, a halogenated hydrocarbon such as dichlorobenzene, an aromatic hydrocarbon such as toluene, mesitylene, or cyclohexylbenzene, an aliphatic hydrocarbon such as cyclohexane, decalin, or dodecane, and an organic solvent such as DMF or DMSO.

In addition, as a dispersing method, dispersing can be performed by ultrasonic wave, high shearing force dispersion, media dispersion, or the like.

Furthermore, a film forming method varying depending on a layer may be applied. In a case of adopting a vapor deposition method for film formation, vapor deposition conditions therefor vary depending on the kind of a compound to be used or the like. However, in general, the conditions are desirably selected appropriately while a boat heating temperature is within a range of 50 to 450° C., the degree of vacuum is within a range of 10⁻⁶ to 10⁻² Pa, a vapor deposition rate is within a range of 0.01 to 50 nm/sec, a substrate temperature is within a range of −50 to 300° C., and a layer (film) thickness is within a range of 0.1 nm to 5 μm, preferably within a range of 5 to 200 nm.

Formation of an organic layer is preferably performed from a hole injection layer to a negative electrode consistently with a single evacuation, but a product may be taken out during manufacture and may be subjected to a different film forming method. In this case, operation is preferably performed in a dry inert gas atmosphere.

[Support Substrate]

For a support substrate (hereinafter, also referred to as a substrate, a base material, or the like) that can be used for the organic EL element of the present invention, there is no particular limitation on the type such as glass or plastic, and the support substrate may be transparent or opaque. In a case where light is extracted from the support substrate side, the support substrate is preferably transparent. Preferable examples of the transparent support substrate include glass, quartz, and a transparent resin film. A particularly preferable support substrate is a resin film capable of imparting flexibility to the organic EL element.

Examples of the resin film include a polyester such as polyethylene terephthalate (PET) or polyethylene naphthalate (PEN), polyethylene, polypropylene, a cellulose ester and a derivative thereof such as cellophane, cellulose diacetate, cellulose triacetate (TAC), cellulose acetate butyrate, cellulose acetate propionate (CAP), cellulose acetate phthalate, or cellulose nitrate, polyyvinylidene chloride, polyvinyl alcohol, polyethylene vinyl alcohol, syndiotactic polystyrene, polycarbonate, a norbornene resin, polymethylpentene, polyetherketone, polyimide, polyethersulfone (PES), polyphenylene sulfide, a polysulfone, polyether imide, polyether ketone imide, polyamide, fluororesin, nylon, polymethyl methacrylate, anacrylic resin, a polyarylate, and a cycloolefin-based resin such as Arton (trade mine, manufactured by JSR Corporation) or Apel (trade name, manufactured by Mitsui Chemicals, Inc.).

On a surface of the resin film, a coating film of an inorganic substance, a coating film of an organic substance, or a hybrid coating film of both the inorganic substance and the organic substance may be formed. The resin film is preferably a barrier film having a water vapor transmittance of 0.01 g/m²·24 h or less (25±0.5° C., relative humidity (90±2)% RH) measured by a method in accordance with JIS K 7129-1992, and is more preferably a high barrier film having an oxygen transmittance of 1×10⁻³ ml/m²·24 h·atm or less measured by a method in accordance with JIS K 7126-1987, and a water vapor transmittance of 1×10⁻⁵ g/m²·24 h or less.

A material for forming a barrier film only needs to have a function of suppressing infiltration of a substance that causes deterioration of an element, such as moisture or oxygen. Examples of the material include silicon oxide, silicon dioxide, and silicon nitride. In order to further improve brittleness of the film, it is more preferable to form a laminated structure including such an inorganic layer and an organic material layer. The order of laminating the inorganic layer and the organic layer is not particularly limited, but the inorganic layer and the organic layer are preferably laminated alternately a plurality of times.

A method for forming a barrier film is not particularly limited, and examples thereof include a vacuum vapor deposition method, a sputtering method, a reactive sputtering method, a molecular beam epitaxy method, a cluster ion beam method, an ion plating method, a plasma polymerization method, an atmospheric pressure plasma polymerization method, a plasma CVD method, a laser CVD method, a thermal CVD method, and a coating method. However, an atmospheric pressure plasma polymerization method as described in JP 2004-68143 A is particularly preferable.

Examples of the opaque support substrate include a metal plate such as aluminum or stainless steel, a film, an opaque resin substrate, and a ceramic substrate.

The external extraction quantum efficiency of light emission of the organic EL element of the present invention at room temperature (25° C.) is preferably 1% or more, and more preferably 5% or more.

Here, the external extraction quantum efficiency (%)=the number of photons emitted to the outside of the organic EL element/the number of electrons that have flowed through the organic EL element×100.

In addition, a hue improving filter such as a color filter may be used in combination, or a color conversion filter for converting an emission color obtained from the organic EL element into a multicolor using a phosphor may be used in combination.

[Sealing]

Examples of a sealing means used for sealing the organic EL element of the present invention include a method for bonding a sealing member to an electrode and a support substrate with an adhesive. The sealing member only needs to be disposed so as to cover a display region of the organic EL element, and may have a recessed plate shape or a flat plate shape.

In addition, transparency and an electrical insulation property are not particularly limited.

Specific examples of the sealing member include a glass plate, a polymer plate film, and a metal plate/film. Particular examples of the glass plate include soda-lime glass, barium/strontium-containing glass, lead glass, aluminosilicate glass, borosilicate glass, barium borosilicate glass, and quartz. In addition, examples of the polymer plate include polycarbonate, an acrylic resin, polyethylene terephthalate, polyethersulfide, and polysulfone. Examples of the metal plate include a plate formed of one or more metals or alloys selected from the group consisting of stainless steel, iron, copper, aluminum, magnesium, nickel, zinc, chromium, titanium, molybdenum, silicon, germanium, and tantalum.

In the present invention, a polymer film or a metal film can be preferdbly used because the organic EL element can be thinned. Furthermore, the polymer film preferably has an oxygen transmittance of 1×10⁻³ ml/m²·24 h·atm or less measured by a method in accordance with JIS K 7126-1987, and a water vapor transmittance of 1×10⁻³ g/m²·24 h or less (25±0.5° C., relative humidity 90±2%) measured by a method in accordance with JIS K 7129-1992.

Sandblast processing, chemical etching processing, or the like is used to process the sealing member into a recessed shape.

Specific examples of the adhesive include a photocurable or thermosetting adhesive having a reactive vinyl group, such as an acrylic acid-based oligomer or a methacrylic acid-based oligomer, and a moisture-curable adhesive such as 2-cyanoacrylate. In addition, examples of the adhesive include a thermally or chemically curable (two-liquid mixing) adhesive, such as an epoxy-based adhesive. In addition, examples of the adhesive include hot melt type polyamide, polyester, and polyolefin. In addition, examples of the adhesive include a cationically curable ultraviolet curable epoxy resin adhesive.

Niote that the organic EL element may be deteriorated by heat treatment. Therefore, an adhesive capable of adhesion and curing from room temperature to 80° C. is preferable. In addition, a desiccant may be dispersed in the adhesive. An adhesive may be applied to a sealing portion using a commercially available dispenser or by printing like screen printing.

In addition, it is also preferable to form a layer of an inorganic substance and an organic substance so as to cover an electrode facing a support substrate with an organic layer sandwiched therebetween and the organic layer outside the electrode in contact with the support substrate, and to use the layer as a sealing film. In this case, a material for forming the film only needs to have a function of suppressing infiltration of a substance that causes deterioration of an element, such as moisture or oxygen. Examples of the material include silicon oxide, silicon dioxide, and silicon nitride.

In order to further improve brittleness of the film, it is preferdble to form a laminated structure including such an inorganic layer and an organic material layer. A method for forming the film is not particularly limited, and examples thereof include a vacuum vapor deposition method, a sputtering method, a reactive sputtering method, a molecular beam epitaxy method, a cluster ion beam method, an ion plating method, a plasma polymerization method, an atmospheric pressure plasma polymerization method, a plasma CVD method, a laser CVD method, a thermal CVD method, and a coating method.

An inert gas such as nitrogen or argon or an inert liquid such as fluorohydrocarbon or silicone oil is preferably injected into a gap between the sealing member and a display region of the organic EL element in a gas phase or a liquid phase. In addition, it is also possible to make the gap vacuum. In addition, a hygroscopic compound can be encapsulated inside the gap.

Examples of the hygroscopic compound include a metal oxide (for example, sodium oxide, potassium oxide, calcium oxide, barium oxide, magnesium oxide, or aluminum oxide), a sulfate (for example, sodium sulfate, calcium sulfate, magnesium sulfate, or cobalt sulfate), a metal halide (for example, calcium chloride, magnesium chloride, cesium fluoride, tantalum fluoride, cerium bromide, magnesium bromide, barium iodide, or magnesium iodide), and a perchloric acid (for example, barium perchlorate or magnesium perchlorate). As the sulfate, the metal halide, or the perchloric acid, an anhydrous salt is preferably used.

[Protective Film and Protective Plate]

A protective film or a protective plate may be disposed outside the sealing film or the sealing film facing the support substrate with the organic layer sandwiched therebetween in order to increase the mechanical strength of the element. Particularly, in a case where sealing is performed with the sealing film, the mechanical strength is not necessarily high. Therefore, it is preferable to dispose such a protective film or protective plate. As a material that can be used for the protective film or the protective plate, a glass plate, a polymer plate/film, a metal plate/film, or the like similar to the material used for the above sealing can be used. However, a polymer film is preferably used from viewpoints of light weight and thin film formation.

[Light Extraction Improvement Technique]

It is generally said that an organic EL element emits light inside a layer having a refractive index higher than air (within a range of a refractive index of about 1.6 to 2.1) and can extract only about 15% to 20% of light generated in the light emitting layer. This is because light incident on an interface (interface between a transparent substrate and air) at an angle θ equal to or larger than a critical angle cannot be extracted to the outside of the element due to total reflection, and light is totally reflected between the transparent electrode or the light emitting layer and the transparent substrate, the light is propagated through the transparent electrode or the light emitting layer, and as a result, the light escapes in a lateral direction of the element.

Examples of a method for improving efficiency of extracting the light include a method for forming irregularities on a surface of a transparent substrate to prevent total reflection at an interface between the transparent substrate and air (for example, U.S. Pat. No. 4,774,435), a method for improving efficiency by imparting a light-condensing property to a substrate (for example, JP 63-314795 A), a method for forming a reflecting surface on a side surface or the like of an element (for example, JP 1-220394 A), a method for introducing a flat layer having an intermediate refractive index between a substrate and a light emitter to form an antireflection film. (for example, JP 62472691 A), a method for introducing a flat layer having a lower refractive index than a substrate between the substrate and a light emitter (for example, JP 2001-202827 A), and a method for forming a diffraction grating on a substrate or between any layers such as a transparent electrode layer and a light emitting layer (may be formed between the substrate and the outside world) (JP 11-283751 A).

In the present invention, these methods can be used in combination with the organic EL element of the present invention. However, the method for introducing a flat layer having a lower refractive index than a substrate between the substrate and a light emitter or the method for forming a diffraction grating on a substrate or between any layers such as a transparent electrode layer and a light emitting layer (may be formed between the substrate and the outside world) can be preferably used.

In the present invention, by combining these means, it is possible to obtain an element having higher brightness or better durability.

When a medium having a low refractive index is formed between a transparent electrode and a transparent substrate with a thickness larger than the wavelength of light, light emitted from the transparent electrode has higher extraction efficiency to the outside as the refractive index of the medium is lower. Examples of the low refractive index layer include aerogel, porous silica, magnesium fluoride, and a fluorine-based polymer. The refractive index of a transparent substrate is generally within a range of about 1.5 to 1.7. Therefore, the refractive index of the low refractive index layer is preferably about 1.5 or less. The refractive index of the low refractive index layer is more preferably 1.35 or less.

In addition, the thickness of the low refractive index medium is desirably twice or more the wavelength in the medium. This is because when the thickness of the low refractive index medium is about the same as the wavelength of light and is a thickness at which an electromagnetic wave which has leaked out by evanescence enters a substrate, an effect of the low refractive index layer is reduced.

The method for introducing a diffraction grating into an interface causing total reflection or into any medium has a feature that an effect of improving the light extraction efficiency is high. In this method, by utilizing a property that the diffraction grating can change the direction of light to a specific direction different from refraction by so-called Bragg diffraction such as first order diffraction or second order diffraction, it is tried to cause diffraction of a light beam that cannot go outside due to total reflection or the like between layers among light beams that have been generated from a light emitting layer by introducing a diffraction grating between any layers or in a medium (in a transparent substrate or in a transparent electrode) to extract the light beam outside.

The diffraction grating to be introduced desirably has a two-dimensional periodic refractive index. This is because light emitted in a light emitting layer is randomly generated in every direction, and therefore, in a general one-dimensional diffraction grating having a periodic refractive index distribution only in a certain direction, only light traveling in a specific direction is diffracted, and the light extraction efficiency does not increase so much.

However, by making the refractive index distribution two-dimensionally distributed, light traveling in every direction is diffracted, and the light extraction efficiency increases.

The diffraction grating may be introduced between any layers or in a medium (in the transparent substrate or in the transparent electrode), but is desirably introduced in the vicinity of an organic light emitting layer where light is generated. In this case, the period of the diffraction grating is preferably within a range of about ½ to 3 times the wavelength of light in the medium. As arrangement of the diffraction gratings, two-dimensional arrangement such as a square lattice shape, a triangular lattice shape, or a honeycomb lattice shape is preferably repeated.

[Light-Condensing Sheet]

The organic EL element of the present invention can enhance brightness in a specific direction by condensing light in a specific direction, for example, in a front direction with respect to an element light emitting surface by forming, for example, a structure on a microlens array on a light extraction side of a support substrate (substrate) or by combination with a so-called light-condensing sheet.

As an example of the microlens array, quadrangular pyramids each having a side of 30 μm and an apex angle of 90° are arranged two-dimensionaily on the light extraction side of a substrate. One side is preferably within a range of 10 to 100 μm. If the size is smaller than this size, an effect of diffraction is generated, and coloring occurs. If the size is too large, the thickness is thick, and this is not preferable.

As the light-condensing sheet, it is possible to use, for example, a light-condensing sheet practically used for an LED backlight of a liquid crystal display device. Examples of such a sheet include a brightness enhancement film (BEF) manufactured by Sumitomo 3M. As the shape of a prism sheet, for example, a base material having a triangular stripe having an apex angle of 90° and a pitch of 50 μm may be used, or a shape having a rounded apex angle, a shape having a pitch randomly changed, or another shape may be used.

In addition, in order to control a light emission angle from the organic EL element, a light diffusing plate/film may be used in combination with the light-condensing sheet. For example, a diffusing film (Lightup) manufactured by kimoto Ltd. can be used.

The organic EL element of the present invention can efficiently transfer excitation energy generated in the light emitting layer to the second organic compound, and therefore can achieve an organic EL element capable of suppressing deterioration of the organic layer and having a small change in resistance value over time during passage of a current. A resistance value of the organic layer of the present invention can be measured by impedance spectroscopy.

<Measurement Example of Thin Film Resistance Value by Impedance Spectroscopic Measurement>

Impedance spectroscopy (IS) is a measurement method for applying a micro sine wave voltage signal to an organic electroluminescent element, and calculating an impedance from an amplitude and a phase of a response current signal to the micro sine wave voltage signal to obtain and an impedance spectrum as a function of the frequency of the applied voltage signal.

A plot obtained by displaying the resulting impedance on a complex plane using the frequency of the applied voltage signal as a parameter is called a Cole-Cole plot. From the impedance, it is possible to obtain modulus, admittance, and a dielectric constant as basic transfer functions. A transfer function suitable for analysis can be selected from these four transfer functions (see “Impedance Spectroscopy of Organic Electronics Element”, Applied Physics Vol. 76, No. 11, 2007, 1252-1258).

The present invention adopts a modulus (M) plot (M-plot) indicating a reciprocal of an electrostatic capacity component. In M-plot, the diameter of a circular arc portion is almost a reciprocal of an electrostatic capacity of a corresponding layer and is proportional to the film thickness. Therefore, by comparing diameters of circular arc portions of a plurality of samples, deviation in film thickness can be detected.

In addition, in analysis of the IS method, an equivalent circuit of an organic electroluminescent element is estimated from a locus of the Cole-Cole plot. Then, generally, the locus of the Cole-Cole plot calculated from the estimated equivalent circuit is fitted with measurement data to determine an equivalent circuit.

The IS measurement can be performed by superimposing an alternating current (frequency range: 0.1 mHz to 10 MHz) of 30 to 100 mV rms to a direct current voltage, for example, using a solartron 1260 type impedance analyzer and a 1296 type dielectric constant measuring interface manufactured by Solartron Co.

For equivalent circuit analysis, ZView manufactured by Scribner Associates can be used.

A method for applying impedance spectroscopy to an organic EL element (element configuration “ITO/HIL (hole injection lager)/HTL (hole transport layer)/EML (light emitting layer)/ETL (electron transport layer)/EIL (electron injection layer)/A1”) to determine a resistance value of a specific layer will be described. For example, in a case where a resistance value of an electron transport layer (ETL) is measured, several elements with only the ETL thickness changed are prepared, and M-plots of the elements are compared, and it is thereby possible to determine which part of a curve drawn by each of the plots corresponds to ETL.

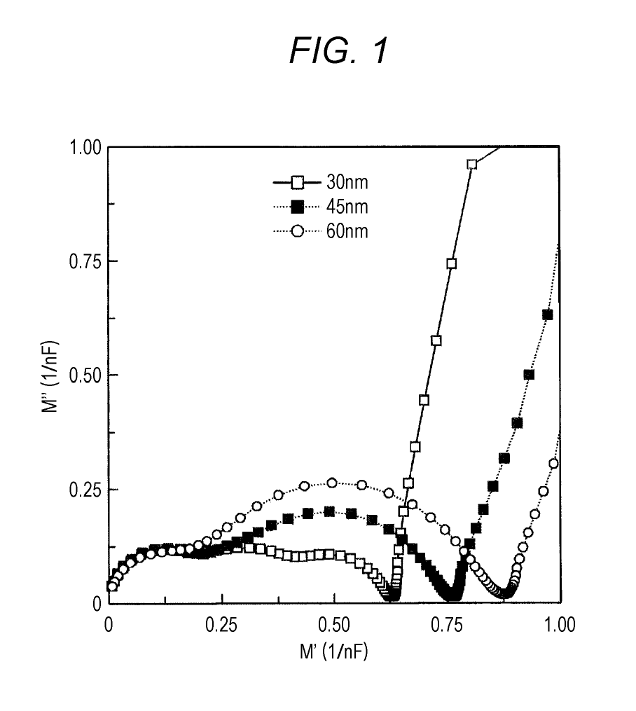

FIG. 1 illustrates examples of M-plots in a case where an electron transport layer has various film thicknesses. FIG. 1 illustrates examples in cases where the film thicknesses are 30, 45 and 60 nm. The vertical axis indicates an imaginary part M″ (nF-1), and the horizontal axis indicates a real part M′ (nF-1).

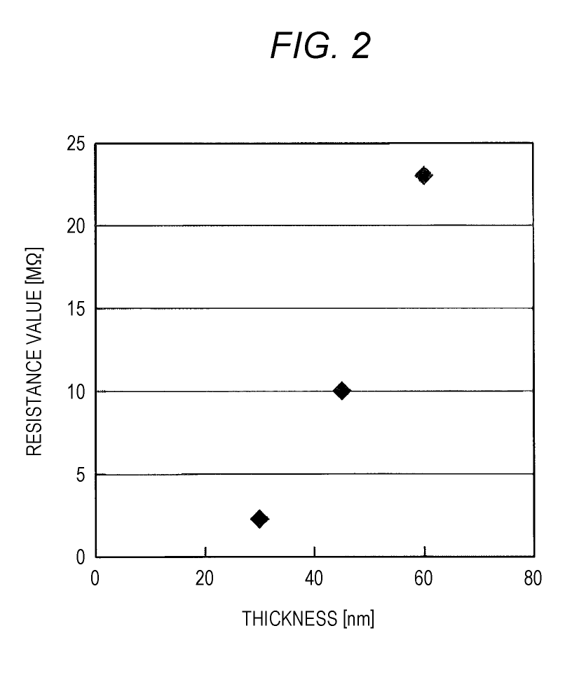

FIG. 2 is a graph illustrating an example of a relationship between an ETL film thickness and a resistance value determined from the plot of FIG. 1. As illustrated in FIG. 2, a resistance value (R) is substantially linearly proportional to an ETL thickness. Therefore, a resistance value at each film thickness can be determined.

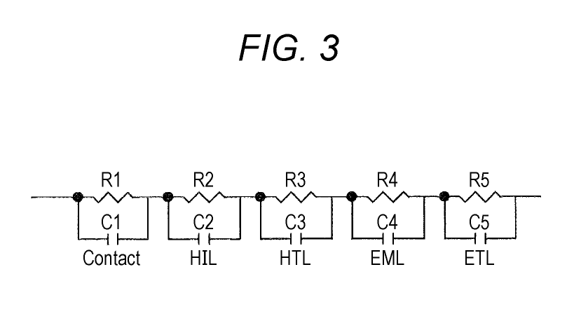

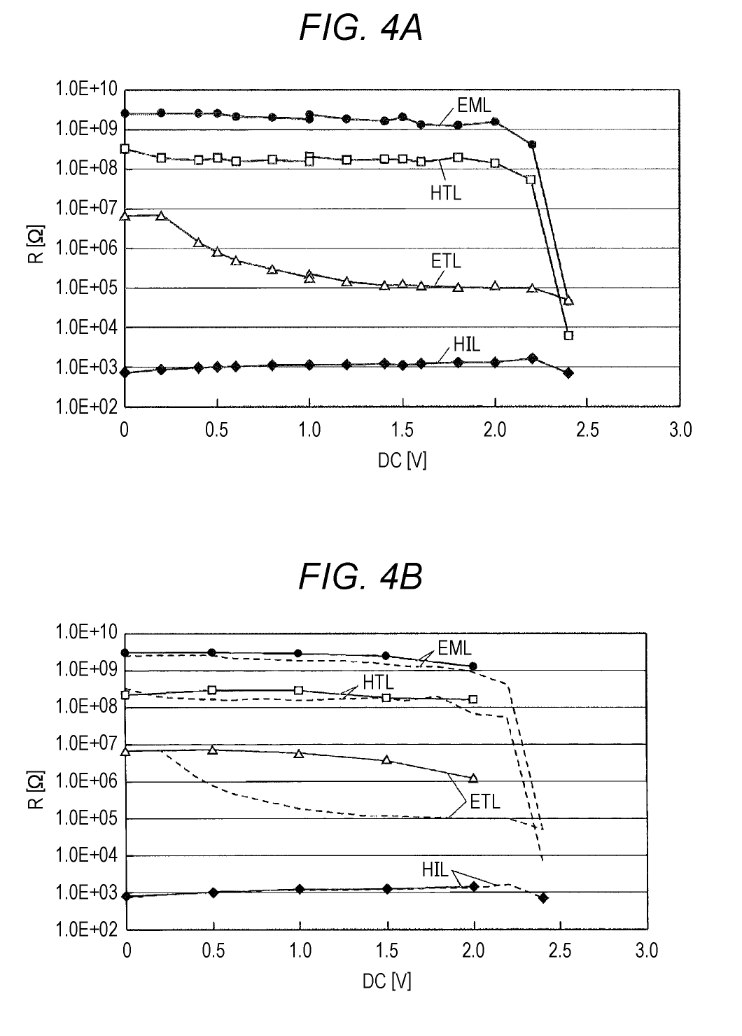

FIG. 3 is a diagram illustrating an equivalent circuit model of an organic EL element having an element configuration “ITO/HIL/HTL/EML/ETL/A1”. FIG. 4A is a graph illustrating an example of a relationship between resistance and voltage in each layer of an organic EL element, analyzed based on FIG. 3. FIG. 4B is a graph illustrating an example of a relationship between resistance and voltage in each layer of an organic EL element after deterioration, analyzed based on FIG. 3. FIG. 4B is a graph obtained by causing the same organic EL element as that of FIG. 4A to emit light for a long time to deteriorate the organic EL element, then performing measurement under certain conditions, and superimposing the obtained measurement result on the graph of FIG. 4A. In addition, resistance values of the layers at voltage of 1 V in FIGS. 4A and 4B are summarized in Table 1.

TABLE 1

| | HIL(Ω) | ETL(Ω) | HTL(Ω) | EML(Ω) |
|---|---|---|---|---|
| Before driving | 1.1k | 0.2M | 0.2 G | 1.9 G |
| After deterioration | 1.2k | 5.7M | 0.3 G | 2.9 G |

In the deteriorated organic EL element, only the electron transport layer (ETL) has largely increased a resistance value thereof due to deterioration, and at the DC voltage of 1 V, the resistance value becomes approximately 30 times. It is found that a change ratio in resistance value between before and after driving is large. By using the above method, it is possible to measure a change ratio (%) in resistance value between before and after driving described in Examples of the present invention.

[Use]

The organic EL element of the present invention can be used as an electronic apparatus, for example, a display device, a display, and various light emitting devices. Examples of the light emitting devices include an illumination device (household illumination, vehicle interior illumination, vehicle exterior illumination, or a light source for an infrared camera), backlights for a watch and a liquid crystal, a signboard advertisement, a traffic signal, a light source of an optical storage medium, a light source of an electrophotographic copying machine, a light source of an optical communication processor, and a light source of an optical sensor, but the present invention is not limited thereto. The organic EL element of the present invention can be used effectively particularly as a light source for illumination such as a light source of an optical communication processor or a light source of an optical sensor. In the organic EL element of the present invention, patterning may be performed with a metal mask, by an inkjet printing method, or the like at the time of film formation as necessary. In a case of patterning, only an electrode may be patterned, an electrode and a light emitting layer may be patterned, or all layers of an element may be patterned. A conventionally known method can be used for manufacturing an element.

<Display device>

A display device including the organic EL element of the present invention may be monochrome or multicolor, but a multicolor display device will be described here.

In a case of a multicolor display device, a shadow mask is formed only at the time of forming a light emitting layer, and a film can be formed on one side by a vapor deposition method, a casting method, a spin coating method, an inkjet method, a printing method, or the like.

In a case of patterning only a light emitting layer, there is no limitation on a method therefor, but a vapor deposition method, an ink jet method, a spin coating method, and a printing method are preferable.

The configuration of the organic EL element included in the display device is selected from among the above configuration examples of the organic EL element as necessary.

In addition, a method for manufacturing the organic EL element is as illustrated in the above manufacture of the organic EL element according to an embodiment of the present invention.

In a case where a direct current voltage is applied to the multicolor display device thus obtained, light emission can be observed when a voltage of about 2 to 40 V is applied with a positive electrode having a positive polarity and a negative electrode having a negative polarity. In addition, even when a voltage is applied with the opposite polarity, a current does not flow, and light is not emitted at all. In a case where an alternating current voltage is further applied, light is emitted only when the positive electrode becomes positive and the negative electrode becomes negative. Note that a waveform of the applied alternating current may be arbitrary.

The multicolor display device can be used as a display device, a display, or various light emission sources. In the display device or the display, full color display is possible by using three kinds of organic EL elements of blue, red, and green light emission.

Examples of the display device or the display include a television, a personal computer, a mobile apparatus, an AV apparatus, a text broadcast display, and information display in an automobile. The display device or the display may be used particularly as a display device for reproducing a still image or a moving image. In a case where the display device or the display is used as a display device for moving image reproduction, either a simple matrix (passive matrix) method or an active matrix method may be used.

Examples of the light emitting device include household illumination, vehicle exterior illumination, a light source for an infrared camera, backlights for a watch and a liquid crystal, a signboard advertisement, a traffic signal, a light source of an optical storage medium, a light source of an electrophotographic copying machine, a light source of an optical communication processor, and a light source of an optical sensor, but the present invention is not limited thereto.

Hereinafter, an example of a display device including the organic EL element of the present invention will be described with reference to the drawings.

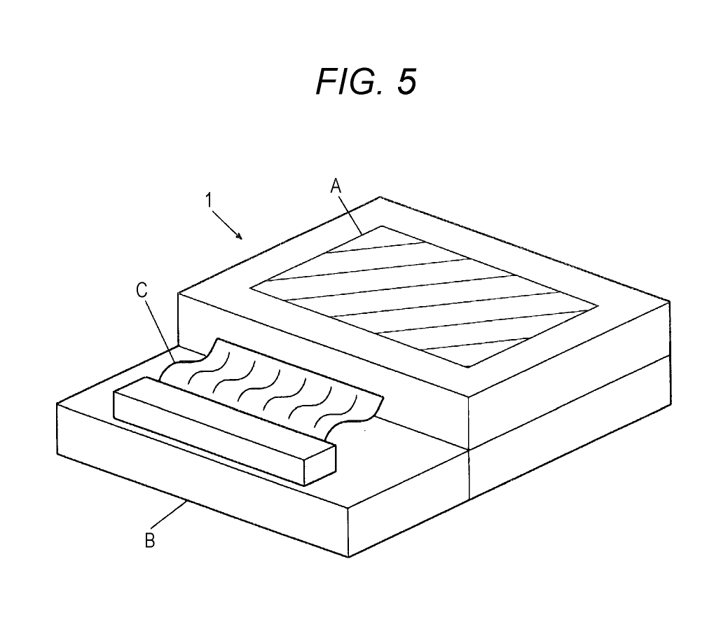

FIG. 5 is a schematic view illustrating an example of a display device including an organic EL element. FIG. 5 is a schematic view of a display for displaying image information by light emission of an organic EL element, such as a mobile phone.

A display 1 includes a display A having a plurality of pixels, a controller B for performing image scanning of the display A based on image information, wiring C for electrically connecting the display A to the controller B, and the like.

The controller B is electrically connected to the display A via the wiring C, sends a scanning signal and an image data signal to each of the plurality of pixels based on image information from the outside, performs image scanning by sequential emitting of light by a pixel for each scanning line according to the image data signal due to the scanning signal, and displays image information on the display A.

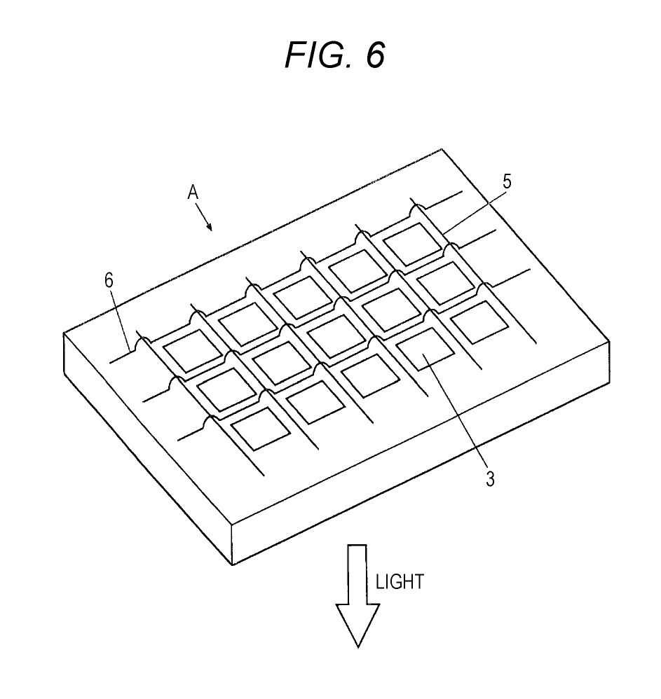

FIG. 6 is a schematic view of a display device according to an active matrix method.

The display A includes the wiring C including a plurality of scanning lines 5 and data lines 6, a plurality of pixels 3, and the like on a substrate. Main members of the display A will be described below.

In FIG. 6 illustrates a case where light emitted from the pixels 3 is extracted in the direction of the white arrow (downward direction).

The scanning lines 5 and the plurality of data lines 6 in the wiring are formed of conductive materials. The scanning lines 5 and the data lines 6 are orthogonal to each other in a lattice shape and are connected to the pixels 3 at orthogonal positions (details thereof are not illustrated).

When a scanning signal is applied from one of the scanning lines 5 to one of the pixels 3, the pixel 3 receives an image data signal from one of the data lines 6 and emits light according to the received image data.

By arranging pixels having a light emission color in a red region, pixels having a light emission color in a green region, and pixels having a light emission color in a blue region on the same substrate appropriately, full color display is possible.

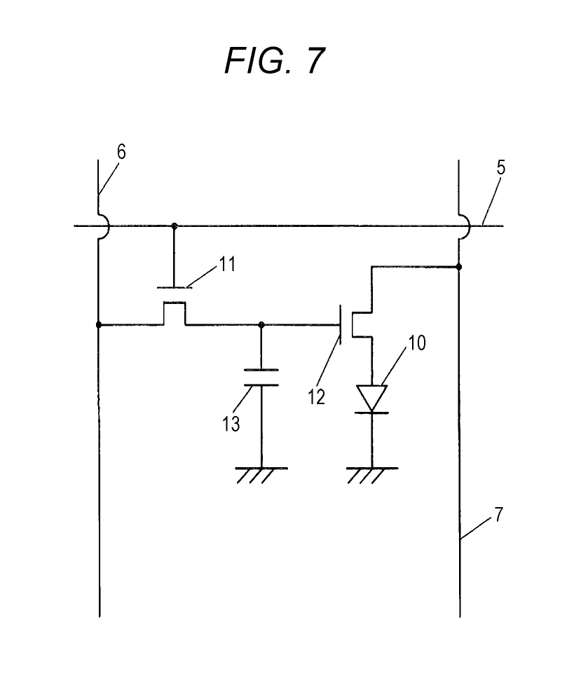

Next, a light emitting process of a pixel will be described. FIG. 7 is a schematic diagram illustrating a circuit of a pixel.

The pixel includes an organic EL element 10, a switching transistor 11, a driving transistor 12, a capacitor 13, and the like. By using organic EL elements for emitting red, green, and blue light as the organic EL elements 10 for a plurality of pixels and juxtaposing these elements on the same substrate, full color display can be petformed.

In FIG. 7, an image data signal is applied from the controller B to a drain of the switching transistor 11 via the data lines 6. Then, when a scanning signal is applied from the controller B to a gate of the switching transistor 11 via the scanning lines 5, driving of the switching transistor 11 is turned on, and the image data signal applied to the drain is transmitted to the capacitor 13 and a gate of the driving transistor 12.

By the transmission of the image data signal, the capacitor 13 is charged according to the potential of the image data signal, and driving of the driving transistor 12 is turned on. A drain of the driving transistor 12 is connected to a power supply line 7, and a source thereof is connected to an electrode of the organic EL element 10. A current is supplied from the power supply line 7 to the organic EL element 10 according to the potential of the image data signal applied to the gate.

When the scanning signal is transferred to a next scanning line 5 by sequential scanning of the controller B, driving of the switching transistor 11 is turned off. However, even if driving of the switching transistor 11 is turned off, the capacitor 13 holds the potential of the charged image data signal. Therefore, driving of the driving transistor 12 is kept on, and light emission of the organic EL element 10 continues until a next scanning signal is applied. When a next scanning signal is applied by sequential scanning, the driving transistor 12 is driven according to the potential of the next image data signal synchronized with the scanning signal, and the organic EL element 10 emits light.

That is, as for light emission of the organic EL element 10, the organic EL element 10 for each of the plurality of pixels 3 emits light by disposing the switching transistor 11 and the driving transistor 12, which are active elements, in the organic EL element 10 for each of the plurality of pixels. Such a light emitting method is called an active matrix method.

Here, light emission of the organic EL element 10 may be light emission in a plurality of gradations by a multi-valued image data signal having a plurality of gradation potentials, or light emission in which a predetermined light emission amount is turned on or off by a binary image data signal. In addition, the potential of the capacitor 13 may be held continuously until a next scanning signal is applied, or may be discharged immediately before the next scanning signal is applied.

The present invention may use not only the above-described active matrix method light emission driving but also passive matrix method light emission driving in which an organic EL element emits light in response to a data signal only when a scanning signal is scanned.

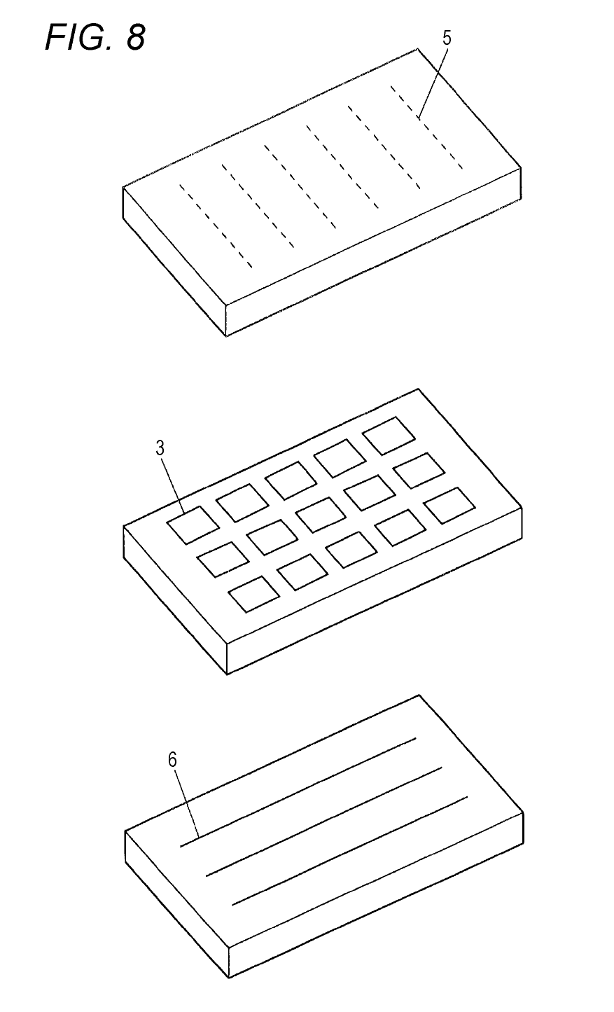

FIG. 8 is a schematic view of a display device according to a passive matrix method. In FIG. 8, a plurality of scanning lines 5 and a plurality of image data lines 6 are disposed in a lattice shape facing each other with the pixels 3 sandwiched therebetween. When a scanning signal of one of the scanning lines 5 is applied due to sequential scanning, one of the pixels 3 which is connected to the scanning line 5 and to which the signal has been applied emits light according to an image data signal.

In the passive matrix method, there is no active element in each of the pixels 3, and manufacturing cost can be reduced.

By using the organic EL element of the present invention, a display device having high luminous efficiency and a small change in resistance value over time during passage of a current can be obtained.

<illumination Device>

The organic EL element of the present invention can also be used for an illumination device.

The organic EL element of the present invention may be used as an organic EL element having a resonator structure. Examples of a purpose of using such an organic EL element having a resonator structure include a light source of an optical storage medium, a light source of an electrophotographic copying machine, a light source of an optical communication processor, and a light source of an optical sensor, but the present invention is not limited thereto. In addition, the organic EL element of the present invention may be used for the above use by causing laser oscillation.

In addition, the organic EL element of the present invention may be used as a kind of lamp such as a lamp for illumination or an exposure light source, or may be a used as a projection device that projects an image or a display device (display) with which a still image or a moving image is directly recognized visually.

In a case of use as a display device for reproducing a moving image, the driving method may be either a passive matrix method or an active matrix method.

In addition, as a method for forming the organic EL element of the present invention, it is only required to perform simple arrangement, for example, a mask is formed only at the time of forming a light emitting layer, a hole transport layer, an electron transport layer, or the like, and coloring with different colors is performed with the mask. Patterning with a mask or the like is unnecessary because the other layers are common. For example, an electrode film can be formed on one side by a vapor deposition method, a casting method, a spin coating method, an inkjet method, a printing method, or the like, and productivity is improved.

[Illumination Device According to an Embodiment of the Present Invention]

An illumination device according to an embodiment of the present invention, including the organic EL element of the present inyention, will be described.

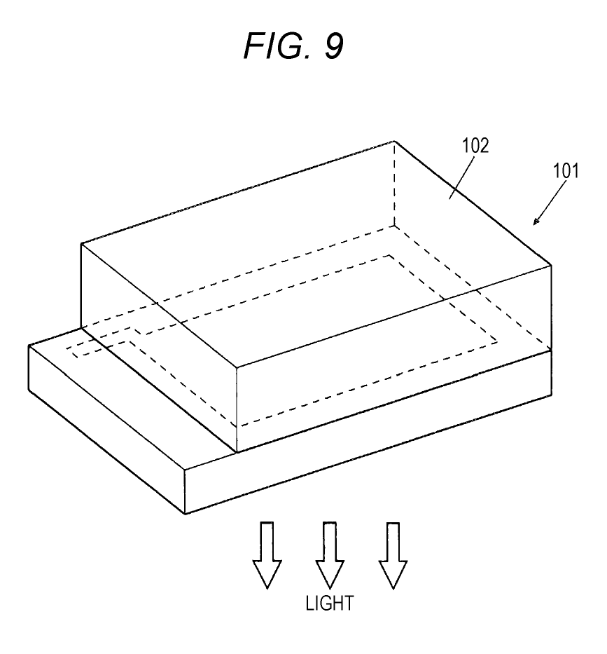

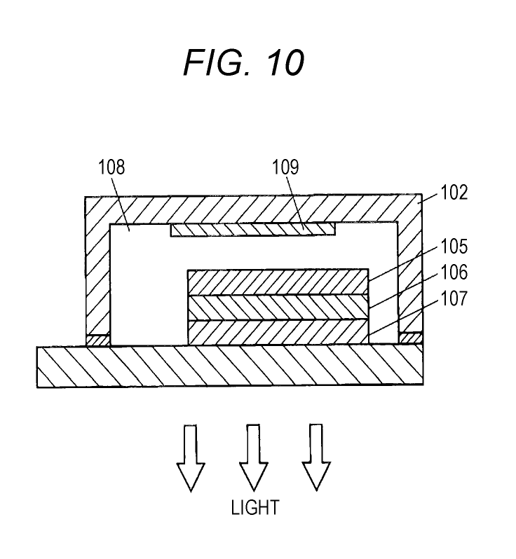

A non-light emitting surface of the organic EL element of the present invention is covered with a glass case. A glass substrate having a thickness of 300 μm is used as a sealing substrate, and an epoxy-based photocurable adhesive (Luxtrak LC0629B manufactured by Toagosei Co., Ltd.) is applied to a peripheral portion as a sealing agent. The resulting product is placed on a negative electrode to be in close contact with a transparent support substrate, irradiated with UV light from the glass substrate side, cured, and sealed to form an illumination device as illustrated in FIGS. 9 and 10.

FIG. 9 illustrates a schematic view of the illumination device, and the organic EL element of the present invention (organic EL element 101 in the illumination device) is covered with a glass cover 102 (Note that sealing operation with the glass cover was performed in a glove box (under an atmosphere of high purity nitrogen gas having a purity of 99.999% or more) under a nitrogen atmosphere without bringing the organic EL, element 101 in the illumination device into contact with the atmosphere.

FIG. 10 illustrates a cross-sectional view of the illumination device. Reference numeral 105 represents a negative electrode, reference numeral 106 represents an organic layer, and reference numeral 107 represents a glass substrate with a transparent electrode. Note that the glass cover 102 is filled with nitrogen gas 108 and includes a water-capturing agent 109.

By using the organic EL element of the present invention, an illumination device having high luminous efficiency and a small change in resistance value over time during passage of a current can be obtained.

### EXAMPLES

Hereinafter, the present invention will be specifically described with reference to Examples, but the present invention is not limited thereto. Note that an expression “%” used in Examples means “% by mass” unless otherwise particularly specified.

Compounds used in Examples and Comparative Examples are illustrated below.

(First Organic Compound)

The following compounds T-2 and T-6 were used.

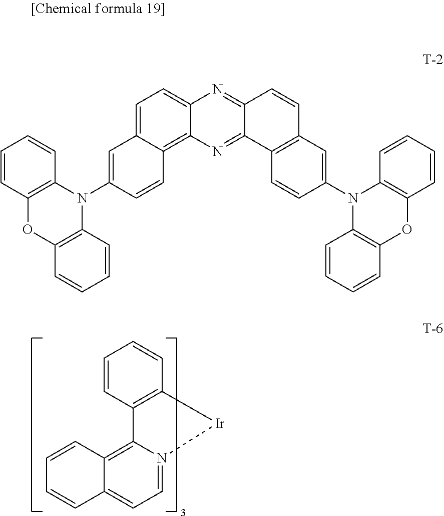

A lowest excited singlet energy level ES1(A) of compound T-2, a lowest excited triplet energy level ET1(A) at 77 K, and a lowest excited triplet energy level ET1(A) of compound T-6 at 77 K were measured by the following methods. For compound T-2, ΔE_{ST} was further calculated from the obtained value to determine ΔE_{ST}.

(Lowest Excited Singlet Energy Level ES1)

A compound to be measured was vapor-deposited on a Si substrate to prepare a sample, and a fluorescence spectrum of this sample was measured at room temperature (300 K). In the fluorescence spectrum, the vertical axis represents light emission, and the horizontal axis represents a wavelength. A tangent was drawn to a trailing edge of this emission spectrum on a short wave side, and a wavelength value λedge [nm] at an intersection between the tangent and the horizontal axis was determined. This wavelength value was converted into an energy value by the following conversion formula, and the value thus obtained was referred to as ES1.

Conversion formula: ES1[eV]=1239.85/λedge

For measurement of an emission spectrum, a nitrogen laser (MNL 200 manufactured by Lasertechnik Berlin) was used as an excitation light source, and a streak camera (C4334 manufactured by Hamamatsu Photonics KK) was used as a detector.

(Lowest Excited Triplet Energy Level ET1)

The same sample as the sample used for the singlet energy ES1 was cooled to 77 [K]. The sample for phosphorescence measurement was irradiated with excitation light (337 nm) to measure phosphorescence intensity using a streak camera. A tangent was drawn to a rising edge of this phosphorescence spectrum on a short wave side, and a wavelength value λedge [nm] at an intersection between the tangent and the horizontal axis was determined. A value obtained by converting this wavelength value into an energy value by the following conversion formula was defined as ET1.

Conversion formula: ET1[eV]=1239.85/λedge

(Calculation of ΔE_{ST})

The obtained ES1 and ET1 were applied to the following formula to determine ΔE_{ST}.

ΔE_{ST}|ES1−ET1|

The lowest excited singlet energy level ES1(A) of compound T-2 was 2.5 eV, and the lowest excited triplet energy level ET1(A) at 77 K was 2.4 eV. ΔE_{ST} of compound T-2 was 0.1 eV.

The lowest excited triplet energy level ET1 (A) of compound T-6 at 77 K was 2.0 eV.

(Second Organic Compound)

The following compounds D-2, D-10, D-32, D-35, D-47, D-52, D-60, D-16, D-65, and D-67 were used.

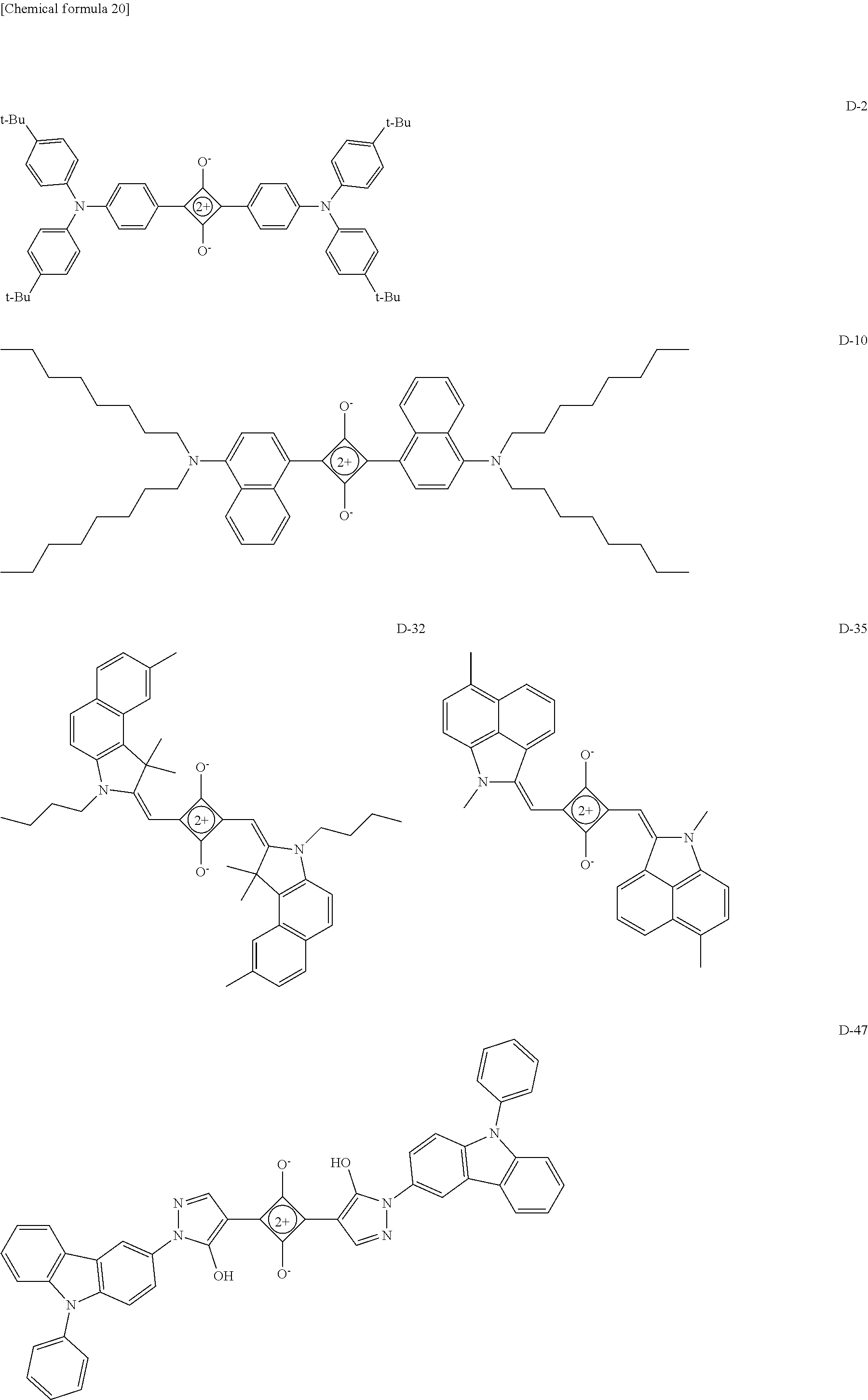

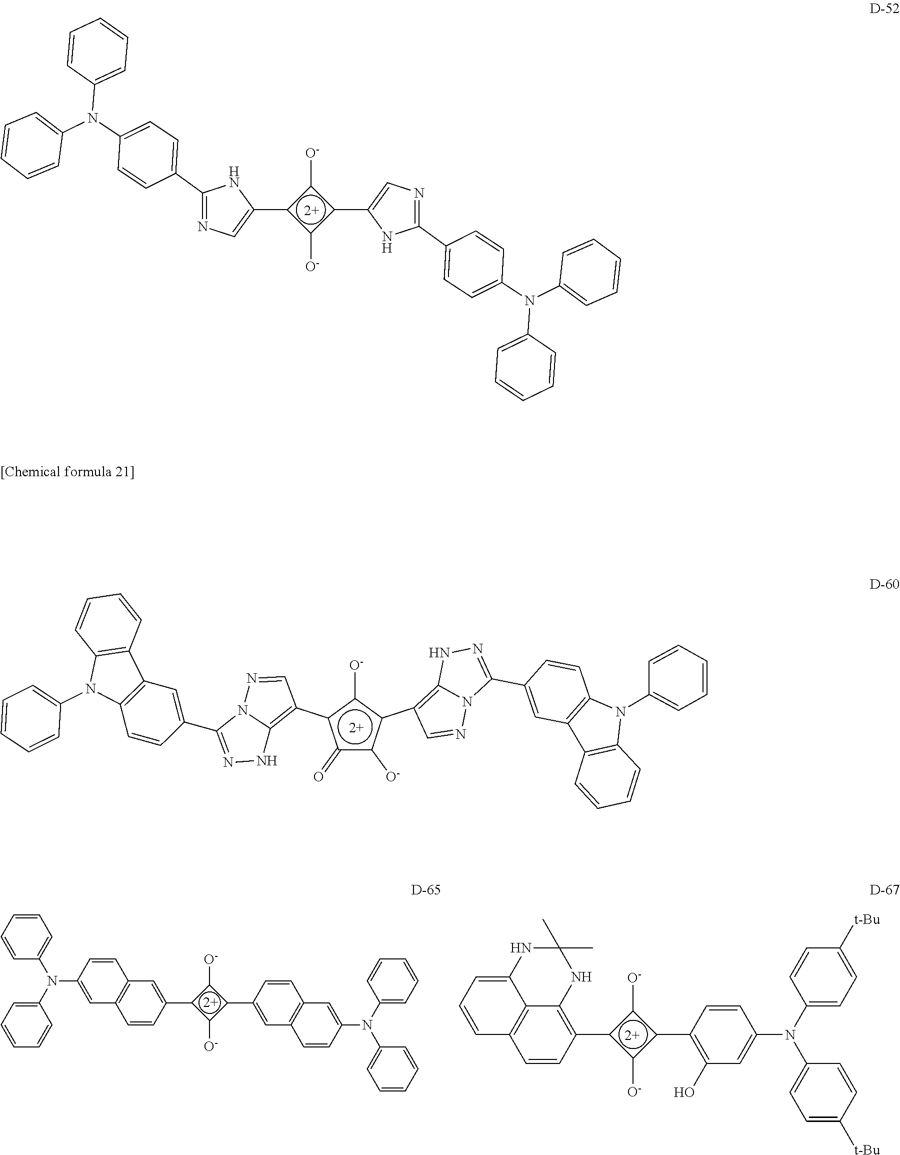

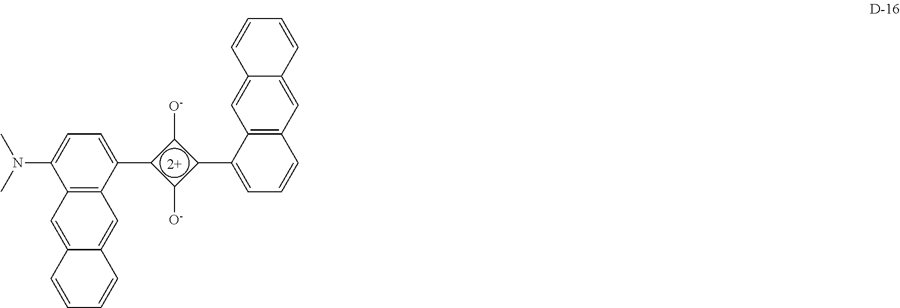

A lowest excited singlet energy level ES1(B) of each of compounds D-2, D-10, D-32, D-35, D-47, D-52, D-60, D-16, D-65, and D-67 was measured by the same method as that for the first organic compound.

As a result, the lowest excited singlet energy level ES1(B) of compound D-2 was 2.1 eV. The lowest excited singlet energy level ES1(B) of compound D-10 was 1.9 eV. The lowest excited singlet energy level ES1(B) of compound D-32 was 2.2 eV. The lowest excited singlet energy level ES1(B) of compound D-35 was 1.7 eV. The lowest excited singlet energy level ES1(B) of compound D-47 was 2.1 eV. The lowest excited singlet energy level ES1(B) of compound D-52 was 1.9 eV. The lowest excited singlet energy level ES1(B) of compound D-60 was 1.9 eV. The lowest excited singlet energy level ES1(B) of compound D-16 was 1.8 eV. The lowest excited singlet energy level ES1(B) of compound D-65 was 1.9 eV. The lowest excited singlet energy level ES1(B) of compound D-67 was 2.0 eV.

(Third Organic Compound)

The following compound (CBP) was used.

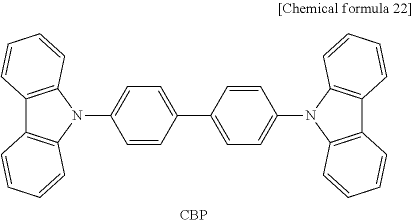 [SMILES: c1ccc2c(c1)c1ccccc1n2-c1ccc(-c2ccc(-n3c4ccccc4c4ccccc43)cc2)cc1 ; "CBP"]

A lowest excited singlet energy level ES1(C) of compound CBP and a lowest excited triplet energy level ET1(C) at 77 K were measured by the same methods as those for the first organic compound.

As a result, the lowest excited singlet energy level ES1(C) of compound CBP was 3.3 eV, and the lowest excited triplet energy level ET1(C) at 77 K was 2.6 eV.

(Other Compounds)

Comparative compounds 1 and 2 were used as comparative compounds of the second organic compound.

In addition, α-NPD was used as a hole transport material.

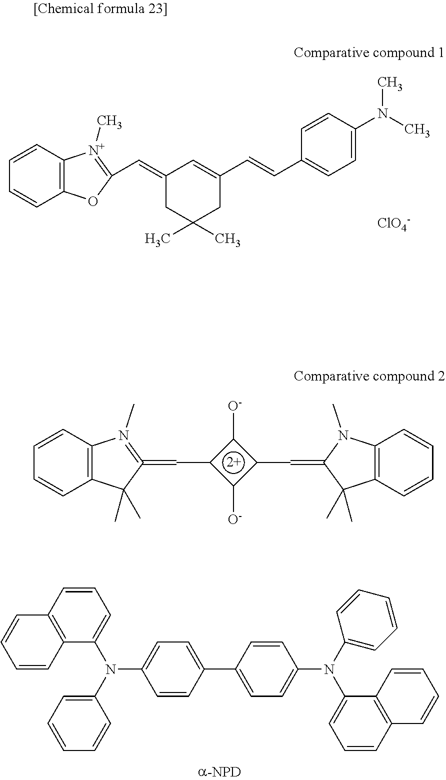

### Example 1

(Preparation of Organic EL Element 1-1)

A substrate (NA45 manufactured by NH Techno Glass Co., Ltd.) on which a film of ITO (indium tin oxide) had been formed at 100 nm on a glass substrate of 100 mm×100 mm×1.1 mm as a positive electrode was patterned. Thereafter, a transparent support substrate including this ITO transparent electrode was ultrasonically washed with isopropyl alcohol, dried with dry nitrogen gas, and washed with UV ozone for five minutes.

On this transparent support substrate, a thin film was formed using a solution obtained by diluting poly(3,4-ethylenedioxythiophene)-polystyrene sulfonate (PEDOT/PSS, manufactured by Bayer, Baytron P A 1 4083) to 70% with pure water under conditions of 3000 rpm and 30 seconds by a spin coating method, and then dried at 200° C. for one hour to dispose a hole injection layer having a layer thickness of 20 nm.

This transparent support substrate was fixed to a substrate holder of a commercially available vacuum vapor deposition device. Constituent materials of each layer were filled in each vapor deposition crucible in the vacuum vapor deposition device in an optimum amount for manufacturing each element. The vapor deposition crucible was formed of a resistance heating material made of molybdenum or tungsten.

The pressure was reduced to the degree of vacuum of 1×10⁻⁴ Pa. Thereafter, α-NPD was vapor-deposited on the hole injection layer at a vapor deposition rate of 0.1 nm/sec to form a hole transport layer having a layer thickness of 40 nm.

Subsequently, CBP as the third organic compound and comparative compound 1 as the second organic compound were co-vapor-deposited at a vapor deposition rate of 0.1 nm/sec such that the ratios thereof were 99% by mass and 1% by mass, respectively, thus forming a light emitting layer having a layer thickness of 30 nm.

Thereafter, TPBi (1,3,5-tris (N-phenylbenzimidazol-2-yl) was vapor-deposited at a vapor deposition rate of 0.1 nm/sec to form an electron transport layer having a layer thickness of 30 nm.

Furthermore, a film of sodium fluoride was formed at a film thickness of 1 nm, and then aluminum was vapor-deposited at 100 nm to form a negative electrode.

A non-light emitting surface side of the above element was covered with a can-shaped glass case in an atmosphere of high-purity nitrogen gas having a purity of 99.999% or more, and electrode extraction wiring was disposed to prepare an organic EL element 1-1.

(Preparation of Organic EL element 1-2)

An organic EL element 1-2 was prepared in a similar manner to the preparation of the organic EL element 1-1 except that a light emitting layer was formed using CBP as the third organic compound, comparative compound 2 as the second organic compound, and compound T-2 as the first organic compound such that the ratios thereof were 89%, 1%, and 10%, respectively.

(Preparation of Organic EL Element 1-3)

The layers up to the hole injection layer were formed in a similar manner to the organic EL element 1-1. Thereafter, on the hole injection layer, T-2 as the first organic compound and D-2 as the second organic compound were co-vapor-deposited at a vapor deposition rate of 0.1 nm/sec such that the ratios thereof were 99% by mass and 1% by mass, respectively, thus forming a light emitting layer having a layer thickness of 100 nm.

Furthermore, a film of sodium fluoride was formed at a film thickness of 1 nm, and then aluminum was vapor-deposited at 100 nm to form a negative electrode.

A non-light emitting surface side of the above element was covered with a can-shaped glass case in an atmosphere of high-purity nitrogen gas having a purity of 99.999% or more, and electrode extraction wiring was disposed to prepare an organic EL element 1-3.

(Preparation of Organic EL Element 1-4)

The layers up to the hole transport layer were formed in a similar manner to the organic EL element 1-1. Thereafter, CBP as the third organic compound and T-2 as the first organic compound were co-vapor-deposited at a vapor deposition rate 0.1 nm/sec such that the ratios thereof were 90% by mass and 10% by mass, respectively, thus forming a light emitting layer having a layer thickness of 30 nm. Thereafter, TPBi (1,3,5-tris(N-phenylbenzimidazol-2-yl) was vapor-deposited at a vapor deposition rate of 0.1 nm/sec to form an electron transport layer having a layer thickness of 30 nm.

Furthermore, a film of D-2 as the second organic compound was formed at a film thickness of 0.5 nm. Subsequently, a film of sodium fluoride was formed at a film thickness of 1 nm to form an electron injection layer.

Thereafter, aluminum was vapor-deposited at 100 nm to form a negative electrode.

(Preparation of Organic EL Element 1-5)

The layers up to the light emitting layer were formed in a similar manner to the organic EL element 1-4.

Subsequently, a film of D-2 as the second organic compound was fonmed at a film thickness of 0.5 nm. Thereafter, TPBi (1,3,5-tris(N-phenylbenzimidazol-2-yl) was further vapor-deposited at a vapor deposition rate of 0.1 nm/sec to form an electron transport layer having a layer thickness of 30 nm.

Furthermore, a film of sodium fluoride was formed at a film thickness of 1 nm, and then aluminum was vapor-deposited at 100 nm to form a negative electrode.

A non-light emitting surface side of the above element was covered with a can-shaped glass case in an atmosphere of high-purity nitrogen gas having a purity of 99.999% or more, and electrode extraction wiring was disposed to prepare an organic EL element 1-5.

(Preparation of Organic EL Element 1-6)

An organic EL element 1-6 was prepared in a similar manner to the preparation of the organic EL element 1-1 except that a light emitting layer was formed using CBP as the third organic compound, D-2 as the second organic compound, and T-2 as the first organic compound such that the ratios thereof were 89%, 1%, and 10%, respectively.

(Preparation of Organic EL Element 1-7)

An organic EL element 1-7 was prepared in a similar manner to the preparation of the organic EL element 1-1 except that a light emitting layer was formed using CBP as the third organic compound, D-16 as the second organic compound, and T-2 as the first organic compound such that the ratios thereof were 89%, 1%, and 10%, respectively.

(Preparation of Organic EL Element 1-8)

An organic EL element 1-8 was prepared in a similar manner to the preparation of the organic EL element 1-1 except that a light emitting layer was formed using CBP as the third organic compound, D-10 as the second organic compound, and T-6 as the first organic compound such that the ratios thereof were 89%, 1%, and 10%, respectively.

(Preparation of Organic EL Elements 1-9 to 1-16)

Organic EL elements 1-9 to 1-16 were prepared in a similar manner to the preparation of the organic EL element 1-6 except that the second organic compound was changed to the compound listed in Table 2.

(Measurement of Maximum Emission Wavelength)

A maximum emission wavelength of each sample at the time of driving an organic EL element was evaluated by performing the following measurement.

Each of the organic EL elements prepared above was allowed to emit light at a constant current of 2.5 mA/cm² at room temperature (about 25° C.), and an emission spectrum immediately after start of light emission was measured with a spectral radiance meter CS-2000 (manufactured by Konica Minolta, Inc.).

For an emission color, an element having a maximum emission wavelength of 600 to 699 nm was set to red, and an element having a maximum emission wavelength of 700 nm to 1000 nm was set to a near-infrared color.

(Measurement of Luminous Efficiency)

The luminous efficiency of each sample at the time of driving an organic EL element was evaluated by performing the following measurement.

Each of the organic EL elements prepared above was allowed to emit light at a constant current of 2.5 mA/cm² at room temperature (about 25° C.), and emission brightness immediately after start of light emission was measured with a spectral radiance meter CS-2000 (manufactured by Konica Minolta, Inc.).

Table 2 illustrates a relative value of the obtained emission brightness (relative value to the emission brightness of the organic EL element 1-1 in Example 1).

(Measurement For Change Ratio in Resistance Value of Light Emitting Layer)

Using each of the obtained organic EL elements, the above illumination device as illustrated in FIGS. 9 and 10 was prepared, and a change ratio in resistance value of a light emitting layer was measured with an impedance spectrometer.

Specifically, in a glove box adjusted to a nitrogen atmosphere (under an atmosphere of high purity nitrogen gas having a purity of 99.999% or more), an epoxy-based photocurable adhesive (Luxtrak LC0629B manufactured by Toagosei Co., Ltd.) was applied to a peripheral portion on a glass cover side as a sealing agent. The resulting product was bonded to a surface on which the organic EL layer was formed in the glass substrate with a transparent electrode in the organic EL element to be brought into close contact with the surface. Subsequently, a peripheral portion of the back side of the glass substrate with a transparent electrode excluding the organic EL layer was irradiated with UV light to cure the sealing agent. As a result, an illumination device 101 in which an organic EL element obtained by laminating the glass substrate with a transparent electrode 107, the organic EL element layer 106, and the negative electrode 105 in this order was covered with the glass cover 102 was obtained (see FIG. 10). Note that the glass cover 102 is filled with the nitrogen gas 108 and includes the water-capturing agent 109.

A change ratio in resistance value of a light emitting layer of the obtained illumination device 101 was determined by the following method.

Specifically, impedance values before and after driving the obtained illumination device 101 for 1000 hours under a constant current condition of 2.5 mA/cm² at room temperature (about 23° C. to 25° C.) were measured with reference to the measurement method described on pages 423 to 425 of “Thin film evaluation handbook” published by Techno Systems Inc. using a 1260 type impedance analyzer and a 1296 type dielectric interface manufactured by Solartron at a bias voltage of 1 V From an obtained Cole-Cole plot, resistance values before and after driving a light emitting layer of an organic EL element constituting the prepared illumination device were measured. A method for measuring the resistance value of the light emitting layer from the Cole-Cole plot was similar to that in the above <Measurement example of thin film resistance value by impedance spectroscopic measurement>. Then, a resistance value of the light emitting layer obtained by the measurement was applied to the following calculation formula to determine a change ratio in resistance value. Table 2 illustrates a relative ratio when the change ratio in resistance value of the organic EL element 1-1 is assumed to be 100.

Change ratio (%) in resistance value between before and after driving=|(resistance value after driving/resistance value before driving)−1|×100

A value closer to 0 indicates a smaller change ratio between before and after driving.

TABLE 2

| | | | | | | Change ratio | |
|---|---|---|---|---|---|---|---|
| | | | | | Relative | in resistance | |
| Organic | First | Second | Third | | luminous | value of light | |
| EL | organic compound | organic compound | organic compound | Emission | efficiency | emitting layer | |
| element | Inclusion layer | Inclusion layer | Inclusion layer | color | (%) | (%) | Note |
| 1-1 | — | Comparative compound 1 | CBP | Near- | 100 | 100 | Comparative |
| | | Light emitting layer | Light emitting layer | infrared | | | Example |
| 1-2 | T-2 | Comparative compound 2 | CBP | Red | 220 | 85 | Comparative |
| | Light emitting layer | Light emitting layer | Light emitting layer | | | | Example |
| 1-3 | T-2 | D-2 | — | Near- | 168 | 87 | Present |
| | Light emitting layer | Light emitting layer | | infrared | | | invention |
| 1-4 | T-2 | D-2 | CBP | Near- | 225 | 78 | Present |
| | Light emitting layer | Electron injection layer | Light emitting layer | infrared | | | invention |
| 1-5 | T-2 | D-2 | CBP | Near- | 232 | 75 | Present |
| | Light emitting layer | Electron transport layer | Light emitting layer | infrared | | | invention |
| 1-6 | T-2 | D-2 | CBP | Near- | 255 | 65 | Present |
| | Light emitting layer | Light emitting layer | Light emitting layer | infrared | | | invention |
| 1-7 | T-2 | D-16 | CBP | Near- | 209 | 87 | Present |
| | Light emitting layer | Light emitting layer | Light emitting layer | infrared | | | invention |
| 1-8 | T-6 | D-10 | CBP | Near- | 180 | 79 | Present |
| | Light emitting layer | Light emitting layer | Light emitting layer | infrared | | | invention |
| 1-9 | T-2 | D-10 | CBP | Near- | 215 | 78 | Present |
| | Light emitting layer | Light emitting layer | Light emitting layer | infrared | | | invention |
| 1-10 | T-2 | D-32 | CBP | Near- | 192 | 76 | Present |
| | Light emitting layer | Light emitting layer | Light emitting layer | infrared | | | invention |
| 1-11 | T-2 | D-35 | CBP | Near- | 201 | 76 | Present |
| | Light emitting layer | Light emitting layer | Light emitting layer | infrared | | | invention |
| 1-12 | T-2 | D-47 | CBP | Near- | 196 | 81 | Present |
| | Light emitting layer | Light emitting layer | Light emitting layer | infrared | | | invention |
| 1-13 | T-2 | D-52 | CBP | Near- | 238 | 69 | Present |
| | Light emitting layer | Light emitting layer | Light emitting layer | infrared | | | invention |
| 1-14 | T-2 | D-60 | CBP | Near- | 189 | 82 | Present |
| | Light emitting layer | Light emitting layer | Light emitting layer | infrared | | | invention |
| 1-15 | T-2 | D-65 | CBP | Near- | 238 | 72 | Present |
| | Light emitting layer | Light emitting layer | Light emitting layer | infrared | | | invention |
| 1-16 | T-2 | D-67 | CBP | Near- | 245 | 68 | Present |
| | Light emitting layer | Light emitting layer | Light emitting layer | infrared | | | invention |

As illustrated in Table 2, the organic EL element of the present invention emitted near-infrared light. In addition, any one of the organic EL elements of the present invention exhibited higher luminous efficiency and a smaller change ratio in resistance value than an organic EL element in Comparative Example.

Specifically, from comparison among the organic EL elements 1-4 to 1-6, it is found that the organic elements 1-5 and 1-6 in each of which the second organic compound is included in a layer (electron transport layer) adjacent to a light emitting layer or a light emitting layer (par6cularly, the element 1-6 in which the second organic compound is included in a light emitting layer) each have higher relative luminous efficiency and a smaller change ratio in resistance value than the organic EL element 1-4 in which the second organic compound is included in a negative electrode.

In addition, from comparison between the organic EL elements 1-3 and 1-6, the organic EL element 1-6 further including the third organic compound has higher relative luminous efficiency and a smaller change ratio in resistance value than the organic EL element 1-3 not including the third organic compound.

In addition, from comparison between the organic EL elements 1-8 and 1-9, the organic EL element 1-9 in which the first organic compound is a delayed fluophor has higher relative luminous efficiency and a smaller change ratio in resistance value than the organic EL element 1-8 in which the first organic compound is a phosphorescent compound.

In addition, from comparison between the organic EL element 1-7 and the organic EL elements 1-6 and 1-9 to 1-16, the organic EL elements 1-6 and 1-9 to 1-16 in each of which the second organic compound has a specific structure each have higher relative luminous efficiency and a smaller change ratio in resistance value than the organic EL element 1-7 in which the second organic compound does not have a specific structure.

The present applicatio claims priority based on Japanese Patent Application No. 2016-135991 filed on Jul. 8, 2016. Contents described in the application specification and drawings are all incorporated herein by reference.

### INDUSTRIAL APPLICABILITY

The above means of the present invention can provide, for example, an organic EL element having high luminous efficiency and a small change in resistance value over time during passage of a current. The above means of the present invention can provide a display device and an illumination device each including the organic EL element.

### REFERENCE SIGNS LIST

1 Display
3 Pixel
5 Scanning line
6 Data line
7 Power supply line
10 Organic EL element
11 Switching transistor
12 Driving transistor
13 Condenser
101 Organic EL element in illumination device
102 Glass cover
105 Negative electrode
106 Organic layer
107 Glass substrate with transparent electrode
108 Nitrogen gas
109 Water-capturing agent
A Display
B Controller
C Wiring

1. An organic electroluminescent element comprising a positive electrode, a negative electrode, and an organic layer sandwiched between the positive electrode and the negative electrode and including at least a light emitting layer, wherein
the light emitting layer includes a first organic compound formed of a delayed fluophor or a phosphorescent compound having a difference in energy ΔE_{ST} of 0.3 eV or less between a lowest excited singlet state and a lowest excited triplet state at 77 K,
the positive electrode, the negative electrode, or the organic layer includes a second organic compound formed of a fluorescent dye represented by general formula (1) or (2), having a maximum emission wavelength of 700 nm to 1000 nm in a fluorescence spectrum, 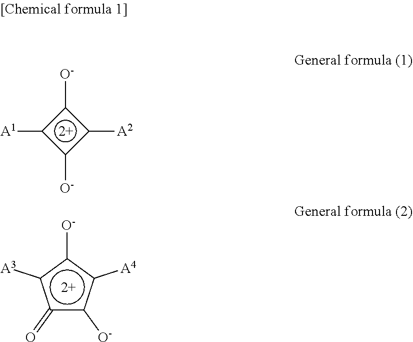
[In general formulas (1) and (2), A¹ to A⁴ each independently represent a group having a sp2 carbon atom at a bonding site]
when the first organic compound is the delayed fluophor, the first organic compound and the second organic compound satisfy the following formula (a),
formula (a): ES1(A)>ES1(B)
(In formula (a),
ES1(A) represents a lowest excited singlet energy level of the first organic compound, and
ES1(B) represents a lowest excited singlet energy level of the second organic compound), and
when the first organic compound is the phosphorescent compound, the first organic compound and the second organic compound satisfy the following formula (b).
Formula (b): ET1(A)>ES1(B)
(In formula (b),
ET1(A) represents a lowest excited triplet energy level of the first organic compound at 77 K, and
ES1(B) represents a lowest excited singlet energy level of the second organic compound.)

2. The organic electroluminescent element according to claim 1, wherein
the light emitting layer further includes a third organic compound,
when the first organic compound is the delayed fluophor, the first organic compound and the third organic compound satisfy the following formulas (a)′ and (c)′,
formula (a)′: ES1(C)>ES1(A)
formula (c)′: ET1(C)>ET1(A)
(In formula (a)′,
ES1(C) represents a lowest excited singlet energy level of the third organic compound, and
ES1(A) represents a lowest excited singlet energy level of the first organic compound.
In formula (c)′,
ET1(C) represents a lowest excited triplet energy level of the third organic compound at 77 K, and
ET1(A) represents a lowest excited triplet energy level of the first organic compound at 77 K), and
when the first organic compound is the phosphorescent compound, the first organic compound and the third organic compound satisfy the formula (c)′.

3. The organic electroluminescent element according to claim 1,
wherein the second organic compound is included in the light emitting layer or a layer adjacent to the light emitting layer.

4. The organic electroluminescent element according to claim 3, wherein the second organic compound is included in the light emitting layer.

5. The organic electroluminescent element according to claim 2, wherein the first organic compound, the second organic compound, and the third organic compound are all included in the light emitting layer.

6. The organic electroluminescent element according to claim 1, wherein in the general formulas (1) and (2), A¹ to A⁴ are each independently selected from the group consisting of the following (a) to (l). 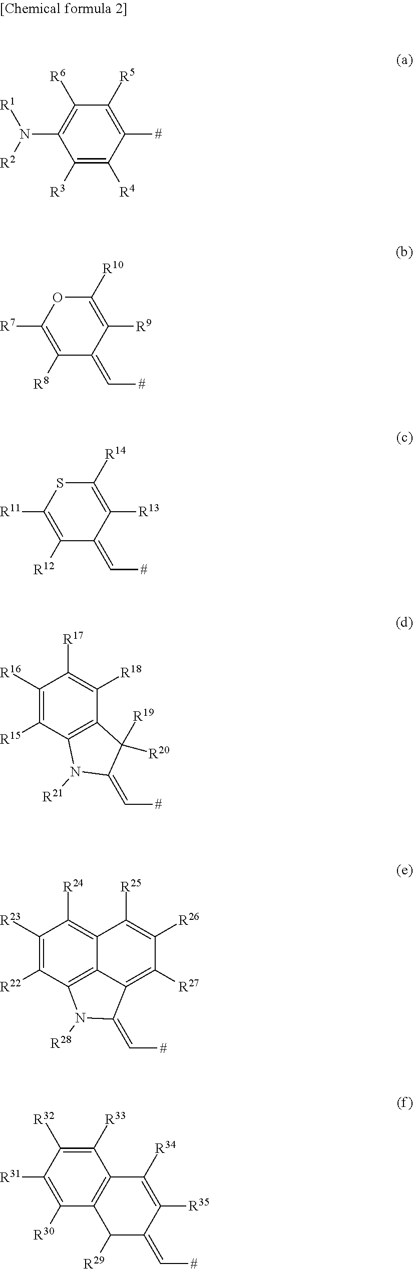 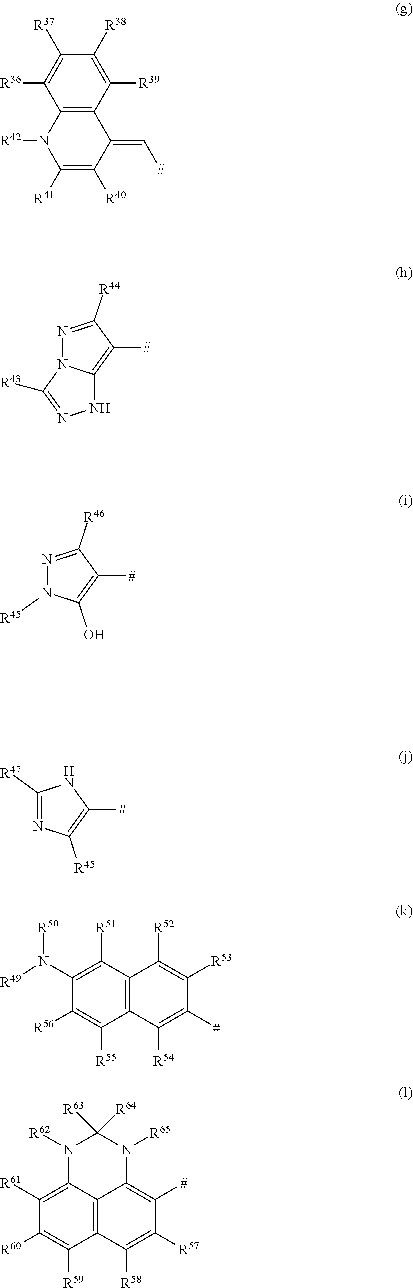
[In formulas (a) to (l),
R¹ to R⁶⁵ each independently represent a hydrogen atom or a substituent,
adjacent ones of the substituents may be bonded to each other to form a cyclic structure, and
# represents a bond to general formula (1) or (2).
Provided that at least one of R¹⁵ to R¹⁸ in formula (d), at least one of R²² to R²⁷ in formula (e), at least one of R³⁰ to R³⁵ in formula (f), at least one of R³⁶ to R⁴¹ in formula (g), at least one of R⁴³ and R⁴⁴ in formula (h), at least one of R⁴⁵ and R⁴⁶ in formula (i), and at least one of R⁴⁷ and R⁴⁸ in formula (j) each represent an electron-donating group D selected from the group consisting of an aryl group substituted with an electron-donating group, an optionally substituted electron-donating heterocyclic group, an optionally substituted amino group, an optionally substituted alkoxy group, and an alkyl group.]

7. The organic electroluminescent element according to claim 1, wherein the first organic compound is the delayed fluophor.

8. A display device comprising the organic electroluminescent element according to claim 1.

9. An illumination device comprising the organic electroluminescent element according to claim 1.

10. The organic electroluminescent element according to claim 2, wherein the second organic compound is included in the light emitting layer or a layer adjacent to the light emitting layer.

11. The organic electroluminescent element according to claim 2, wherein in the general formulas (1) and (2), A¹ to A⁴ are each independently selected from the group consisting of the following (a) to (l). 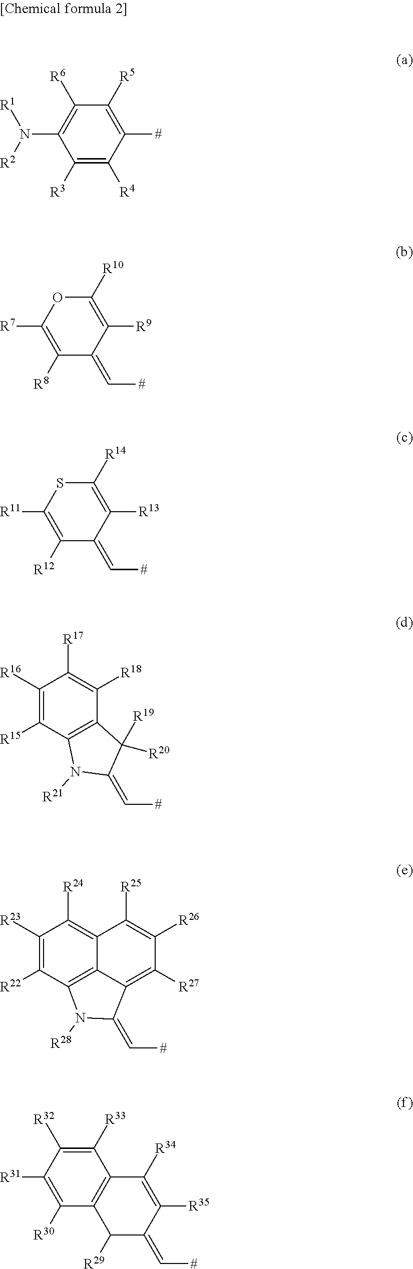 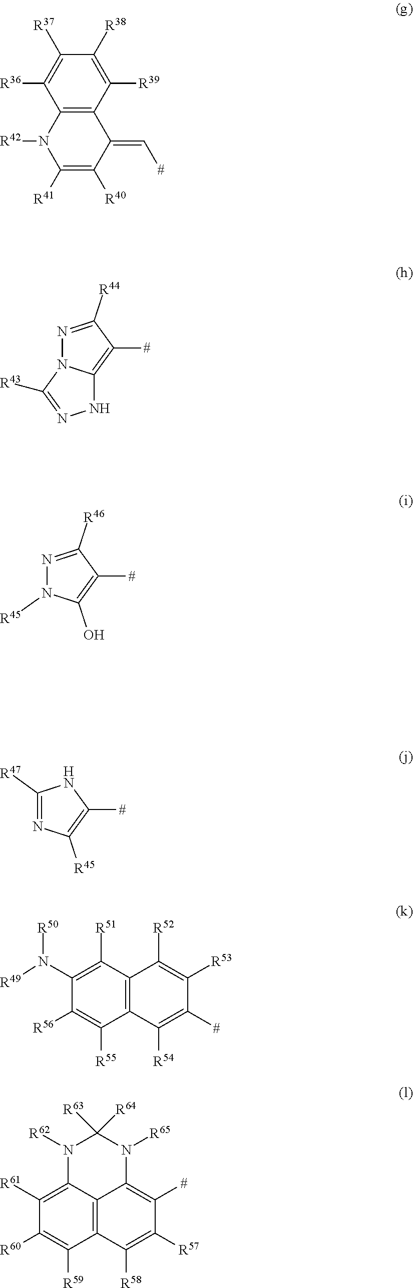
[In formulas (a) to (l),
R¹ to R⁶⁵ each independently represent a hydrogen atom or a substituent,
adjacent ones of the substituents may be bonded to each other to form a cyclic structure, and
# represents a bond to general formula (1) or (2).
Provided that at least one of R¹⁵ to R¹⁸ in formula (d), at least one of R²² to R²⁷ in formula (e), at least one of R³⁰ to R³⁵ in formula (f), at least one of R³⁶ to R⁴¹ in formula (g), at least one of R⁴³ and R⁴⁴ in formula (h), at least one of R⁴⁵ and R⁴⁶ in formula (i), and at least one of R⁴⁷ and R⁴⁸ in formula (j) each represent an electron-donating group D selected from the group consisting of an aryl group substituted with an electron-donating group, an optionally substituted electron-donating heterocyclic group, an optionally substituted amino group, an optionally substituted alkoxy group, and an alkyl group.]

12. The organic electroluminescent element according to claim 2, wherein the first organic compound is the delayed fluophor.

13. A display device comprising the organic electroluminescent element according to claim 2.

14. An illumination device comprising the organic electroluminescent element according to claim 2.

15. The organic electroluminescent element according to claim 3, wherein in the general formulas (1) and (2), A¹ to A⁴ are each independently selected from the group consisting of the following (a) to (l). 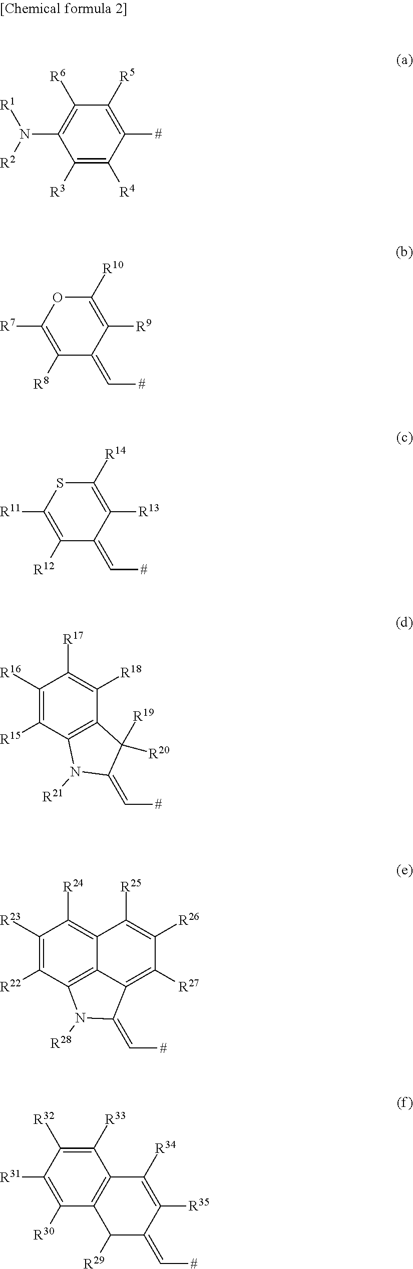 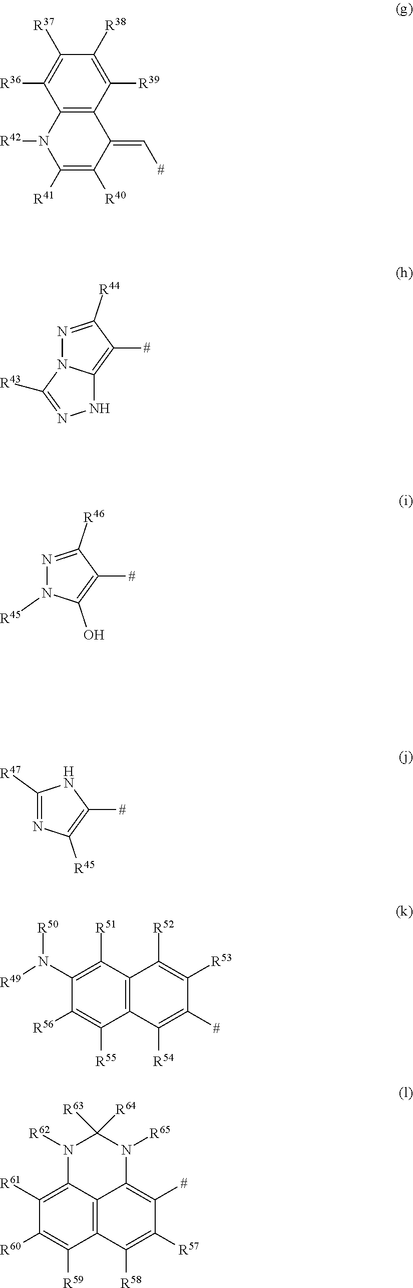
[In formulas (a) to (l),
R¹ to R⁶⁵ each independently represent a hydrogen atom or a substituent,
adjacent ones of the substituents may be bonded to each other to form a cyclic structure, and
# represents a bond to general formula (1) or (2).
Provided that at least one of R¹⁵ to R¹⁸ in formula (d), at least one of R²² to R²⁷ in formula (e), at least one of R³⁰ to R³⁵ in formula (f), at least one of R³⁶ to R⁴¹ in formula (g), at least one of R⁴³ and R⁴⁴ in formula (h), at least one of R⁴⁵ and R⁴⁶ in formula (i), and at least one of R⁴⁷ and R⁴⁸ in formula (j) each represent an electron-donating group D selected from the group consisting of an aryl group substituted with an electron-donating group, an optionally substituted electron-donating heterocyclic group, an optionally substituted amino group, an optionally substituted alkoxy group, and an alkyl group.]

16. The organic electroluminescent element according to claim 3, wherein the first organic compound is the delayed fluophor.

17. A display device comprising the organic electroluminescent element according to claim 3.

18. An illumination device comprising the organic electroluminescent element according to claim 3.

19. The organic electroluminescent element according to claim 4, wherein in the general formulas (1) and (2), A¹ to A⁴ are each independently selected from the group consisting of the following (a) to (l). 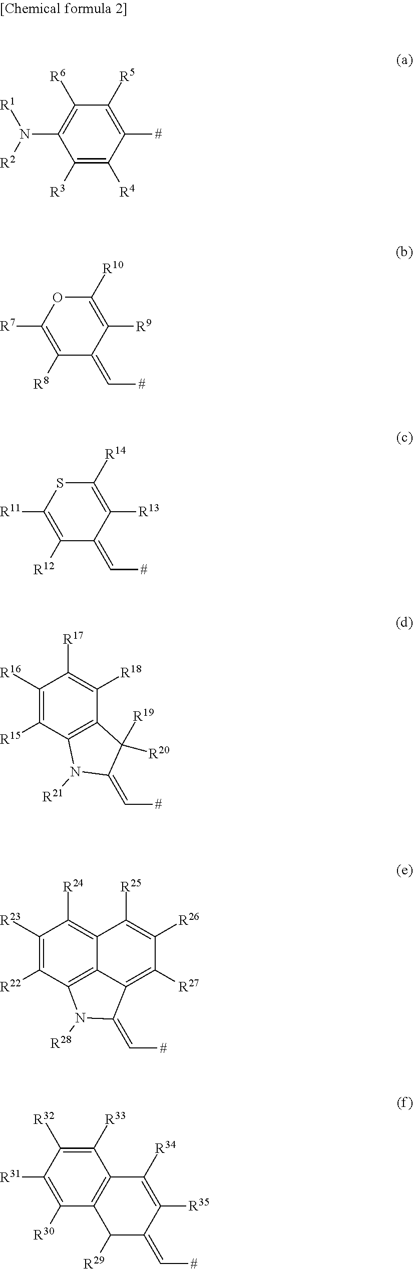 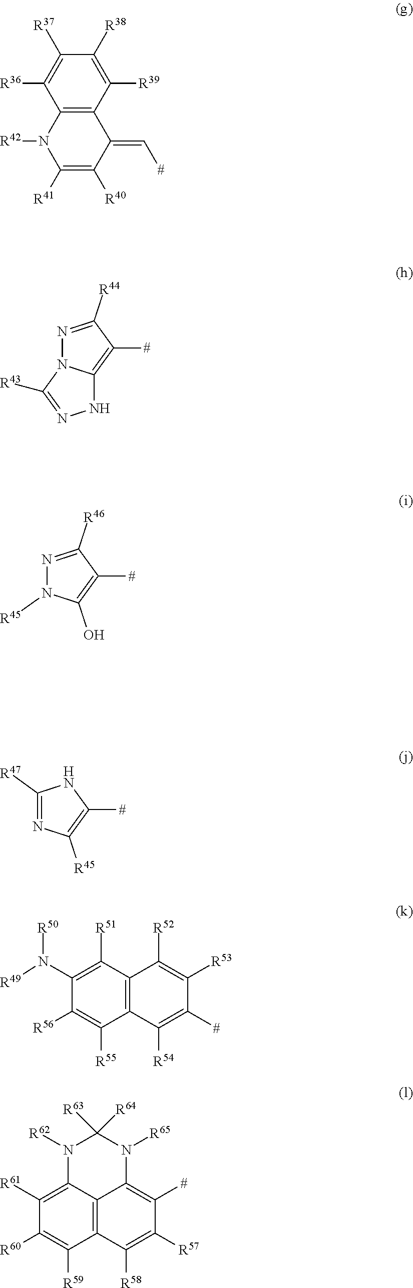
[In formulas (a) to (l),
R¹ to R⁶⁵ each independently represent a hydrogen atom or a substituent,
adjacent ones of the substituents may be bonded to each other to form a cyclic structure, and
# represents a bond to general formula (1) or (2).
Provided that at least one of R¹⁵ to R¹⁸ in formula (d), at least one of R²² to R²⁷ in formula (e), at least one of R³⁰ to R³⁵ in formula (f), at least one of R³⁶ to R⁴¹ in formula (g), at least one of R⁴³ and R⁴⁴ in formula (h), at least one of R⁴⁵ and R⁴⁶ in formula (i), and at least one of R⁴⁷ and R⁴⁸ in formula (j) each represent an electron-donating group D selected from the group consisting of an aryl group substituted with an electron-donating group, an optionally substituted electron-donating heterocyclic group, an optionally substituted amino group, an optionally substituted alkoxy group, and an alkyl group.]

20. The organic electroluminescent element according to claim 4, wherein the first organic compound is the delayed fluophor.
